(19) United States
(12) Patent Application Publication
(10) Pub. No.: US 2025/0107319 A1
(43) Pub. Date: Mar. 27, 2025

(54) Display Device

(71) Applicant: Semiconductor Energy Laboratory Co., Ltd., Kanagawa-ken (JP)

(72) Inventors: Tomoya AOYAMA, Atsugi, Kanagawa (JP); Hisao IKEDA, Zama, Kanagawa (JP); Daiki NAKAMURA, Atsugi, Kanagawa (JP)

(73) Assignee: Semiconductor Energy Laboratory Co., Ltd., Kanagawa-ken (JP)

(21) Appl. No.: 18/724,973

(22) PCT Filed: Dec. 15, 2022
(86) PCT No.: PCT/IB2022/062259

§ 371 Date: Jun. 27, 2024

(30) Foreign Application Priority Data
Dec. 29, 2021 (JP) 2021-215375

(51) Int. Cl. H10K 50/19; H10K 59/124

(52) U.S. Cl. CPC H10K 50/19; H10K 59/124

(57) ABSTRACT

A display device in which film separation is sufficiently inhibited is provided. The display device includes a first insulating layer and a second insulating layer, a first light-emitting device positioned over the first insulating layer, a second light-emitting device positioned over the second insulating layer, and a third insulating layer including a region covering part of a side surface of the first light-emitting device, a region covering part of the bottom surface of the first insulating layer, a region covering part of the bottom surface of the second insulating layer, and a region covering part of a side surface of the second light-emitting device. The first light-emitting device has a tandem structure and the second light-emitting device has a single structure.

### TECHNICAL FIELD

One embodiment of the present invention relates to a display device.

Note that one embodiment of the present invention is not limited to the above technical field. Examples of the technical field of one embodiment of the present invention disclosed in this specification and the like include a semiconductor device, a light-emitting apparatus, a power storage device, a memory device, an electronic device, a lighting device, an input device, and an input/output device in addition to a display device, and methods for manufacturing the same. Note that in this specification and the like, a semiconductor device generally means a device that can function by utilizing semiconductor characteristics.

### BACKGROUND ART

In recent years, electronic devices such as smartphones, tablet terminals, and notebook computers have been increased in definition, and display devices included in the electronic devices need to be increased in resolution accordingly. As a display device that can be increased in resolution, a light-emitting apparatus using an EL (Electro Luminescence) element is given. To inhibit film separation and improve the manufacturing yield of a light-emitting apparatus manufactured through a step of separating a support substrate from processed components, and the like, a structure in which an opening of an insulating layer is filled with an adhesive layer is proposed (see Patent Document 1).

### REFERENCE

### Patent Document

[Patent Document 1] Japanese Published Patent Application No. 2017-174811

### SUMMARY OF THE INVENTION

### Problems to be Solved by the Invention

In Patent Document 1, the interface between an EL layer and a conductive layer thereover is pointed out by the investigation as a weak adhesion area where film separation is caused in the step of separating the support substrate from the processed components and the like. In view of the above point, an opening of an insulating layer is filled with an adhesive layer in Patent Document 1. However, such a structure is insufficient to inhibit film separation in some cases.

The present invention has been made in view of the above problem, and one object is to provide a display device that has a structure in which film separation is sufficiently inhibited, for example.

Patent Document 1 proposes a display device in which a light-emitting element exhibiting white and coloring layers (color filters) are used. In such a display device, crosstalk and narrow viewing angle are caused in some cases.

The present invention has been made in view of the above problem, one object is to provide a display device with a wide viewing angle in which crosstalk is inhibited, for example.

Note that these objects should be construed as being independent of one another. One embodiment of the present invention only needs to achieve at least one of these objects and does not necessarily achieve all the objects. The description of these objects does not preclude the existence of other objects, and other objects can be derived from the description of the specification, the drawings, and the claims, which are this specification and the like.

### Means for Solving the Problems

In view of the above objects, in a display device of one embodiment of the present invention, an insulating layer that includes a region covering a light-emitting device is provided to sufficiently inhibit film separation of the light-emitting device processed by a lithography process. Note that “an insulating layer includes a region covering a light-emitting device” means that at least a side surface of an organic layer included in the light-emitting device is covered with the insulating layer and the insulating layer is not necessarily in contact with the organic layer. However, the insulating layer that includes a region covering a light-emitting device preferably includes a region in contact with an insulating layer positioned on a formation surface of the light-emitting device. If the region in contact with the insulating layer can be positioned on the bottom surface (may be referred to as a rear surface) of the insulating layer positioned on the formation surface, film separation of the light-emitting device can be effectively inhibited.

The light-emitting device included in the display device of one embodiment of the present invention includes at least a light-emitting layer processed by a lithography process. Through the lithography process, a red-light-emitting device, a green-light-emitting device, and a blue-light-emitting device can be separately formed, thereby inhibiting leakage current between adjacent light-emitting devices. This can prevent crosstalk due to unintended light emission, so that a display device with extremely high contrast can be achieved. Furthermore, the light-emitting layer processed by the lithography process enables a display device with a wide viewing angle to be provided.

Specifically, one embodiment of the invention is a display device that includes a first insulating layer and a second insulating layer, a first light-emitting device positioned over the first insulating layer, a second light-emitting device positioned over the second insulating layer, and a third insulating layer including a region covering a part of a side surface of the first light-emitting device, a region covering a part of a bottom surface of the first insulating layer, a region covering a part of a bottom surface of the second insulating layer, and a region covering a part of a side surface of the second light-emitting device. The first light-emitting device has a tandem structure and the second light-emitting device has a single structure.

Another embodiment of the present invention is a display device that includes a first insulating layer and a second insulating layer, a first light-emitting device positioned over the first insulating layer, a second light-emitting device positioned over the second insulating layer, and a third insulating layer including a region covering a part of a side surface of the first light-emitting device, a region in contact with a part of a bottom surface of the first insulating layer, a region in contact with a part of a bottom surface of the second insulating layer, and a region covering a part of a side surface of the second light-emitting device. The first light-emitting device has a tandem structure and the second light-emitting device has a single structure.

Another embodiment of the present invention is a display device that includes a first insulating layer including a depressed portion, a second insulating layer positioned over the first insulating layer and including a first protruding portion overlapping with the depressed portion, a third insulating layer positioned over the first insulating layer and including a second protruding portion overlapping with the depressed portion, a first light-emitting device positioned over the first insulating layer, a second light-emitting device positioned over the second insulating layer, and a fourth insulating layer including a region covering a part of a side surface of the first light-emitting device, a region covering a bottom surface of the first protruding portion, a region covering a bottom surface of the second protruding portion, and a region covering a part of a side surface of the second light-emitting device. The first light-emitting device has a tandem structure and the second light-emitting device has a single structure.

Another embodiment of the present invention is a display device that includes a first insulating layer including a depressed portion, a second insulating layer positioned over the first insulating layer and including a first protruding portion overlapping with the depressed portion, a third insulating layer positioned over the first insulating layer and including a second protruding portion overlapping with the depressed portion, a first light-emitting device positioned over the first insulating layer, a second light-emitting device positioned over the second insulating layer, and a fourth insulating layer including a region covering a part of a side surface of the first light-emitting device, a region in contact with a bottom surface of the first protruding portion, a region in contact with a bottom surface of the second protruding portion, and a region covering a part of a side surface of the second light-emitting device. The first light-emitting device has a tandem structure and the second light-emitting device has a single structure.

Another embodiment of the present invention is a display device that includes a first insulating layer and a second insulating layer, a first light-emitting device positioned over the first insulating layer, a second light-emitting device positioned over the second insulating layer, and a third insulating layer including a region covering a part of a side surface of the first light-emitting device, a region covering a part of a bottom surface of the first insulating layer, a region covering a part of a bottom surface of the second insulating layer, and a region covering a part of a side surface of the second light-emitting device. The first light-emitting device includes a first light-emitting unit, a charge-generation layer over the first light-emitting unit, and a second light-emitting unit over the charge-generation layer. The second light-emitting device includes a third light-emitting unit.

Another embodiment of the present invention is a display device that includes a first insulating layer and a second insulating layer, a first light-emitting device positioned over the first insulating layer, a second light-emitting device positioned over the second insulating layer, and a third insulating layer including a region covering a part of a side surface of the first light-emitting device, a region in contact with a part of a bottom surface of the first insulating layer, a region in contact with a part of a bottom surface of the second insulating layer, and a region covering a part of a side surface of the second light-emitting device. The first light-emitting device includes a first light-emitting unit, a charge-generation layer over the first light-emitting unit, and a second light-emitting unit over the charge-generation layer. The second light-emitting device includes a third light-emitting unit.

Another embodiment of the present invention is a display device that includes a first insulating layer including a depressed portion, a second insulating layer positioned over the first insulating layer and including a first protruding portion overlapping with the depressed portion, a third insulating layer positioned over the first insulating layer and including a second protruding portion overlapping with the depressed portion, a first light-emitting device positioned over the first insulating layer, a second light-emitting device positioned over the second insulating layer, and a fourth insulating layer including a region covering a part of a side surface of the first light-emitting device, a region covering a bottom surface of the first protruding portion, a region covering a bottom surface of the second protruding portion, and a region covering a part of a side surface of the second light-emitting device. The first light-emitting device includes a first light-emitting unit, a charge-generation layer over the first light-emitting unit, and a second light-emitting unit over the charge-generation layer. The second light-emitting device includes a third light-emitting unit.

Another embodiment of the present invention is a display device that includes a first insulating layer including a depressed portion, a second insulating layer positioned over the first insulating layer and including a first protruding portion overlapping with the depressed portion, a third insulating layer positioned over the first insulating layer and including a second protruding portion overlapping with the depressed portion, a first light-emitting device positioned over the first insulating layer, a second light-emitting device positioned over the second insulating layer, and a fourth insulating layer including a region covering a part of a side surface of the first light-emitting device, a region in contact with a bottom surface of the first protruding portion, a region in contact with a bottom surface of the second protruding portion, and a region covering a part of a side surface of the second light-emitting device. The first light-emitting device includes a first light-emitting unit, a charge-generation layer over the first light-emitting unit, and a second light-emitting unit over the charge-generation layer. The second light-emitting device includes a third light-emitting unit.

In another embodiment of the present invention, the charge-generation layer preferably includes lithium.

In another embodiment of the present invention, each of the first insulating layer to the third insulating layer preferably includes an inorganic material.

In another embodiment of the present invention, the first insulating layer preferably includes an organic material and each of the second insulating layer to the fourth insulating layer preferably includes an inorganic material.

In another embodiment of the present invention, each of the first insulating layer to the fourth insulating layer preferably includes an inorganic material.

### Effect of the Invention

According to one embodiment of the present invention, a display device in which film separation is sufficiently inhibited can be provided. According to one embodiment of the present invention, a display device in which crosstalk is inhibited can be provided. According to one embodiment of the present invention, a display device with a wide viewing angle can be provided.

Note that these effects should be construed as being independent of one another. One embodiment of the present invention only needs to have at least one of these effects and does not necessarily have all the effects. The description of these effects does not preclude the existence of other effects, and other effects can be derived from the description of the specification, the drawings, and the claims, which are this specification and the like.

### BRIEF DESCRIPTION OF THE DRAWINGS

FIG. 1A to FIG. 1F are diagrams illustrating structure examples of a light-emitting device.

FIG. 2A and FIG. 2B are diagrams illustrating structure examples of a light-emitting device.

FIG. 3A and FIG. 3B are diagrams illustrating structure examples of a light-emitting device.

FIG. 4A to FIG. 4F are diagrams illustrating structure examples of a light-emitting device.

FIG. 5A and FIG. 5B are diagrams illustrating structure examples of a light-emitting device.

FIG. 6A and FIG. 6B are diagrams illustrating a structure examples of a display device.

FIG. 7 is a diagram illustrating a structure example of a display device.

FIG. 8A and FIG. 8B are diagrams illustrating a structure example of a display device.

FIG. 9 is a diagram illustrating a structure example of a display device.

FIG. 10A to FIG. 10D are diagrams illustrating an example of a manufacturing process of a display device.

FIG. 11A to FIG. 11D are diagrams illustrating an example of a manufacturing process of a display device.

FIG. 12A and FIG. 12B are diagrams illustrating an example of a manufacturing process of a display device, and the like.

FIG. 13A to FIG. 13C are diagrams illustrating an example of a manufacturing process of a display device.

FIG. 14A to FIG. 14D are diagrams illustrating an example of a manufacturing process of a light-emitting device.

FIG. 15A and FIG. 15B are diagrams illustrating structure examples of a light-emitting device.

FIG. 16A and FIG. 16B are diagrams illustrating structure examples of a light-emitting device.

FIG. 17A and FIG. 17B are diagrams illustrating structure examples of a light-emitting device.

FIG. 18A to FIG. 18E are diagrams illustrating structure examples of a display device.

FIG. 19A to FIG. 19G are diagrams illustrating layouts of a display device.

FIG. 20A to FIG. 20K are diagrams illustrating layouts of a display device.

FIG. 21A and FIG. 21B are diagrams illustrating structure examples of a display device.

FIG. 22 is a diagram illustrating a structure example of a display device.

FIG. 23 is a diagram illustrating a structure example of a display device.

FIG. 24 is a diagram illustrating a structure example of a display device.

FIG. 25 is a diagram illustrating a structure example of a display device.

FIG. 26 is a diagram illustrating a structure example of a display device.

FIG. 27 is a diagram illustrating a structure example of a display device.

FIG. 28 is a diagram illustrating a structure example of a display device.

FIG. 29A is a diagram illustrating a structure example of a display device, and FIG. 29B and FIG. 29C are diagrams illustrating structure examples of a transistor.

FIG. 30A to FIG. 30D are diagrams illustrating structure examples of an electronic device.

FIG. 31A to FIG. 31F are diagrams illustrating structure examples of an electronic device.

FIG. 32A to FIG. 32G are diagrams illustrating structure examples of an electronic device.

### MODE FOR CARRYING OUT THE INVENTION

In this specification and the like, a light-emitting device includes a pair of electrodes and a functional layer positioned between the pair of electrodes. Layers using organic compounds are stacked as the functional layer between the pair of electrodes. In this specification and the like, the functional layer positioned between the pair of electrodes may be referred to as an organic layer or a stack, and the organic layer included in the light-emitting device refers to a state in which layers using organic compounds are stacked. The light-emitting device may be referred to as a light-emitting element or an EL element.

Examples of the functional layer include a light-emitting layer, carrier-injection layers (typically, a hole-injection layer and an electron-injection layer), carrier-transport layers (typically, a hole-transport layer and an electron-transport layer), and carrier-blocking layers (typically, a hole-blocking layer and an electron-blocking layer). The light-emitting layer refers to a layer including a light-emitting material (may be referred to as a light-emitting substance). A layer using an organic compound is preferably used as the light-emitting layer, in which case the layer using an organic compound may be referred to as an organic light-emitting layer and a light-emitting device including the organic light-emitting layer may be referred to as an organic light-emitting device. The hole-injection layer refers to a layer including a substance with a high hole-injection property. The electron-injection layer refers to a layer including a substance with a high electron-injection property. The hole-transport layer refers to a layer including a substance with a high hole-transport property. The electron-transport layer refers to a layer including a substance with a high electron-transport property. The hole-blocking layer refers to a layer including a substance with a high hole-blocking property. The electron-blocking layer refers to a layer including a substance with a high electron-blocking property.

A layer using an inorganic compound (referred to as an inorganic compound layer) can be used for the carrier-injection layer, the carrier-blocking layer, or the like among the functional layers given above.

In this specification and the like, the light-emitting device includes at least a light-emitting layer as the organic layer, and the organic layer including the light-emitting layer may be referred to as an EL layer. The light-emitting device may include two or more light-emitting layers.

The light-emitting device can emit red light, green light, and blue light depending on light-emitting materials included in the light-emitting layers. In this specification and the like, a light-emitting device capable of emitting red light, green light, or blue light may be referred to as a red-light-emitting device, a green-light-emitting device, or a blue-light-emitting device. In this specification and the like, a light-emitting region in a plan view that corresponds to red light emission, green light emission, or blue light emission may be referred to as a subpixel. Although a combination of three subpixels such as red, green, and blue described above is sometimes referred to as a pixel, a pixel may be a combination of four or more subpixels in which white or the like is added to the above-described combination.

In this specification and the like, many names are used to refer to one and the other of the pair of electrodes included in the light-emitting device. For example, one of the pair of electrodes may be referred to as an anode and the other may be referred to as a cathode. In the case where the pair of electrodes in the light-emitting device are named after their positions, one of the pair of electrodes positioned below the light-emitting layer may be referred to as a lower electrode and the other of the pair of electrodes positioned above the light-emitting layer may be referred to as an upper electrode. Furthermore, in the case where the pair of electrodes are described in accordance with the direction in which light from the light-emitting device is extracted, one of the pair of electrodes positioned on the side where light is extracted may be referred to as an extraction electrode and the other may be referred to as a counter electrode. Note that “one” and “the other” are just examples and can be interchanged with each other.

In this specification and the like, the light-emitting device can have a tandem structure or a single structure. In the tandem structure, a charge-generation layer is provided between two or more light-emitting layers that are stacked between the pair of electrodes. A stack including a light-emitting layer may be referred to as a light-emitting unit, and the light-emitting unit includes neither a pair of electrodes nor a charge-generation layer. That is, in the tandem structure, two or more light-emitting units are stacked with a charge-generation layer therebetween. In the case where two light-emitting units are referred to as a first light-emitting unit and a second light-emitting unit, the first light-emitting unit and the second light-emitting unit may include the same stack or different stacks in the tandem structure. Furthermore, in the tandem structure, one light-emitting unit may include one light-emitting layer or two or more light-emitting layers. In the case where two or more light-emitting layers are included, the light-emitting layers may or may not be positioned in contact with each other. The tandem structure may include two or more charge-generation layers, in which case three or more light-emitting units are included.

The charge-generation layer refers to a layer that has a function of injecting holes into one of the light-emitting units and a function of injecting electrons into the other light-emitting unit when voltage is applied between the pair of electrodes. The charge-generation layer is positioned between the stacked light-emitting units, whereby an increase in driving voltage in the tandem structure can be inhibited. The charge-generation layer is positioned between the light-emitting units and thus may be referred to as an intermediate layer. In the case where the charge-generation layer is thin, it cannot be identified as a layer in some cases; for this reason, the charge-generation layer may be referred to as a charge-generation region or an intermediate region.

The single structure does not include a charge-generation layer but includes one light-emitting unit between a pair of electrodes. One light-emitting unit may include one light-emitting layer or two or more light-emitting layers. In the case where two or more light-emitting layers are included, the light-emitting layers may or may not be positioned in contact with each other.

In this specification and the like, a light-emitting device formed using a metal mask or an FMM (a fine metal mask or a high-resolution metal mask) may be referred to as a device having an MM (metal mask) structure. In this specification and the like, a light-emitting device formed using neither a metal mask nor an FMM may be referred to as a device having an MML (metal maskless) structure.

In this specification and the like, a structure in which light-emitting layers are separately formed may be referred to as an SBS (Side By Side) structure.

In this specification and the like, a structure in which a connector such as an FPC (Flexible Printed Circuit) or a TCP (Tape Carrier Package) is attached to a substrate of a display device, or a structure in which an IC is mounted on the substrate by a COG (Chip On Glass) method or the like is referred to as a display module in some cases. The display module is one embodiment of a display device.

Next, embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

In this embodiment, a display device that includes an insulating layer or the like provided to inhibit film separation of a light-emitting device or the like will be described.

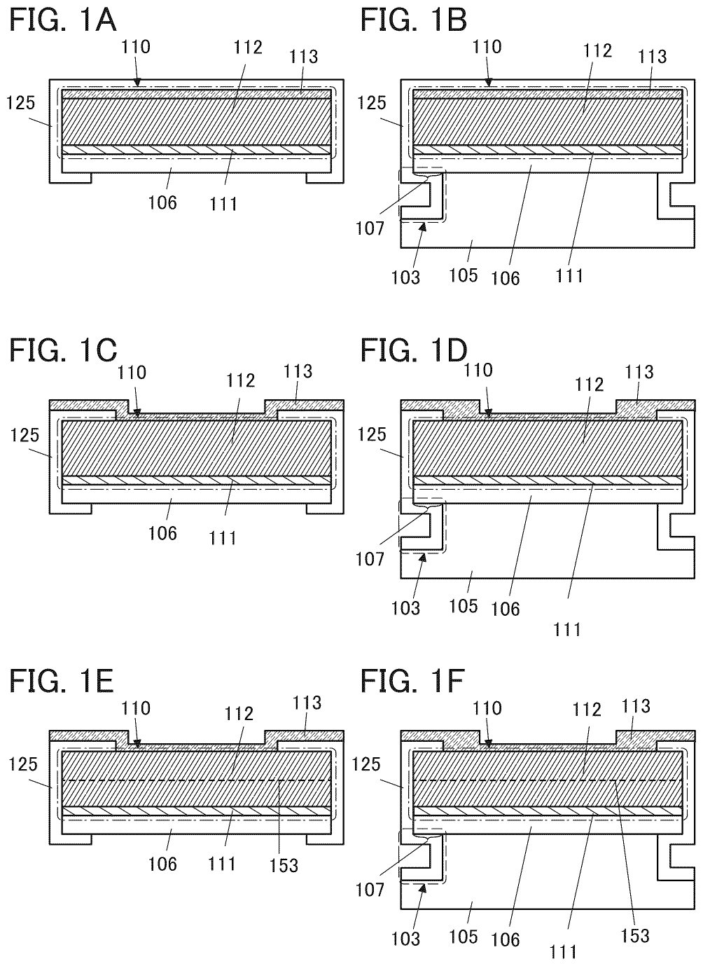

As illustrated in FIG. 1A, the display device of one embodiment of the present invention includes a light-emitting device 110 processed by a lithography process, and the light-emitting device 110 includes a lower electrode 111, an organic layer 112, and an upper electrode 113. An MML structure is applied to the light-emitting device 110 in the display device of one embodiment of the present invention. In the light-emitting device 110 to which the MML structure is applied, a side surface of the organic layer 112 is perpendicular or substantially perpendicular to a formation surface, specifically the top surface of the lower electrode 111. “Perpendicular” or “substantially perpendicular” means the angle between an end portion and the formation surface is greater than or equal to 80° and less than or equal to 100°. With the organic layer 112 having such a side surface, the distance between adjacent light-emitting devices, specifically the distance between adjacent organic layers can be less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm. That is, the MML structure enables the aperture ratio of the display device to be increased as compared with the case where the display device is manufactured using a metal mask with low alignment accuracy. The display device with a high aperture ratio can have high luminance even when the current density of the light-emitting device is reduced, leading to improved reliability of the light-emitting device.

Furthermore, in the display device of one embodiment of the present invention, an insulating layer 125 including a region covering the light-emitting device 110 is provided as illustrated in FIG. 1A to sufficiently inhibit film separation of the light-emitting device 110. “Film separation of the light-emitting device 110” includes separation of the organic layer 112 from the lower electrode 111. To sufficiently inhibit the film separation, the insulating layer 125 preferably covers part of a side surface of the light-emitting device 110, i.e., part of a side surface of the organic layer 112. Although FIG. 1A illustrates the state where the insulating layer 125 is in contact with the side surface of the organic layer 112, the insulating layer 125 is not necessarily in contact with the side surface of the organic layer 112. To sufficiently inhibit the film separation, the insulating layer 125 preferably includes a region in contact with the lower electrode 111 or with the insulating layer 106 positioned on the formation surface of the light-emitting device 110, for example. FIG. 1A illustrates a structure in which a side surface of the lower electrode 111 exposed from the organic layer 112, a side surface of the insulating layer 106, and part of the bottom surface (may be referred to as a rear surface) of the insulating layer 106 are in contact with the insulating layer 125; film separation of the light-emitting device 110 can be sufficiently inhibited when part of the top surface, the side surface, part of the side surface, or part of the bottom surface of the insulating layer 106 includes a region in contact with the insulating layer 125. As the area where the insulating layer 125 is in contact with the insulating layer 106 and the like becomes larger, film separation of the light-emitting device 110 can be inhibited more effectively.

Although FIG. 1A illustrates a structure in which an end portion of the organic layer 112 is aligned with an end portion of the lower electrode 111, the end portion of the organic layer 112 may be positioned inward from the end portion of the lower electrode 111. The end portion of the organic layer 112 may be positioned beyond the end portion of the lower electrode 111.

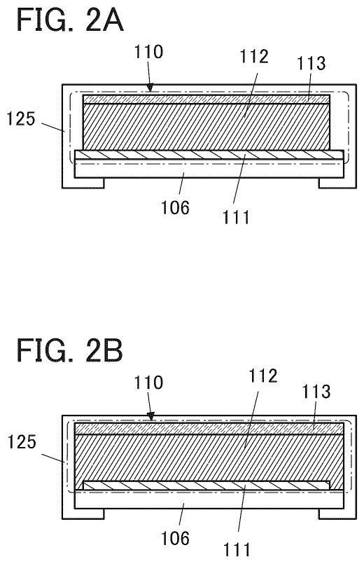

FIG. 2A illustrates the light-emitting device 110 in which an end portion of the organic layer 112 is positioned inward from an end portion of the lower electrode 111 as a variation example of FIG. 1A. FIG. 2B illustrates the light-emitting device 110 in which an end portion of the organic layer 112 is positioned beyond an end portion of the lower electrode 111 as a variation example of FIG. 1A. Also in FIG. 2A and FIG. 2B, film separation of the light-emitting device 110 can be inhibited by the insulating layer 125.

Here, examples of a material and a formation method of the insulating layer 125 are described.

The insulating layer 125 can be an insulating layer including an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a metal oxide film, a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. The metal oxide film will be described later.

Note that in this specification and the like, oxynitride refers to a material that contains more oxygen than nitrogen in its composition and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulating layer 125 preferably has a function of a protective layer against at least one of water and oxygen. The insulating layer 125 preferably has a function of inhibiting diffusion of at least one of water and oxygen. The insulating layer 125 preferably has a function of capturing or fixing (also referred to as gettering) at least one of water and oxygen.

Examples of a method for forming the insulating layer 125 include a sputtering method, a chemical vapor deposition (CVD) method, a pulsed laser deposition (PLD) method, and an atomic layer deposition (ALD) method. The insulating layer 125 is preferably formed by an ALD method enabling good coverage.

An inorganic insulating film such as an aluminum oxide film, a hafnium oxide film, or a silicon oxide film formed by an ALD method is preferably used as the insulating layer 125, in which case the insulating layer 125 has few pinholes. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

When the substrate temperature in forming the insulating layer 125 is increased, the formed insulating layer 125, even with a small thickness, can have a low impurity concentration and a high barrier property against at least one of water and oxygen. Therefore, the substrate temperature is preferably higher than or equal to 60° C., further preferably higher than or equal to 80° C., still further preferably higher than or equal to 100° C., yet still further preferably higher than or equal to 120° C. Meanwhile, the insulating layer 125 is formed after formation of the organic layer 112, and thus is preferably formed at a temperature lower than the upper temperature limit of the organic layer 112. Therefore, the substrate temperature is preferably lower than or equal to 200° C., further preferably lower than or equal to 180° C., still further preferably lower than or equal to 160° C., still further preferably lower than or equal to 150° C., yet still further preferably lower than or equal to 140° C.

Examples of temperature used as an index for the upper temperature limit include the glass transition point, the softening point, the melting point, the thermal decomposition temperature, and the 5% weight loss temperature. The upper temperature limit of the organic layer 112 can be, for example, any of the above temperatures, preferably the lowest one among the temperatures.

The thickness of the insulating layer 125 is preferably greater than or equal to 3 nm and less than or equal to 200 nm, greater than or equal to 5 nm and less than or equal to 150 nm, greater than or equal to 10 nm and less than or equal to 100 nm, or greater than or equal to 10 nm and less than or equal to 50 nm, for example.

The insulating layer 125 can effectively inhibit film separation when positioned on the bottom surface of the insulating layer 106. An example of a structure in which the bottom surface of the insulating layer 106 is exposed at the time of forming the insulating layer 125 is described. For example, as illustrated in FIG. 1B, a structure in which the insulating layer 106 has a protruding portion 107 enables the insulating layer 125 to be formed at least on the bottom surface of the protruding portion 107. Note that the protruding portion 107 is a portion where the insulating layer 106 protrudes from an insulating layer 105 that is a formation surface. As illustrated in FIG. 1B, the protruding portion 107 can be obtained by providing a depressed portion 103 in the insulating layer 105. The depressed portion 103 has a top surface lower than the top surface of the insulating layer 105 and a bottom lower than the top surface of the insulating layer 105. A surface connecting the top surface of the insulating layer 105 and the bottom surface of the depressed portion 103, what is called a side surface, may be inclined. The protruding portion 107 is a portion that is at a position defining the depressed portion 103 and protrudes from an upper end of the insulating layer 105 in the direction along a formation surface of the insulating layer 106. The direction along the formation surface includes a shift from the formation surface greater than 0° and less than or equal to 20°. In such a structure, the insulating layer 125 can be in contact with at least the bottom surface of the protruding portion 107.

Here, examples of materials and formation methods of the insulating layer 105 and the insulating layer 106 are described.

As the insulating layer 105, an insulating layer including an inorganic material or an organic material can be used. As the organic material, a photosensitive organic resin is preferably used; for example, a photosensitive resin composition containing an acrylic resin is used. Note that an acrylic resin refers to not only a polymethacrylic acid ester or a methacrylic resin but also all the acrylic polymer in a broad sense in some cases.

The organic material that can be used for the insulating layer 105 is not limited to the materials given above. For the insulating layer 105, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 105, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used. As the photosensitive resin, a photoresist can be used. As the photosensitive resin, a positive photosensitive material or a negative photosensitive material can be used.

The insulating layer 105 is preferably formed by, for example, a wet process such as spin coating, dipping, spray coating, ink-jetting, dispensing, screen printing, offset printing, doctor blade coating, slit coating, roll coating, curtain coating, or knife coating. Specifically, the insulating layer 105 is preferably formed by spin coating.

As the inorganic material used for the insulating layer 105, an oxide insulating film, a nitride insulating film, an oxynitride insulating film, a nitride oxide insulating film, and the like can be used. The inorganic material that can be used for the insulating layer 105 is not limited to the above. For example, silicon oxide with good step coverage that is formed by reacting TEOS (tetraethyl-Ortho-Silicate), silane, or the like with oxygen, nitrous oxide, or the like can be used. The insulating layer 105 can be formed by a method such as thermal CVD, plasma CVD, atmospheric pressure CVD, or sputtering. For the insulating layer 105, silicon oxide formed by a low temperature oxidation (LTO) method may also be used. TEOS is preferable because it facilitates formation of the depressed portion 103.

As the insulating layer 106, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the insulating layer 106 preferably includes a nitride insulating film or a nitride oxide insulating film, and further preferably includes a nitride insulating film. The insulating layer 106 may be formed using a single layer of the above-described material or a stack of the above-described materials.

The insulating layer 106 is positioned over the insulating layer 105, and the protruding portion 107 of the insulating layer 106 is a portion protruding from the upper end of the insulating layer 105 to define the depressed portion 103. That is, the protruding portion 107 is positioned to overlap with the depressed portion 103. The protruding portion 107 preferably has a length greater than or equal to 50 nm and less than or equal to 500 nm, further preferably greater than or equal to 80 nm and less than or equal to 300 nm from the upper end of the insulating layer 105 to define the depressed portion in a cross-sectional view.

According to the structure illustrated in FIG. 1B, the insulating layer 125 further includes a region in contact with the insulating layer 105. The insulating layer 105 including the depressed portion 103 enables a region where the insulating layer 125 is in contact with the insulating layer 105 to be enlarged. Also from this perspective, film separation of the light-emitting device 110 can be effectively inhibited.

Furthermore, on the basis of the structure illustrated in FIG. 1B, the structure in which the insulating layer 105 including the depressed portion 103 and the insulating layer 125 are in contact with each other can sufficiently inhibit film separation of the light-emitting device 110. Thus, the insulating layer 106 is not necessarily provided over the insulating layer 105 in the structure illustrated in FIG. 1B.

To enhance the effect of inhibiting film separation of the light-emitting device 110, the adhesion between the insulating layer 125 and the insulating layer 106 is preferably high in FIG. 1B. For that reason, both the insulating layer 106 and the insulating layer 125 preferably include an inorganic material. Furthermore, the insulating layer 106 and the insulating layer 125 may include the same inorganic material.

To enhance the effect of inhibiting film separation of the light-emitting device 110, the adhesion between the insulating layer 125 and the insulating layer 105 is preferably high in FIG. 1B. For that reason, both the insulating layer 105 and the insulating layer 125 preferably include an inorganic material. Furthermore, the insulating layer 105 and the insulating layer 125 may include the same inorganic material.

To enhance the effect of inhibiting film separation of the light-emitting device 110, the adhesion between the insulating layer 125, the insulating layer 106, and the insulating layer 105 is preferably high in FIG. 1B. For that reason, the insulating layer 105, the insulating layer 106, and the insulating layer 125 preferably include an inorganic material. Furthermore, the insulating layer 105, the insulating layer 106, and the insulating layer 125 may include the same inorganic material.

Although FIG. 1B illustrates a structure in which an end portion of the organic layer 112 is aligned with an end portion of the lower electrode 111, the end portion of the organic layer 112 may be positioned inward from the end portion of the lower electrode 111 as in the light-emitting device 110 illustrated in FIG. 2A. The end portion of the organic layer 112 may be positioned beyond the end portion of the lower electrode 111 as in the light-emitting device 110 illustrated in FIG. 2A.

Unlike FIG. 1A and FIG. 1B, FIG. 1C and FIG. 1D each illustrate the display device 110 in which the upper electrode 113 is positioned over the organic layer 112 through an opening in the insulating layer 125. Since the other components in FIG. 1C and FIG. 1D are similar to those in FIG. 1A and FIG. 1B, the description is omitted. The insulating layer 125 covers at least a side surface of the organic layer 112 and includes a region where the insulating layer 125 is in contact with the insulating layer 106 or the insulating layer 105, whereby film separation of the light-emitting device 110 can be effectively inhibited.

Although FIG. 1C illustrates a structure in which an end portion of the organic layer 112 is aligned with an end portion of the lower electrode 111, the end portion of the organic layer 112 may be positioned inward from the end portion of the lower electrode 111. The end portion of the organic layer 112 may be positioned beyond the end portion of the lower electrode 111.

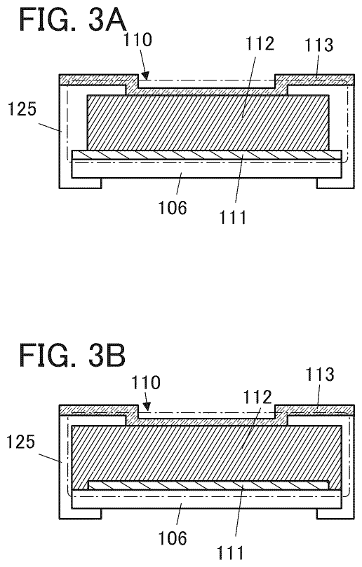

FIG. 3A illustrates the light-emitting device 110 in which an end portion of the organic layer 112 is positioned inward an end portion of the lower electrode 111 as a variation example of FIG. 1C. FIG. 3B illustrates the light-emitting device 110 in which an end portion of the organic layer 112 is positioned beyond an end portion of the lower electrode 111 as a variation example of FIG. 1C. Also in FIG. 3A and FIG. 3B, film separation of the light-emitting device 110 can be inhibited by the insulating layer 125 or the like.

Although FIG. 1D illustrates a structure in which an end portion of the organic layer 112 is aligned with an end portion of the lower electrode 111, the end portion of the organic layer 112 may be positioned inward from the end portion of the lower electrode 111 as in the light-emitting device 110 illustrated in FIG. 3A. The end portion of the organic layer 112 may be positioned beyond the end portion of the lower electrode 111 as in the light-emitting device 110 illustrated in FIG. 3B.

Unlike FIG. 1C and FIG. 1D, FIG. 1E and FIG. 1F each illustrate the display device 110 that includes a charge-generation layer 153. Since the other components in FIG. 1E and FIG. 1F are similar to those in FIG. 1A, FIG. 1B, FIG. 1C, and FIG. 1D, the description is omitted. The insulating layer 125 covers at least a side surface of the organic layer 112 and includes a region where the insulating layer 125 is in contact with the insulating layer 106 or the insulating layer 105, whereby film separation of the light-emitting device 110 can be effectively inhibited. The charge-generation layer 153 has higher conductivity than the organic layer in some cases; the charge-generation layer 153 can be prevented by the insulating layer 125 from being electrically connected to the lower electrode 111 or the upper electrode 113.

Although FIG. 1E illustrates a structure in which an end portion of the organic layer 112 is aligned with an end portion of the lower electrode 111, the end portion of the organic layer 112 may be positioned inward from the end portion of the lower electrode 111 as in the light-emitting device 110 illustrated in FIG. 3A. The end portion of the organic layer 112 may be positioned beyond the end portion of the lower electrode 111 as in the light-emitting device 110 illustrated in FIG. 3B.

Although FIG. 1F illustrates a structure in which an end portion of the organic layer 112 is aligned with an end portion of the lower electrode 111, the end portion of the organic layer 112 may be positioned inward from the end portion of the lower electrode 111 as in the light-emitting device 110 illustrated in FIG. 3A. The end portion of the organic layer 112 may be positioned beyond the end portion of the lower electrode 111 as in the light-emitting device 110 illustrated in FIG. 3B.

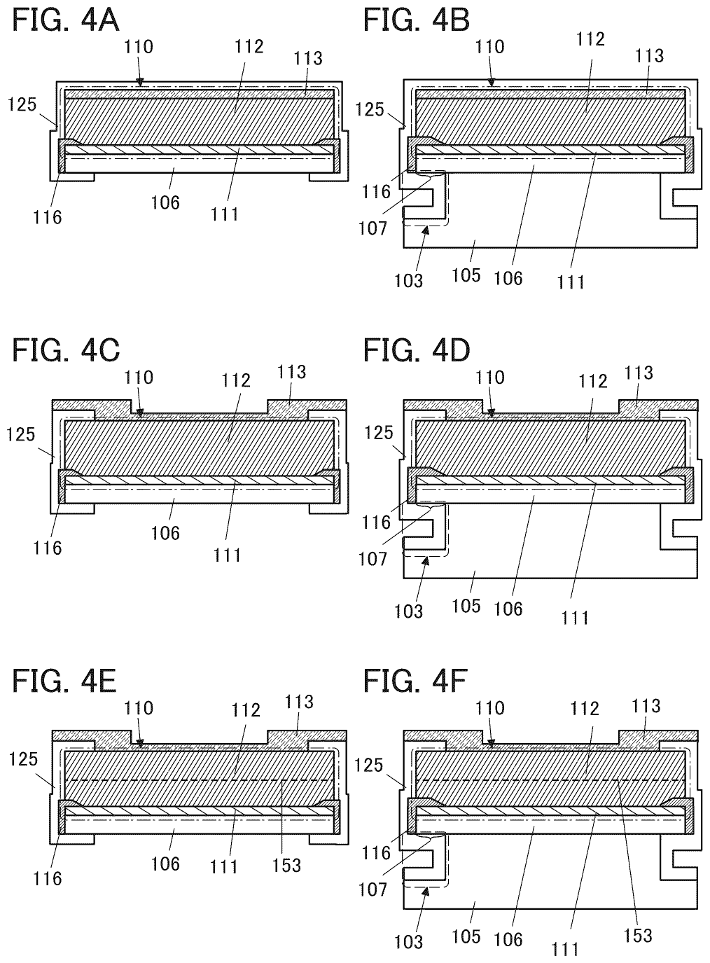

Next, the light-emitting devices 110 each of which includes an insulating layer 116 including a region overlapping with an end portion of the lower electrode 111 are described with reference to FIG. 4A to FIG. 4F. After the lower electrode 111 is formed, the insulating layer 116 is formed and an opening is formed in the insulating layer 116 so that the top surface of the lower electrode 111 is exposed. The insulating layer 116 may be referred to as a partition, a bank, or an embankment.

Here, examples of a material and a formation method of the insulating layer 116 are described.

As the insulating layer 116, an insulating layer including an inorganic material or an organic material can be used. As the organic material, a photosensitive organic resin is preferably used; for example, a photosensitive resin composition containing an acrylic resin is used. Note that an acrylic resin refers to not only a polymethacrylic acid ester or a methacrylic resin but also all the acrylic polymer in a broad sense in some cases.

The organic material that can be used for the insulating layer 116 is not limited to the materials given above. For the insulating layer 116, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 116, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used. As the photosensitive resin, a photoresist can be used. As the photosensitive resin, a positive photosensitive material or a negative photosensitive material can be used.

The insulating layer 116 is preferably formed by, for example, a wet process such as spin coating, dipping, spray coating, ink-jetting, dispensing, screen printing, offset printing, doctor blade coating, slit coating, roll coating, curtain coating, or knife coating. Specifically, the insulating layer 116 is preferably formed by spin coating.

As the inorganic material used for the insulating layer 116, an oxide insulating film, a nitride insulating film, an oxynitride insulating film, a nitride oxide insulating film, and the like can be used. The inorganic material that can be used for the insulating layer 116 is not limited to the above. For example, silicon oxide with good step coverage that is formed by reacting TEOS, silane, or the like with oxygen, nitrous oxide, or the like can be used. The insulating layer 116 can be formed by a method such as thermal CVD, plasma CVD, atmospheric pressure CVD, or sputtering. For the insulating layer 116, silicon oxide formed by a low temperature oxidation method may also be used.

In FIG. 4A to FIG. 4F, the insulating layer 125 includes a region in contact with the insulating layer 106, the insulating layer 105, or the insulating layer 116, whereby film separation of the light-emitting device 110 can be effectively inhibited.

In FIG. 4A to FIG. 4F, components other than the insulating layer 116 are similar to those in FIG. 1A to FIG. 1F. Note that as illustrated in FIG. 4E and FIG. 4F, the insulating layer 116 is formed in the light-emitting device 110 including the charge-generation layer 153, whereby the charge-generation layer 153 and the lower electrode 111 can be inhibited from being in contact with each other.

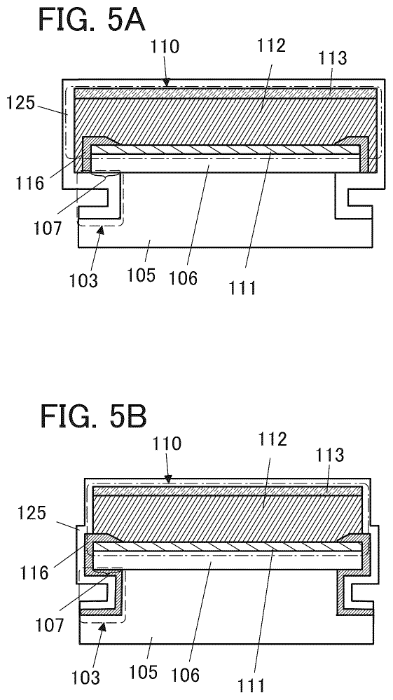

Although FIG. 4A and FIG. 4B each illustrate a structure in which an end portion of the organic layer 112 overlaps with the top surface of the insulating layer 116, the end portion of the organic layer 112 may be positioned beyond an end portion of the insulating layer 116. FIG. 5A illustrates the light-emitting device 110 in which an end portion of the organic layer 112 is positioned beyond an end portion of the insulating layer 116 as a variation example of FIG. 4B.

Although FIG. 4A and FIG. 4B each illustrate a structure in which the bottom surface of the insulating layer 116 is aligned with the bottom surface of the insulating layer 106, the insulating layer 116 may be provided also in the depressed portion 103. FIG. 5B illustrates the light-emitting device 110 in which the insulating layer 116 is provided also in the depressed portion 103 as a variation example of FIG. 4B.

Also in FIG. 5A and FIG. 5B, film separation of the light-emitting device 110 can be inhibited by the insulating layer 125 or the like.

The light-emitting devices 110 illustrated in FIG. 1A to FIG. 5B can be any one of a red-light-emitting device, a green-light-emitting device, and a blue-light-emitting device through a lithography process. That is, in the display device of one embodiment of the present invention, an SBS structure can be applied to the light-emitting device 110; thus, a display device with a wide viewing angle in which crosstalk is inhibited can be provided. The SBS structure is preferred to the structure in which a white-light-emitting element and coloring layers (color filters) are used because an optimal material of the organic layer can be used for each of the light-emitting devices 110 and an optimal stacking order or the like of the organic layer can be employed for each of the light-emitting devices 110.

Note that in FIG. 1A to FIG. 5B, the light-emitting device 110 may be manufactured using a metal mask or the like as long as film separation of the light-emitting device 110 can be effectively inhibited. That is, an MM structure may be applied to the light-emitting device 110. The SBS structure may also be applied to a light-emitting device having an MM structure.

### [Display Device 100A]

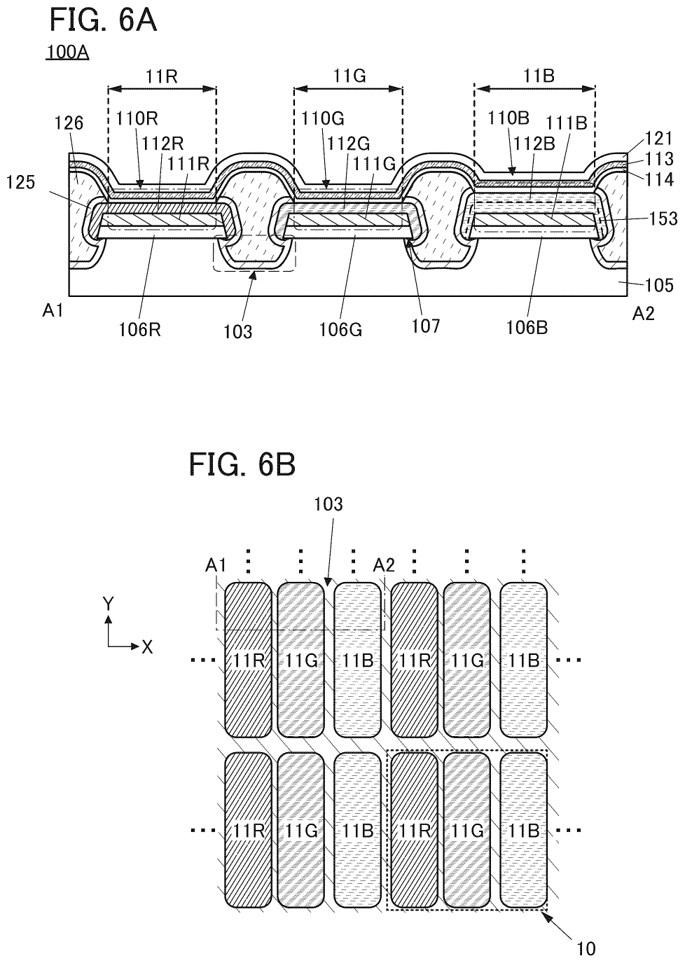

Next, a display device 100A in which a plurality of light-emitting devices are provided will be described with reference to FIG. 6 and the like.

Note that the SBS structure is applied to the light-emitting device in the display device 100A. Furthermore, in the display device 100A, the organic layer is optimized for each of the light-emitting devices. Specifically, in the display device 100A, both a light-emitting device with a single structure and a light-emitting device with a tandem structure are provided. The color of light emitted from the light-emitting device with a single structure is not particularly limited, and the color of light emitted from the light-emitting device with a tandem structure is not particularly limited either. The light-emitting device with a tandem structure may be a light-emitting device with the lowest reliability. For example, in the case where a blue-light-emitting device has the lowest reliability, a tandem structure is applied to at least the blue-light-emitting device, and a single structure is applied to either one of a green-light-emitting device and a red-light-emitting device. In the case where the green-light-emitting device has the lowest reliability, a tandem structure is applied to at least the green-light-emitting device, and a single structure is applied to either one of the blue-light-emitting device and the red-light-emitting device.

The display device 100A illustrated in FIG. 6A is an example in which a red-light-emitting device 110R is included as a first light-emitting device, a green-light-emitting device 110G is included as a second light-emitting device, a blue-light-emitting device 110B is included as a third light-emitting device, a tandem structure is applied to the blue-light-emitting device 110B, and a single structure is applied to the red-light-emitting device 110R and the green-light-emitting device 110G.

Here, the blue-light-emitting device is described. The blue-light-emitting device with a single structure has a shorter emission lifetime than the red-light-emitting device and the green-light-emitting device with a single structure in some cases. A short emission lifetime leads to low reliability of the display device. Furthermore, a tandem structure needs a smaller amount of current for obtaining luminance comparable to a single structure, and thus can extend emission lifetime. Thus, when the tandem structure is applied to the blue-light-emitting device and the single structure is applied to the red-light-emitting device and the green-light-emitting device, a difference in emission lifetime is suppressed. Note that even when the single structure is applied only to the red-light-emitting device and the tandem structure is applied to the blue-light-emitting device and the green-light-emitting device, a difference in emission lifetime can be suppressed.

An organic layer 112R included in the red-light-emitting device 110R, an organic layer 112G included in the green-light-emitting device 110G, and an organic layer 112B included in the blue-light-emitting device 110B, which are illustrated in FIG. 6A, include at least light-emitting layers separately formed by a lithography process. That is, the MML structure and the SBS structure are applied to the red-light-emitting device 110R, the green-light-emitting device 110G, and the blue-light-emitting device 110B, so that effects of the MML structure and the SBS structure can be obtained.

FIG. 6A illustrates a subpixel 11R, a subpixel 11G, and a subpixel 11B that correspond to emission regions of the red-light-emitting device 110R, the green-light-emitting device 110G, and the blue-light-emitting device 110B, respectively.

The structures described above with reference to FIG. 1D, FIG. 5B, and the like are applied to the display device 100A, to sufficiently inhibit film separation of the red-light-emitting device 110R, the green-light-emitting device 110G, and the blue-light-emitting device 110B. Note that in this embodiment and the like, in the case where the organic layer 112R, the organic layer 112G, and the organic layer 112B do not need to be distinguished from each other, the “organic layer 112” may be used in the description and that in the case where the red-light-emitting device 110R, the green-light-emitting device 110G, and the blue-light-emitting device 110B do not need to be distinguished from each other, the “light-emitting device 110” may be used in the description.

As illustrated in FIG. 6A, the red-light-emitting device 110R is positioned over an insulating layer 106R. The green-light-emitting device 110G is positioned over an insulating layer 106G. The blue-light-emitting device 110B is positioned over an insulating layer 106B. The insulating layer 106R, the insulating layer 106G, and the insulating layer 106B are insulating layers formed through the same process and may be collectively referred to as the insulating layer 106. Note that the display device 100A does not necessarily include the insulating layer 106.

The display device 100A illustrated in FIG. 6A may include the insulating layer 116 that overlaps with an end portion of the lower electrode 111 and functions as a partition, a bank, or an embankment. Although a structure in which the insulating layer 116 is provided is not illustrated in FIG. 6, the insulating layer 116 is preferably combined with the blue-light-emitting device 110B with a tandem structure. This is because the insulating layer 116 can inhibit the charge-generation layer 153 included in the tandem structure from being in contact with the lower electrode 111B. Needless to say, the insulating layer 116 may be used in all the light-emitting devices.

The display device 100A illustrated in FIG. 6A includes the insulating layer 125 covering the organic layer 112 included in the light-emitting device 110, and the insulating layer 125 includes a region in contact with the insulating layer 106 or the insulating layer 105. The insulating layer 125 further preferably includes a region in contact with the insulating layer 106 and the insulating layer 105. The insulating layer 125 can effectively inhibit film separation of the light-emitting device 110.

In the display device 100A illustrated in FIG. 6A, the insulating layer 106 includes the protruding portion 107. As long as the insulating layer 125 can be in contact with the bottom surface of the protruding portion 107, film separation of the light-emitting device 110 can be effectively inhibited.

The insulating layer 105 includes the depressed portion 103 so that the protruding portion 107 is formed. The depressed portion 103 is described with reference to a plan view illustrated in FIG. 6B in addition to FIG. 6A. In the plan view, the X direction and the Y direction intersecting with the X direction are shown. FIG. 6A is a cross-sectional view corresponding to A1-A2 along the X direction in FIG. 6B.

According to FIG. 6A and FIG. 6B, the depressed portion 103 is positioned between the subpixel 11R and the subpixel 11G and between the subpixel 11G and the subpixel 11B. Note that the maximum width of the depressed portion 103 formed below the lower electrode 111 may be larger than the distance between the subpixel 11R and the subpixel 11G as illustrated in FIG. 6A.

The depressed portion 103 is preferably laid out in a lattice shape in a plan view. Specifically, the depressed portion 103 is positioned to surround the subpixel 11R, positioned to surround the subpixel 11G, and positioned to surround the subpixel 11B in the plan view illustrated in FIG. 6B. Since the insulating layer 125 can include a region in contact with the insulating layer 106 along the depressed portion 103, the depressed portion 103 provided in a lattice shape can effectively inhibit film separation of the light-emitting device 110, which is preferable.

When the insulating layer 125 is formed by an ALD method, the insulating layer 125 can be provided along a side surface of the organic layer 112 and the shape of the depressed portion 103 as illustrated in FIG. 6A. The insulating layer 125 along the depressed portion 103 can have a large area in contact with the insulating layer 105. Such a structure enables film separation of the light-emitting device 110 to be effectively inhibited.

Moreover, when the insulating layer 125 is formed by an ALD method, a depressed portion along the depressed portion 103 may be defined by a surface of the insulating layer 125. Thus, the display device 100A has a structure in which the depressed portion defined by the insulating layer 125 is filled with the insulating layer 126. An organic material is preferably used for the insulating layer 126, in which case a surface of the insulating layer 126 can be flat in a region overlapping with the depressed portion 103. As illustrated in FIG. 6A, the surface of the insulating layer 126 in the region overlapping with the depressed portion 103 can be positioned higher than the top surface of the organic layer 112. The insulating layer 126 with such a shape can inhibit disconnection of a common layer 114 or a common electrode due to the depressed portion.

Next, structures of the red-light-emitting device 110R, the green-light-emitting device 110G, and the blue-light-emitting device 110B included in the display device 100A are described.

The red-light-emitting device 110R includes a lower electrode 111R and the upper electrode 113 in a position facing the lower electrode 111R. The green-light-emitting device 110G includes a lower electrode 111G and the upper electrode 113 in a position facing the lower electrode 111G. The blue-light-emitting device 110B includes a lower electrode 111B and the upper electrode 113 in a position facing the lower electrode 111B. The upper electrode 113 can be shared by the red-light-emitting device 110R, the green-light-emitting device 110G, and the blue-light-emitting device 110B. The layer shared by the light-emitting devices may be referred to as a common layer, and the common layer may be referred to as a common electrode when having a function of an electrode. That is, the upper electrode 113 may be referred to as a common electrode. The insulating layer 126 can inhibit disconnection of the common layer 114 or the upper electrode 113 that is a common electrode.

The red-light-emitting device 110R includes the organic layer 112R between the lower electrode 111R and the upper electrode 113. It is preferable that the organic layer 112R include at least one light-emitting layer and have what is called a single structure. The organic layer 112R can be formed to be positioned beyond the lower electrode 111R; FIG. 6A illustrates the case where the organic layer 112R is formed on a side surface of the lower electrode 111R and a side surface of the insulating layer 106R. As the organic layer included in the red-light-emitting device 110R, an electron-injection layer is given in addition to a light-emitting layer; the electron-injection layer may be the common layer 114. Needless to say, a layer other than the electron-injection layer may be the common layer 114.

The organic layer 112R can be formed by, for example, a vacuum evaporation method after the depressed portion 103 is formed, and then is processed by a lithography process. As described above, the organic layer 112R may be positioned on the side surface of the lower electrode 111R and may further be positioned on the side surface of the insulating layer 106R. FIG. 6A illustrates a structure in which the side surface of the insulating layer 106R has a tapered shape and the side surface of the lower electrode 111R also has a tapered shape; the organic layer 112R is easily formed on the side surface with a tapered shape. Furthermore, although not illustrated in FIG. 6A, an end portion of the lower electrode 111R may be positioned inward from an end portion of the insulating layer 106R. When the end portion of the lower electrode 111R is positioned inward from the end portion of the insulating layer 106R, the organic layer 112R may also be formed on part of the top surface of the insulating layer 106R.

Note that in this specification and the like, a tapered shape refers to a shape in which at least part of a side surface of a component is inclined to a formation surface, for example, the top surface of a substrate. The tapered shape refers to a shape including a region where the angle between the inclined side surface and the substrate surface (also referred to as a taper angle) is less than 90°.

The green-light-emitting device 110G includes the organic layer 112G between the lower electrode 111G and the upper electrode 113. It is preferable that the organic layer 112G include at least one light-emitting layer and have what is called a single structure. The organic layer 112G can be formed to be positioned beyond the lower electrode 111G; FIG. 6A illustrates the case where the organic layer 112G is formed on a side surface of the lower electrode 111G and a side surface of the insulating layer 106G. As the organic layer included in the green-light-emitting device 110G, an electron-injection layer is given in addition to a light-emitting layer; the electron-injection layer may be the common layer 114. Needless to say, a layer other than the electron-injection layer may be the common layer 114.

The organic layer 112G can be formed after the depressed portion 103 is formed by a vacuum evaporation method, for example, and then is processed by a lithography process. As described above, the organic layer 112G may be positioned on the side surface of the lower electrode 111G and may further be positioned on the side surface of the insulating layer 106G. FIG. 6A illustrates a structure in which the side surface of the insulating layer 106G has a tapered shape and the side surface of the lower electrode 111G also has a tapered shape; the organic layer 112G is easily formed on the side surface with a tapered shape. Furthermore, although not illustrated in FIG. 6A, an end portion of the lower electrode 111G may be positioned inward from an end portion of the insulating layer 106G. When the end portion of the lower electrode 111G is positioned inward from the end portion of the insulating layer 106G, the organic layer 112G may also be formed on part of the top surface of the insulating layer 106G.

The blue-light-emitting device 110B includes the organic layer 112B between the lower electrode 111B and the upper electrode 113. It is preferable that the organic layer 112B include at least two light-emitting layers and the charge-generation layer 153 therebetween and have what is called a tandem structure. The organic layer 112B can be formed to be positioned beyond the lower electrode 111B; FIG. 6A illustrates the case where the organic layer 112B is formed on a side surface of the lower electrode 111B and a side surface of the insulating layer 106B. As the organic layer included in the blue-light-emitting device 110B, an electron-injection layer is given in addition to a light-emitting layer; the electron-injection layer may be the common layer 114. Needless to say, a layer other than the electron-injection layer may be the common layer 114.

The organic layer 112B can be formed after the depressed portion 103 is formed by a vacuum evaporation method, for example, and then is processed by a lithography process. As described above, the organic layer 112B may be positioned on the side surface of the lower electrode 111B and may further be positioned on the side surface of the insulating layer 106B. FIG. 6A illustrates a structure in which the side surface of the insulating layer 106B has a tapered shape and the side surface of the lower electrode 111B also has a tapered shape; the organic layer 112B is easily formed on the side surface with a tapered shape. Furthermore, although not illustrated in FIG. 6A, an end portion of the lower electrode 111B may be positioned inward from an end portion of the insulating layer 106B. When the end portion of the lower electrode 111B is positioned inward from the end portion of the insulating layer 106B, the organic layer 112B may also be formed on part of the top surface of the insulating layer 106B.

Since the electron-injection layer that serves as the common layer can be positioned above the insulating layer 126, the electron-injection layer can be inhibited by the insulating layer 126 from being disconnected between adjacent light-emitting devices.

A protective layer 121 is preferably provided over the upper electrode 113. The protective layer 121 can also be a common layer. Since the protective layer 121 can also be positioned above the insulating layer 126, the protective layer 121 can be inhibited by the insulating layer 126 from being disconnected between adjacent light-emitting devices.

An example of the above-described film separation of the light-emitting device 110 includes separation of each of the organic layer 112R, the organic layer 112G, and the organic layer 112B from the lower electrode 111. In the display device 100A, separation of each of the organic layer 112R, the organic layer 112G, and the organic layer 112B from the lower electrode 111 can be sufficiently inhibited.

Although not illustrated in FIG. 6 and the like, a color filter or a color conversion layer may be used in combination with an SBS structure. The color filter or the color conversion layer is positioned to overlap with the light-emitting device and may be provided for all of the light-emitting devices or for only one of the light-emitting devices, for example, the blue-light-emitting device.

The color filter has a function of transmitting light in a specific wavelength range (typically red, green, or blue). Transmitting light in a specific wavelength range refers to a state where light transmitted through a color filter has a peak at the wavelength corresponding to the specific color. For example, a red color filter for transmitting light in a red wavelength range, a green color filter for transmitting light in a green wavelength range, and a blue color filter for transmitting light in a blue wavelength range are given.

The color filters can be formed in desired positions using any of various materials such as a chromatic light-transmitting resin by a printing method, an ink-jet method, an etching method using a photolithography method, or the like. A photosensitive organic resin or a non-photosensitive organic resin can be used as the chromatic light-transmitting resin; a photosensitive organic resin is preferably used, in which case the number of resist masks used in the etching can be reduced and the process can be accordingly simplified.

Chromatic colors are colors except achromatic colors such as black, gray, and white; specifically, red, green, blue, or the like can be used. The colors of the color filters may be cyan, magenta, yellow, or the like.

The thickness of each of the color filters can be greater than or equal to 500 nm and less than or equal to 5 μm.

The use of the color filters can eliminate the need for an optical element such as a circularly polarizing plate or a polarizing plate provided in the display device 100A.

For the color conversion layer, a fluorescent material or a quantum dot (QD) is preferably used. A quantum dot has an emission spectrum with a narrow peak, so that emission with high color purity can be obtained.

### [Display Device 100B]

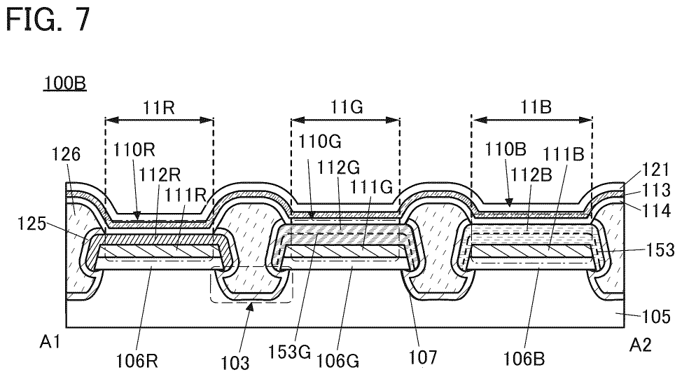

Next, a display device 100B in which a plurality of light-emitting devices are provided will be described with reference to FIG. 7 and the like. Note that the display device 100B has a structure in which the green-light-emitting device 110G and the blue-light-emitting device 110B have a tandem structure and the red-light-emitting device 110R has a single structure, for example. The display device 100B differs from the display device 100A in the structure and is similar to the display device 100A in the other structures. The green-light-emitting device 110G having a tandem structure includes a charge-generation layer 153G like the blue-light-emitting device 110B.

In the display device 100B, a light-emitting device having a single structure and a light-emitting device having a tandem structure can be provided together; the light-emitting device having a tandem structure may be a light-emitting device with low reliability and two or more light-emitting devices may employ a tandem structure. Specifically, a tandem structure may be applied to the green-light-emitting device and the blue-light-emitting device, and a single structure may be applied to the red-light-emitting device.

Furthermore, in the display device 100B, separation of each of the organic layer 112R, the organic layer 112G, and the organic layer 112B from the lower electrode 111 can be sufficiently inhibited as in the display device 100A.

### [Display Device 100C]

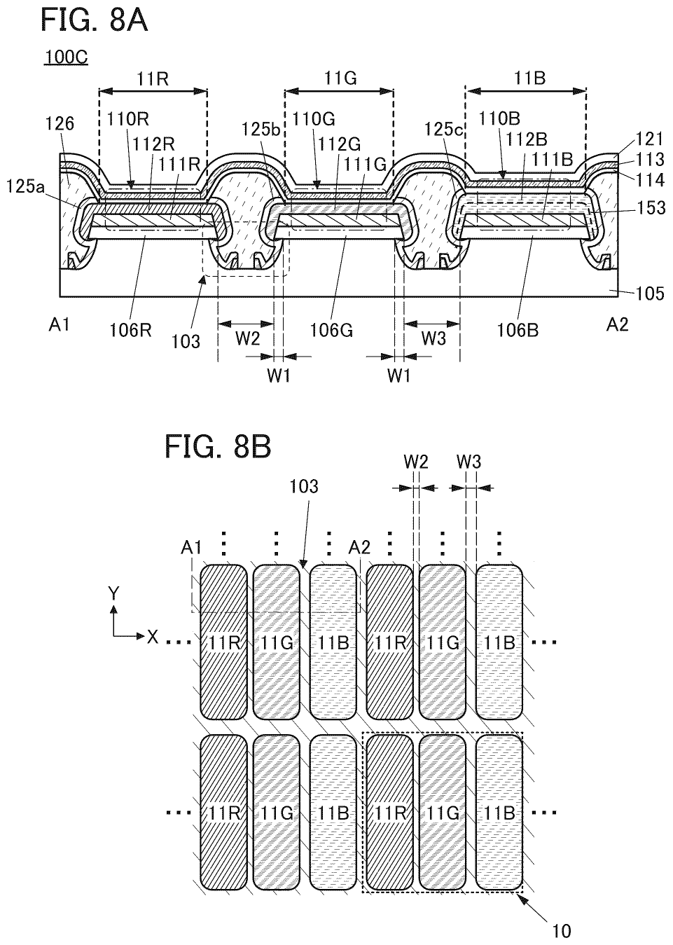

Next, a display device 100C in which a plurality of light-emitting devices are provided will be described with reference to FIG. 8 and the like. Note that the display device 100C has a structure in which part of an organic layer remains in the depressed portion 103, and the like. The display device 100C differs from the display device 100A in the structure and is similar to the display device 100A in the other structures.

As illustrated in FIG. 8A, the organic layer 112 can be disconnected with use of the depressed portion 103 in the display device 100C. After that, the organic layer 112 is processed by a lithography step. Then, part of the organic layer 112R, part of the organic layer 112G, and part of the organic layer 112B remain in the depressed portion 103. In the depressed portion 103, the remaining part of the organic layer 112R is preferably covered with an insulating layer 125a corresponding to the insulating layer 125. In the depressed portion 103, the remaining part of the organic layer 112G is preferably covered with an insulating layer 125b corresponding to the insulating layer 125. In the depressed portion 103, the remaining part of the organic layer 112B is preferably covered with an insulating layer 125c corresponding to the insulating layer 125.

Since the insulating layers 125a, 125b, and 125c in the display device 100C each include a region in contact with the bottom surface of the insulating layer 106, separation of each of the organic layer 112R, the organic layer 112G, and the organic layer 112B can be inhibited.

Width W1 shown in FIG. 8A is a length of a protruding portion of the lower electrode 111G in the X direction along the direction in which the subpixels 11R, 11G, and 11B are arranged, i.e., a width of a region where the lower electrode 111G overlaps with the depressed portion 103. In the case where a side surface of the lower electrode 111G has a tapered shape, the width W1 is preferably defined using a lower end of the lower electrode 111G. Although the width W1 is described using the lower electrode 111G, the width W1 can be understood by replacing the lower electrode 111G with the lower electrode 111B. In addition, the width W1 can be understood by replacing the lower electrode 111G with the lower electrode 111R.

Width W2 shown in FIG. 8A is a width of the depressed portion 103 in a region overlapping with neither the lower electrode 111R nor the lower electrode 111G in the X direction along the direction in which the subpixels 11R, 11G, and 11B are arranged. The width W2 is also shown in a plan view of FIG. 8B. According to FIG. 8A and the like, the width W2 can be rephrased as the shortest distance between the insulating layer 106G and the insulating layer 106R adjacent to each other in the display device 100C. In the case where a side surface of the insulating layer 106G or a side surface of the insulating layer 106R has a tapered shape, the width W2 is preferably defined using a lower end of the insulating layer 106G or a lower end of the insulating layer 106R. If the side surface of the insulating layer is not tapered, the width W2 can be rephrased as the shortest distance between the lower electrode 111G and the lower electrode 111R adjacent to each other in the display device 100C. In the case where a side surface of the lower electrode 111G or a side surface of the lower electrode 111R has a tapered shape, the width W2 is preferably defined using a lower end of the lower electrode 111G or a lower end of the lower electrode 111R.

Width W3 shown in FIG. 8A is a width of the depressed portion 103 in a region overlapping with neither the lower electrode 111G nor the lower electrode 111B in the X direction along the direction in which the subpixels 11R, 11G, and 11B are arranged. The width W3 is also shown in a plan view of FIG. 8B. The width W3 can be rephrased as the shortest distance between the lower electrode 111B and the lower electrode 111G adjacent to each other in the display device 100C. In the case where a side surface of the lower electrode 111B or a side surface of the lower electrode 111G has a tapered shape, the width W3 is preferably defined using a lower end of the lower electrode 111B or a lower end of the lower electrode 111G. Although the width W3 is described using the lower electrode 111B and the lower electrode 111G, the width W3 can be understood by replacing the lower electrode 111G with the lower electrode 111R.

The width W1 may be a width causing the organic layer 112G to be disconnected and allowing the insulating layer 125 to be in contact with the bottom surface of the insulating layer 106G. The lower limit of the width W1 is preferably greater than or equal to 2 nm, greater than or equal to 5 nm, greater than or equal to 10 nm, or greater than or equal to 20 nm, and the upper limit of the width W1 is preferably less than or equal to 500 nm, less than or equal to 300 nm, less than or equal to 200 nm, less than or equal to 150 nm, or less than or equal to 100 nm. The lower limit and the upper limit of the width W1 can be selected from the values given above.

The width W2 is preferably larger than twice the overall thickness of the organic layer 112G. In the case where the overall thickness of the organic layer 112G is 100 nm, for example, the width W2 is greater than or equal to 200 nm and less than or equal to 1200 nm, preferably greater than or equal to 200 nm and less than or equal to 1000 nm, further preferably greater than or equal to 200 nm and less than or equal to 900 nm. This causes the organic layer 112G to be disconnected due to the depressed portion 103. This may be referred to as disconnection caused in the organic layer 112G. Then, the organic layer 112G can be formed over the lower electrode 111G. In that case, the organic layer 112G is formed to cover the side surface of the lower electrode 111G as illustrated in FIG. 8A.

Note that the width W2 is preferably adjusted as appropriate in accordance with the processing accuracy at the time of forming the depressed portion 103, the deposition conditions of the organic layer 112G, and the like. In the case where the organic layer 112G is formed by a vacuum evaporation method, for example, disconnection of the organic layer 112G might occur even when the width W2 is smaller than twice the thickness of the organic layer 112G. For example, in the case where the thickness of the organic layer 112G is 100 nm, the lower limit of the width W2 may be greater than or equal to 100 nm. The upper limit of the width W2 can be selected from the values described in the case where the width W2 is larger than twice the thickness of the organic layer 112G.

The width W3 is preferably larger than twice the overall thickness of the organic layer 112B. In the case where the overall thickness of the organic layer 112B is 150 nm, for example, the width W3 is greater than or equal to 300 nm and less than or equal to 1200 nm, preferably greater than or equal to 300 nm and less than or equal to 1000 nm, further preferably greater than or equal to 300 nm and less than or equal to 900 nm. This causes the organic layer 112B to be disconnected due to the depressed portion 103, and the organic layer 112B can be formed over the lower electrode 111B. In that case, the organic layer 112B is formed to cover the side surface of the lower electrode 111B as illustrated in FIG. 8A.

Note that the width W3 is preferably adjusted as appropriate in accordance with the processing accuracy at the time of forming the depressed portion 103, the deposition conditions of the organic layer 112B, and the like. In the case where the organic layer 112B is formed by a vacuum evaporation method, for example, disconnection of the organic layer 112B might occur even when the width W3 is smaller than twice the thickness of the organic layer 112B. For example, in the case where the thickness of the organic layer 112B is 150 nm, the lower limit of the width W3 may be greater than or equal to 150 nm. The upper limit of the width W3 can be selected from the values described in the case where the width W3 is larger than twice the thickness of the organic layer 112B.

As illustrated in the plan view of FIG. 8B, the width W2 is preferably smaller than the width W3 in the display device 100C. In the above range satisfying the upper limit of the width W2, the width W2 may be the same as the width W3 in the display device 100C.

A display device with extremely high resolution can be achieved with the above-described structure in which the organic layer 112 is disconnected with use of the depressed portion 103, and the like. For example, pixels can be arranged with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

In the display device C, a tandem structure may be applied to the green-light-emitting device 110G as in the display device B.

### [Display Device 100D]

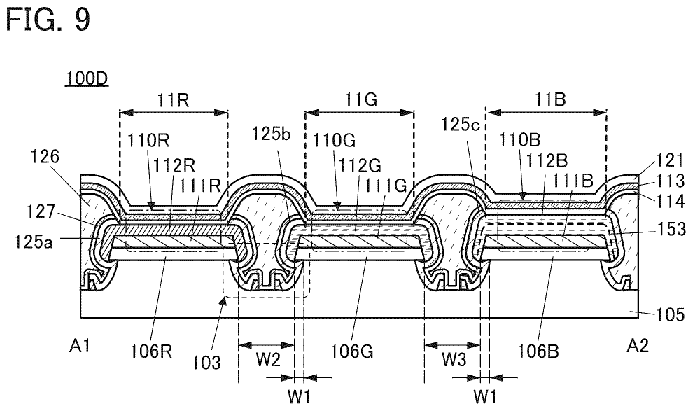

Next, a display device 100D in which a plurality of light-emitting devices are provided will be described with reference to FIG. 9 and the like. Note that the display device 100D has a structure in which an insulating layer 127 is provided in the depressed portion 103, for example. The display device 100D differs from the display device 100C in the structure and is similar to the display device 100C in the other structures.

As illustrated in FIG. 9, the display device 100D includes the insulating layer 127 positioned over the insulating layers 125a, 125b, and 125c. As described in the case of the display device 100C, when the organic layer 112 is processed by a lithography process, part of the organic layer 112R, part of the organic layer 112G, and part of the organic layer 112B remain in the depressed portion 103 and side surfaces of the remaining organic layers 112 are exposed by the lithography process. Due to such an exposed surface, the organic layer 112 is separated from the depressed portion 103 in some cases. The display device 100D has a structure in which the insulating layer 127 covers the organic layer 112 to inhibit separation of the organic layer 112.

A display device with extremely high resolution can be achieved with the above-described structure in which the organic layer 112 is disconnected with use of the depressed portion 103, and the like. For example, pixels can be arranged with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

In the display device D, a tandem structure may be applied to the green-light-emitting device 110G as in the display device B.

### [Manufacturing Method Example]

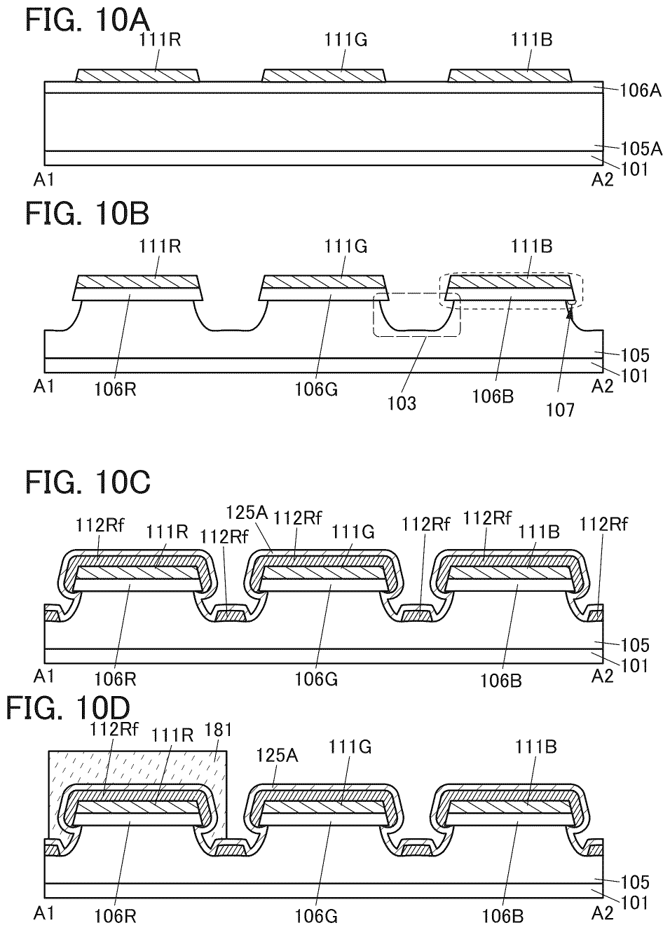

A method for manufacturing the display device 100D illustrated in FIG. 9 will be described with reference to FIG. 10 to FIG. 13.

Note that thin films that constitute the display device (e.g., insulating films, semiconductor films, and conductive films) can be formed by a sputtering method, a CVD method, a vacuum evaporation method, a PLD method, an ALD method, or the like. Examples of the CVD method include a plasma-enhanced chemical vapor deposition (PECVD: Plasma Enhanced CVD) method and a thermal CVD method. An example of the thermal CVD method is a metal organic chemical vapor deposition (MOCVD: Metal Organice CVD) method.

Alternatively, thin films that constitute the display device (e.g., insulating films, semiconductor films, and conductive films) can be formed by a wet process such as spin coating, dipping, spray coating, ink-jetting, dispensing, screen printing, offset printing, a doctor knife method, slit coating, roll coating, curtain coating, or knife coating.

When the thin films that constitute the display device are processed, a lithography method or the like can be used for the processing. Besides, a nanoimprinting method, a sandblasting method, a lift-off method, or the like may be used to process the thin films. Alternatively, island-shaped thin films may be directly formed by a deposition method using a shielding mask such as a metal mask.

There are the following two typical examples of a lithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light for light exposure in a lithography method, it is possible to use light with an i-line (wavelength: 365 nm), light with a g-line (wavelength: 436 nm), light with an h-line (wavelength: 405 nm), or combined light of any of them. Alternatively, ultraviolet rays, KrF laser light, ArF laser light, or the like can be used. Light exposure may be performed by liquid immersion exposure technique. As the light used for the light exposure, extreme ultraviolet (EUV) light or X-rays may be used. Furthermore, instead of the light used for the light exposure, an electron beam can also be used. Extreme ultraviolet light, X-rays, or an electron beam is preferably used, in which case extremely minute processing can be performed. Note that a photomask is not needed when light exposure is performed by scanning with a beam such as an electron beam.

For processing of the thin film, a dry etching method, a wet etching method, a sandblasting method, or the like can be used. Note that the resist mask can be removed by dry etching treatment such as ashing, wet etching treatment, wet etching treatment after dry etching treatment, or dry etching treatment after wet etching treatment.

For the planarization treatment of the thin film, typically, a polishing method such as a chemical mechanical polishing (CMP) method can be suitably used. Alternatively, dry etching treatment or plasma treatment may be used. Note that polishing treatment, dry etching treatment, or plasma treatment may be performed a plurality of times, or these treatments may be performed in combination. In the case where the treatments are performed in combination, the order of steps is not particularly limited and may be set as appropriate depending on the roughness of the surface to be processed.

In order to accurately process the thin film to have a desired thickness, for example, the CMP method is employed. In that case, first, polishing is performed at a constant processing rate until part of the top surface of the thin film is exposed. After that, polishing is performed under a condition with a lower processing rate until the thin film has a desired thickness, so that highly accurate processing can be performed.

Examples of a method for detecting the end of the polishing include an optical method in which the surface to be processed is irradiated with light and a change in the reflected light is detected; a physical method in which a change in the polishing resistance received by the processing apparatus from the surface to be processed is detected; and a method in which a magnetic line is applied to the surface to be processed and a change in the magnetic line due to the generated eddy current is used.

After the top surface of the thin film is exposed, polishing treatment is performed under a condition with a low processing rate while the thickness of the thin film is monitored by an optical method using a laser interferometer or the like, whereby the thickness of the thin film can be controlled with high accuracy. Note that the polishing treatment may be performed a plurality of times until the thin film has a desired thickness, as necessary.

### [Preparation for Substrate 101]

As illustrated in FIG. 10A, a substrate 101 is prepared. As the substrate 101, a substrate having at least heat resistance high enough to withstand the following heat treatment can be used. In the case where an insulating substrate is used as the substrate 101, a glass substrate, a quartz substrate, a sapphire substrate, a ceramic substrate or the like can be used. Alternatively, a single crystal semiconductor substrate or a polycrystalline semiconductor substrate using silicon or silicon carbide as a material, a compound semiconductor substrate of silicon germanium or the like, or a semiconductor substrate such as an SOI substrate can be used as the substrate 101.

As the substrate 101, it is preferable to use the insulating substrate where a semiconductor circuit including a semiconductor element such as a transistor is formed. As the substrate 101, the semiconductor substrate where a semiconductor circuit including a semiconductor element such as a transistor is formed may be used. Examples of the semiconductor circuit include a pixel circuit and a driver circuit (a gate driver and a source driver). The pixel circuit includes a semiconductor element for driving a light-emitting device positioned in a subpixel, a switching element for driving the semiconductor element, and the like. The driver circuit is a control circuit for supplying an electric signal for driving the semiconductor element or the switching element. In addition to the above circuits, an arithmetic circuit, a memory circuit, or the like may be used as the semiconductor circuit.

### [Formation of Insulating Layer 105, Insulating Layer 106, and Lower Electrode 111]

As illustrated in FIG. 10A, an insulating film 105A to be the insulating layer 105 and an insulating film 106A to be the insulating layers 106R, 106G, and 106B are formed in this order over the substrate 101. Note that in this specification and the like, a state after formation is referred to as an insulating film and a state after processing is referred to as an insulating layer. A wiring layer included in the semiconductor circuit, a wiring layer that allows connection to the semiconductor circuit, or the like may be formed in the insulating film 105A.

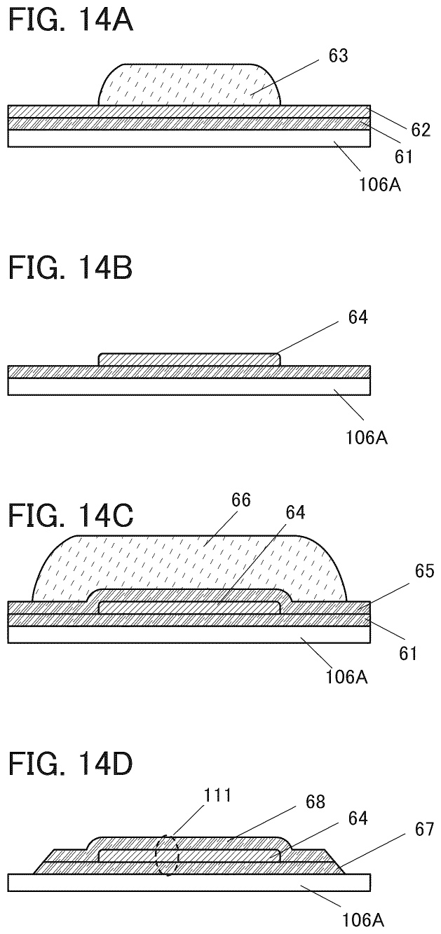

Next, the lower electrodes 111R, 111G, and 111B are formed over the insulating film 106A. The lower electrodes 111R, 111G, and 111B are referred to as the lower electrode 111 without being distinguished from each other; an example of a process of obtaining the lower electrode 111 will be described in detail with reference to FIG. 14A to FIG. 14D.

As illustrated in FIG. 14A, a first conductive film 61 is formed over the insulating film 106A. The first conductive film 61 can be formed using a material selected from materials given later as the lower electrode; for example, ITO, ITSO, or the like is preferably used.

A second conductive film 62 is formed over the first conductive film 61. The second conductive film 62 can be formed by selecting a material from materials given later as the lower electrode; for example, an alloy of silver, palladium, and copper (also referred to as Ag—Pd—Cu or APC) or the like is preferably used. The second conductive film 62 enables the lower electrode to have reflectivity.

For processing of the second conductive film 62, a resist mask 63 is formed. For the resist mask 63, a resist material containing a photosensitive resin such as a positive type resist material or a negative type resist material can be used. The second conductive film 62 can be processed by a wet etching method or a dry etching method. In the case where APC is used as the second conductive film 62, a wet etching method is preferably used.

After that, the resist mask 63 is removed, so that so that a conductive layer 64 formed by processing can be obtained as illustrated in FIG. 14B.

Next, as illustrated in FIG. 14C, a third conductive film 65 is formed over the conductive layer 64. The third conductive film 65 can be formed by selecting a material from materials given later as the lower electrode and is preferably formed using the same material as the first conductive film 61; for example, ITO, ITSO, or the like is used. When the third conductive film 65 is formed using the same material as the first conductive film 61, the adhesion between the first conductive film 61 and the third conductive film 65 is improved; thus, the conductive layer 64 positioned therebetween can be inhibited from being exposed to an etchant. In other words, processing damage to the conductive layer 64 can be suppressed.

To process the first conductive film 61 and the third conductive film 65, a resist mask 66 is formed. For the resist mask 66, a resist material containing a photosensitive resin such as a positive type resist material or a negative type resist material can be used. Although the first conductive film 61 and the third conductive film 65 can be processed by a wet etching method or a dry etching method, a wet etching method is preferably used. When the first conductive film 61 and the third conductive film 65 include the same material, the first conductive film 61 and the third conductive film 65 can be processed without changing the conditions of a wet etching method.

After that, the resist mask 66 is removed, so that a conductive layer 67 and a conductive layer 68 processed as illustrated in FIG. 14D can be obtained. It is preferable that end portions of the conductive layer 67 and the conductive layer 68 have a tapered shape; it is further preferable that the tapered shape of the conductive layer 67 and the tapered shape of the conductive layer 68 be continuous.

In such a process, the insulating film 106A can function as an etching stopper film at the time of performing processing for forming the conductive layers.

A structure in which the conductive layer 67, the conductive layer 64, and the conductive layer 68 are stacked as illustrated in FIG. 14D is preferably used as the lower electrode 111. The conductive layer 64 enables the lower electrodes 111R, 111G, and 111B to have reflectivity.

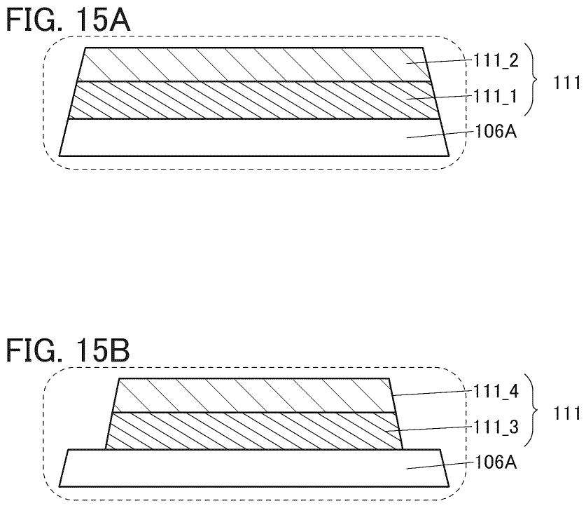

The above-described stacked-layer structure or a single-layer structure may be applied to the lower electrode 111. FIG. 15A illustrates the lower electrode 111 having a stacked-layer structure different from that in FIG. 14 and includes a first conductive layer 111_1 and a second conductive layer 111_2 over the insulating film 106A. In the case where the lower electrode 111 has a single-layer structure, the lower electrode 111 includes only the first conductive layer 111_1 in FIG. 15A. In FIG. 15A, an end portion of the first conductive layer 111_1 or the second conductive layer 111_2 preferably has a tapered shape.

In FIG. 15B, the lower electrode 111 including a first conductive layer 111_3 and a second conductive layer 111_4 is provided over the insulating film 106A and a lower end of the first conductive layer 111_3 is positioned inward from an upper end of the insulating layer 106 unlike in FIG. 15A. In the case where the lower electrode 111 has a single-layer structure, the lower electrode 111 includes only the first conductive layer 111_3 in FIG. 15B. In FIG. 15B, an end portion of the first conductive layer 111_3 or the second conductive layer 111_4 preferably has a tapered shape.

Next, as illustrated in FIG. 10B, regions of the insulating film 106A that overlap with none of the lower electrodes 111R, 111G, and 111B are removed, so that the insulating layers 106R, 106G, and 106B are formed. For example, with a resist mask formed over the insulating film 106A, the insulating layers 106R, 106G, and 106B can be formed by a dry etching method or a wet etching method.

As the dry etching method, a parallel plate RIE (Reactive Ion Etching) method or an ICP (Inductively Coupled Plasma: inductively coupled plasma) etching method can be used. As an etching gas for the dry etching method, for example, a C₄F₆ gas, a C₄F₈ gas, a CF₄ gas, a SF₆ gas, a CHF₃ gas, a Cl₂ gas, a BCl₃ gas, a SiCl₄ gas, or the like can be used alone or two or more of the gases can be mixed and used. Alternatively, an oxygen gas, a helium gas, an argon gas, a hydrogen gas, or the like can be added to any of the above gases as appropriate.

Then, as illustrated in FIG. 10B, the depressed portion 103 is formed in the insulating film 105A to form the insulating layer 105 including the depressed portion 103. The depressed portion 103 can be formed by a dry etching method or a wet etching method and is preferably formed by anisotropic plasma etching treatment or ashing. As the plasma etching treatment, for example, RF plasma treatment using oxygen as a gas is preferably performed. In the case where an inorganic material is used for the insulating film 105A, wet etching treatment is preferably used. In this manner, the depressed portion 103 can be formed. The widths of the depressed portions 103 observed in a plan view may be equal to or different from each other.

Furthermore, ashing allows formation of the depressed portion 103 and ashing treatment before the removal of the resist mask for forming the insulating layer 106 to be performed at the same time. A substrate is placed in an apparatus used for ashing (ashing apparatus) and the power density of bias voltage applied to the substrate side is set to greater than or equal to 1 W/cm² and less than or equal to 5 W/cm². Oxygen can be used as a gas introduced into the ashing apparatus; in that case, the substrate temperature is preferably set to higher than or equal to room temperature and lower than or equal to 300° C., further preferably higher than or equal to 100° C. and lower than or equal to 250° C.

Part of the depressed portion 103 can overlap with part of the insulating layer 106R, 106G, or 106B; specifically, part of the bottom surface of each of the insulating layers 106R, 106G, and 106B is exposed. The part of the bottom surface of each of the insulating layers 106R, 106G, and 106B is a portion protruding from an upper end of the insulating layer 105 defining the depressed portion 103 and is referred to as the protruding portion 107.

[Formation of Organic Layer 112R and Insulating Layer 125a]

As illustrated in FIG. 10C, a film including a first light-emitting compound (an organic film 112Rf) is formed over the lower electrode 111R, the lower electrode 111G, the lower electrode 111B, and the insulating layer 105. The organic film 112Rf has a single structure and can emit red light.

The organic film 112Rf can be formed by, for example, an evaporation method, specifically a vacuum evaporation method. The film may be formed by a method such as a transfer method, a printing method, an ink-jet method, or a coating method.

In this case, the organic film 112Rf is disconnected in the depressed portion 103. In FIG. 10C, the organic film 112Rf is disconnected at least at the protruding portion of the insulating layer 106. As a result, the organic film 112Rf is formed selectively in the depressed portion 103 and over the lower electrode 111R, the lower electrode 111G, and the lower electrode 111B. Selective formation of the organic film 112Rf without a processing step may be described with the expression “the organic film 112Rf is formed in a self-aligned manner”. The organic film 112Rf is also formed on a side surface of the lower electrode 111R, a side surface of the lower electrode 111G, and a side surface of the lower electrode 111B. Furthermore, the organic film 112Rf is formed on a side surface of the insulating layer 106R, a side surface of the insulating layer 106G, and a side surface of the insulating layer 106B. However, the organic film 112Rf is not formed on any of the bottom surface of the insulating layer 106R, the bottom surface of the insulating layer 106G, and the bottom surface of the insulating layer 106B that correspond to the protruding portion 107.

Next, an insulating film 125A is formed over the organic film 112Rf. The insulating film 125A can be formed by a sputtering method, a CVD method, an MBE method, a PLD method, an ALD method, or the like as appropriate.

The insulating film 125A is formed to cover the top surface and a side surface of the organic film 112Rf, the bottom surface of the insulating layer 106, and the depression portion 103. The insulating film 125A preferably includes a region in contact with the bottom surface of the insulating layer 106. The insulating film 125A is formed to cover the organic film 112Rf formed separately in the depressed portion 103.

Although not described above, for the insulating film 125A, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver. A metal material capable of blocking ultraviolet light is preferably used for the insulating film 125A, in which case the organic film 112Rf can be inhibited from being irradiated with ultraviolet light and deteriorating.

A metal oxide film can be used as the insulating film 125A. As the metal oxide film, a film including In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), or indium gallium tin zinc oxide (In—Ga—Sn—Zn oxide) can be used. Alternatively, an indium tin oxide film including silicon can be used. As the insulating film 125A, an In—Ga—Zn oxide film can be formed by a sputtering method, for example.

Note that in place of gallium given above, an element M (M is one or more selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used. In particular, M is preferably one or more kinds selected from gallium, aluminum, and yttrium.

For the insulating film 125A, any of the inorganic insulating materials given above such as aluminum oxide, hafnium oxide, and silicon oxide can be used. As the insulating film 125A, an aluminum oxide film can be formed by an ALD method, for example. An ALD method enables an atomic layer to be deposited one by one, whereby the insulating film 125A can be formed on the bottom surface of the insulating layer 106R, the bottom surface of the insulating layer 106G, and the bottom surface of the insulating layer 106B and in the depressed portion 103, for example, with good coverage. An ALD method is preferably used, in which case damage to the organic film 112Rf can be reduced.

For example, in the case where aluminum oxide is deposited by an ALD method, two kinds of gases, H₂O as an oxidizer and a source gas that is obtained by vaporizing liquid containing a solvent and an aluminum precursor compound (trimethylaluminum (TMA, Al(CH₃)₃) or the like) are used. Examples of another material include tris(dimethylamide) aluminum, triisobutylaluminum, and aluminum tris(2,2,6,6-tetramethyl-3,5-heptanedionate).

Note that the insulating film 125A may be formed by a sputtering method, a CVD method, or a PECVD method that has a higher deposition rate than an ALD method. In that case, a highly reliable display device can be manufactured with high productivity.

The insulating film 125A may have a stacked-layer structure of two or more layers. For example, it is possible to employ a two-layer structure in which an inorganic insulating film (e.g., an aluminum oxide film) formed by an ALD method is used as a lower layer and an inorganic film (e.g., an In—Ga—Zn oxide film, an aluminum film, or a tungsten film) formed by a sputtering method is used as an upper layer.

Next, as illustrated in FIG. 10D, a resist mask 181 is formed over the insulating film 125A. In this case, the resist mask 181 is formed in a portion overlapping with parts of the organic film 112Rf and the depressed portion 103.

An end portion of the resist mask 181 is perpendicular to the surface of the substrate 101 in FIG. 10D; however, the shape of the end portion of the resist mask 181 is not limited thereto. The end portion of the resist mask 181 may have a tapered shape or an inverse tapered shape.

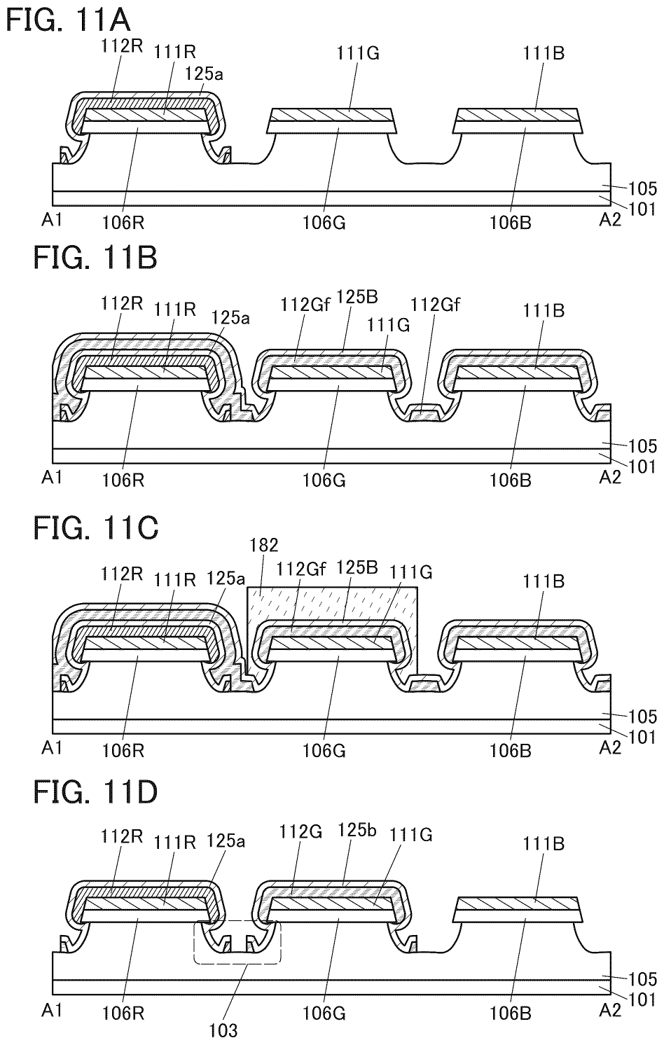

Next, the insulating film 125A in a portion not covered with the resist mask 181 is removed, so that the insulating layer 125a can be formed as illustrated in FIG. 11A. A dry etching method or a wet etching method can be used to remove part of the insulating film 125A. After that, the resist mask 181 is removed.

Next, as illustrated in FIG. 11A, part of the organic film 112Rf is removed by etching treatment using the insulating layer 125a as a hard mask, so that the organic layer 112R is formed. Accordingly, the organic layer 112R is positioned over the lower electrode 111R, and the insulating layer 125a is positioned over the organic layer 112R. Note that part of the organic film 112Rf may remain in the depressed portion 103.

Accordingly, the organic layer 112R and the lower electrode 111R can be sealed with the insulating layer 106R and the insulating layer 125a. Furthermore, the organic layer 112R and the lower electrode 111R can be sealed with a side surface of the insulating layer 105 and the insulating layer 125a positioned in the depressed portion 103. Such a structure can inhibit separation of the organic layer 112R from the lower electrode 111R.

[Formation of Organic Layer 112G and Insulating Film 125b]

As illustrated in FIG. 11B, a film including a second light-emitting compound (an organic film 112Gf) is formed over the lower electrode 111G, the lower electrode 111B, the insulating layer 105, and the insulating layer 125a. The organic film 112Gf has a single structure and can emit green light.

The organic film 112Gf can be formed by, for example, an evaporation method, specifically a vacuum evaporation method. The film may be formed by a method such as a transfer method, a printing method, an ink-jet method, or a coating method.

In this case, the organic film 112Gf is disconnected in the depressed portion 103. In FIG. 11B, the organic film 112Gf is disconnected at least at the protruding portion of the insulating layer 106. As a result, the organic film 112Gf is formed in the depressed portion 103 and over the lower electrode 111G, the lower electrode 111B, the insulating layer 105, and the insulating layer 125a. Selective formation of the organic film 112Gf without a processing step may be described with the expression “the organic film 112Gf is formed in a self-aligned manner”. The organic film 112Gf is also formed on the side surface of the lower electrode 111G and the side surface of the lower electrode 111B. Furthermore, the organic film 112Gf is formed on the side surface of the insulating layer 106G and the side surface of the insulating layer 106B. However, the organic film 112Gf is not formed on either the bottom surface of the insulating layer 106G or the bottom surface of the insulating layer 106B that corresponds to the protruding portion.

Next, an insulating film 125B is formed over the organic film 112Gf. The insulating film 125B can be formed by a sputtering method, a CVD method, an MBE method, a PLD method, an ALD method, or the like as appropriate. For the structure and the like of the insulating film 125B, the description of the insulating film 125A can be referred to.

Next, as illustrated in FIG. 11C, a resist mask 182 is formed over the insulating film 125B. In this case, the resist mask 182 is formed in a portion overlapping with parts of the organic film 112Gf and the depressed portion 103.

An end portion of the resist mask 182 is perpendicular to the surface of the substrate 101 in FIG. 11C; however, the shape of the end portion of the resist mask 182 is not limited thereto. The end portion of the resist mask 182 may have a tapered shape or an inverse tapered shape.

Next, the insulating film 125B in a portion not covered with the resist mask 182 is removed, so that the insulating film 125b can be formed as illustrated in FIG. 11D. A dry etching method or a wet etching method can be used to remove part of the insulating film 125B. After that, the resist mask 182 is removed.

Next, as illustrated in FIG. 11D, part of the organic film 112Gf is removed by etching treatment using the insulating film 125b as a hard mask, so that the organic layer 112G is formed. Accordingly, the organic layer 112G is positioned over the lower electrode 111G, and the insulating layer 125b is positioned over the organic layer 112G. Note that part of the organic film 112Gf may remain in the depressed portion 103. In FIG. 11D, the remaining part of the organic film 112Rf and the remaining part of the organic film 112Gf are positioned and separated from each other in the depressed portion 103.

Accordingly, the organic layer 112G and the lower electrode 111G can be sealed with the insulating layer 106G and the insulating film 125b. Furthermore, the organic layer 112G and the lower electrode 111G can be sealed with a side surface of the insulating layer 105 and the insulating layer 125b positioned in the depressed portion 103. Such a structure can inhibit separation of the organic layer 112G from the lower electrode 111G.

[Formation of Organic Layer 112B and Insulating Layer 125c]

A film including a third light-emitting compound (not illustrated but referred to as an organic film Bf) is formed over the lower electrode 111B, the insulating layer 105, the insulating layer 125a, and the insulating layer 125b. An organic film 112Bf has a tandem structure and can emit blue light.

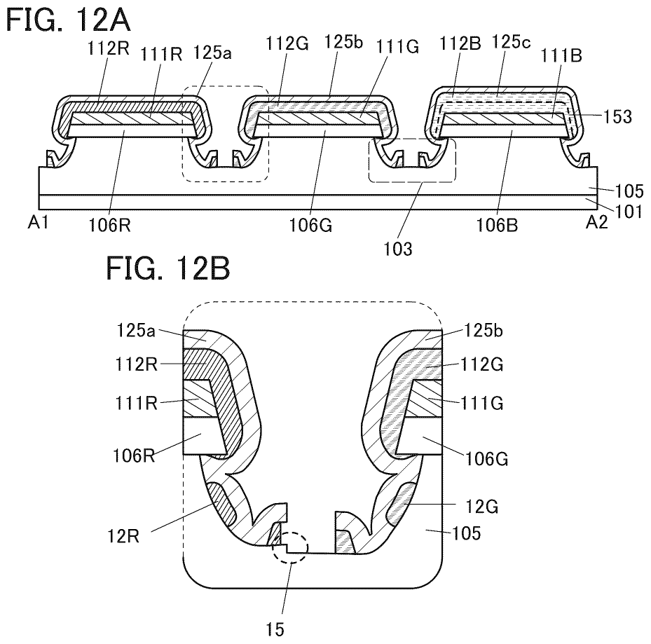

In this case, the organic film 112Bf is disconnected in the depressed portion 103. To ensure disconnection in this step, the width of the depressed portion 103 seen in a plan view between the organic layer 112G and the organic layer 112B and that between the organic layer 112R and the organic layer 112B are each preferably larger than that between the organic layer 112R and the organic layer 112G. In FIG. 12A, the organic film 112Bf is disconnected at least at the protruding portion of the insulating layer 106. As a result, the organic film 112Bf is formed in the depressed portion 103 and over the lower electrode 111B, the insulating layer 105, the insulating layer 125a, and the insulating layer 125b. Selective formation of the organic film 112Bf without a processing step may be described with the expression “the organic film 112Bf is formed in a self-aligned manner”. The organic film 112Bf is also formed on the side surface of the lower electrode 111B. Furthermore, the organic film 112Bf is formed on the side surface of the insulating layer 106B. However, the organic film 112Bf is not formed on the bottom surface of the insulating layer 106B that corresponds to the protruding portion.

With reference to the steps for the organic layer 112R and the organic layer 112G, the charge-generation layer 153 and the organic layer 112B are positioned over the lower electrode 111B and the insulating layer 125c is positioned over the organic layer 112B as illustrated in FIG. 12A. Note that part of the organic film 112Bf may remain in the depressed portion 103. In FIG. 12A, the remaining part of the organic film 112Gf and the remaining part of the organic film 112Bf are positioned and separated from each other in the depressed portion 103.

Accordingly, the organic layer 112B and the lower electrode 111B can be sealed with the insulating layer 106B and the insulating layer 125c. Furthermore, the organic layer 112B and the lower electrode 111B can be sealed with a side surface of the insulating layer 105 and the insulating layer 125c positioned in the depressed portion 103. Such a structure can inhibit separation of the organic layer 112B from the lower electrode 111B.

FIG. 12B illustrates an example of a structure different from that of a region surrounded by a dashed line in FIG. 12A.

As illustrated in FIG. 12B, a step may be formed in the insulating layer 105 in the depressed portion 103 in the step of forming the organic layer 112G, for example. Specifically, as illustrated in FIG. 12B, a step 15 is formed in the vicinity of an end portion of the insulating layer 125a, for example. The shape of the organic film remaining in the depressed portion 103 is not particularly limited. As illustrated in FIG. 12B, organic layers 12R and 12G may also remain on side surfaces of the depressed portion 103, for example, in addition to the bottom surface of the depressed portion 103. The step of forming the organic layer 112G, or the like may be rephrased as the step of forming the organic layer 112B, or the like.

[Formation of Insulating Layer 127, Insulating Layer 126, Common Layer 114, and Common Electrode 113x]

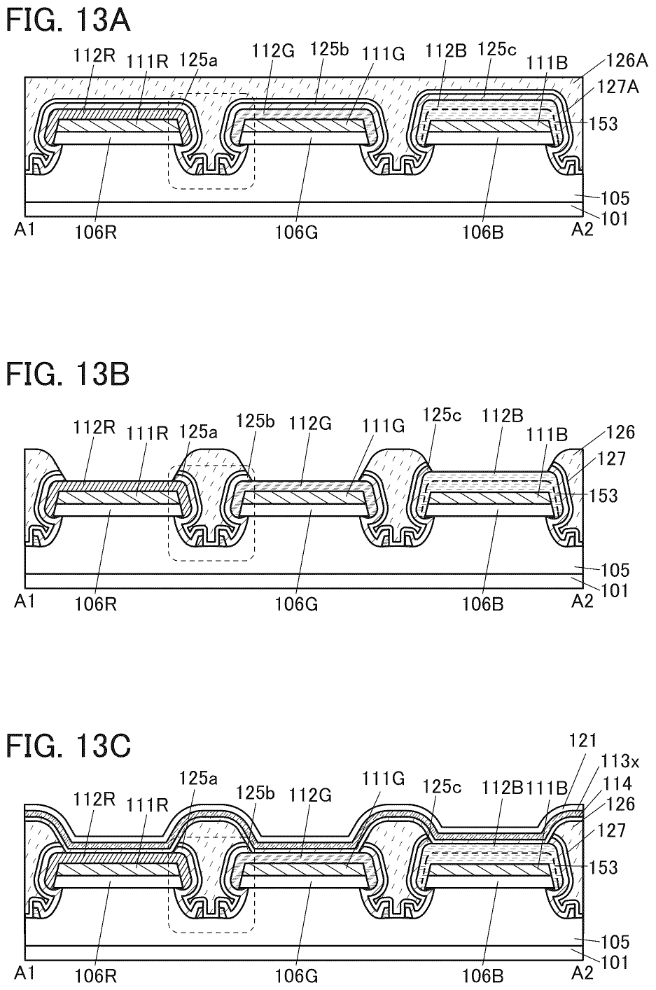

Next, as illustrated in FIG. 13A, an insulating film 127A is formed over the insulating layer 105, the insulating layer 125a, the insulating layer 125b, and the insulating layer 125c, and a resin film 126A is formed over the insulating film 127A. The insulating film 127A is a film to be the insulating layer 127, and the resin film 126A is a film to be the resin layer 126.

A film that can be used as the insulating film 125A and the like can be used as the insulating film 127A. The insulating film 127A is not necessarily provided.

The resin film 126A is formed at a temperature lower than the upper temperature limits of the organic layer 112R, the organic layer 112G, and the organic layer 112B. The insulating film is preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

The resin film 126A is preferably formed by a wet process. For example, the insulating film is preferably formed by spin coating using a photosensitive material, specifically, a photosensitive resin composition containing an acrylic resin.

The resin film 126A is preferably formed using a resin composition containing a polymer, an acid-generating agent, and a solvent, for example. The polymer is formed using one or more kinds of monomers and has a structure in which one or more kinds of structural units (also referred to as building blocks) are repeated regularly or irregularly. As the acid-generating agent, one or both of a compound that generates an acid by light irradiation and a compound that generates an acid by heating can be used. The resin composition may further contain one or more of a photosensitizing agent, a sensitizer, a catalyst, an adhesive aid, a surface-active agent, and an antioxidant.

After the resin film 126A is formed, heat treatment (also referred to as prebaking) is preferably performed. The heat treatment is performed at a temperature lower than the upper temperature limits of the organic layer 112R, the organic layer 112G, and the organic layer 112B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the resin film 126A can be removed.

Then, part of the insulating film 126A is exposed to visible rays or ultraviolet rays. Here, in the case where a positive photosensitive resin composition containing an acrylic resin is used for the insulating film, a region where the insulating layer 126 is not formed in a later step is irradiated with visible rays or ultraviolet rays. The width of the insulating layer 126 formed later can be controlled in accordance with the light-exposure region of the insulating film 126A. As illustrated in FIG. 13B, processing is performed so that the insulating layer 126 includes a region overlapping with the top surface of the lower electrode 111. Light used for light exposure preferably includes the i-line (wavelength: 365 nm). The light used for light exposure may include at least one of the g-line (wavelength: 436 nm) and the h-line (wavelength: 405 nm).

Next, the region of the resin film 126A exposed to light is removed by development, so that the insulating layer 126 is formed as illustrated in FIG. 13B. The insulating layer 126 is formed in a region interposed between any two of the lower electrode 111R, the lower electrode 111G, and the lower electrode 111B. Here, in the case where an acrylic resin is used for the insulating film, an alkaline solution is preferably used as a developer, and for example, an aqueous solution of tetramethyl ammonium hydroxide (TMAH) can be used.

Then, a residue (what is called scum) due to the development may be removed. For example, the residue can be removed by ashing using oxygen plasma.

Note that etching may be performed to adjust the surface level of the insulating layer 126. The insulating layer 126 may be processed by ashing using oxygen plasma, for example. In the case where a non-photosensitive material is used for the resin film to be the insulating layer 126, the surface level of the insulating film can be adjusted by the ashing, for example.

Next, etching treatment is performed using the insulating layer 126 as a mask, so that part of the insulating layer 125a, part of the insulating film 125b, and part of the insulating layer 125c are removed and part of the insulating film 127A is removed to form the insulating layer 127 as illustrated in FIG. 13B. Consequently, an opening is formed in the insulating film 127A and the insulating layer 125a, so that the top surface of the organic layer 112R is exposed. An opening is formed in the insulating film 127A and the insulating layer 125b, so that the top surface of the organic layer 112G is exposed. Furthermore, an opening is formed in the insulating film 127A and the insulating layer 125c, so that the top surface of the organic layer 112B is exposed.

The etching treatment is performed by wet etching. The use of a wet etching method can reduce damage to the organic layers 112R, 112G, and 112B as compared with the case of using a dry etching method. The wet etching can be performed using an alkaline solution such as TMAH, for example. Alternatively, an acidic solution such as a mixed acid chemical solution containing water, phosphoric acid, diluted hydrofluoric acid, and nitric acid may be used. A chemical solution used for the wet etching treatment may be alkaline or acid.

Heat treatment may be performed after parts of the organic layers 112R, 112G, and 112B are exposed. The heat treatment can remove water contained in the organic layers 112R, 112G, and 112B and water adsorbed on the surfaces of the organic layers 112R, 112G, and 112B, for example. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case dehydration at a lower temperature is possible. Note that the temperature range of the heat treatment is preferably set as appropriate in consideration of the upper temperature limit of the organic layer 112. In consideration of the upper temperature limit of the organic layer 112, a temperature higher than or equal to 70° C. and lower than or equal to 120° C. is particularly preferable in the above temperature ranges.

Next, as illustrated in FIG. 13C, the common layer 114 is formed over the organic layer 112R, the organic layer 112G, the organic layer 112B, and the insulating layer 126. The common layer 114 can be formed by a method such as an evaporation method (including a vacuum evaporation method), a transfer method, a printing method, an ink-jet method, or a coating method.

Next, a common electrode 113x is formed over the common layer 114. The common electrode 113x corresponds to an upper electrode. The common electrode 113x can be formed by a sputtering method, a vacuum evaporation method, or the like. Alternatively, the common electrode 113x may be formed by stacking a film formed by an evaporation method and a film formed by a sputtering method.

Through the above steps, the red-light-emitting device 110R, the green-light-emitting device 110G, and the blue-light-emitting device 110B can be formed.

Then, as illustrated in FIG. 13C, the protective layer 121 is formed over the common electrode 113x. The protective layer 121 can be formed by a method such as a vacuum evaporation method, a sputtering method, a CVD method, or an ALD method.

Through the above steps, the display device 100C having the structure illustrated in FIG. 9 and the like can be manufactured.

According to the above manufacturing method example, the organic layer 112 is sealed with the insulating layer 125 and the insulating layer 106 or the insulating layer 105. Such a structure not only inhibits the organic layer 112 from being separated from the lower electrode but also prevents the organic layer 112 from being exposed to a chemical solution or the like used when the resist mask is removed in this method. Thus, the light-emitting device 110 can be formed without using a metal mask for forming the organic layer 112.

According to the above manufacturing method example, the difference in the optical distance between the lower electrode 111 and the common electrode 113x can be precisely controlled by the thicknesses of the organic layer 112; thus, chromaticity deviation in the light-emitting elements is unlikely to occur, so that a display device having excellent color reproducibility and extremely high display quality can be manufactured easily. A structure in which the optical distance difference is controlled may be referred to as a microcavity structure.

Furthermore, the insulating layer 126 can be provided between the organic layers 112 adjacent to each other, for example, and the insulating layer 126 has a tapered end portion, so that disconnection of the common electrode 113x can be inhibited. This can inhibit a connection defect due to disconnection of the common electrode.

Note that in the display device of one embodiment of the present invention or the method for manufacturing the display device, there is no particular limitation on the screen ratio (aspect ratio) of a display portion in the display device. For example, the display device is compatible with a variety of screen ratios such as 1:1 (square), 3:4, 16:9, and 16:10.

This embodiment can be combined with the other embodiments as appropriate.

### Embodiment 2

In this embodiment, a structure example of a light-emitting device that can be used in a display device will be described.

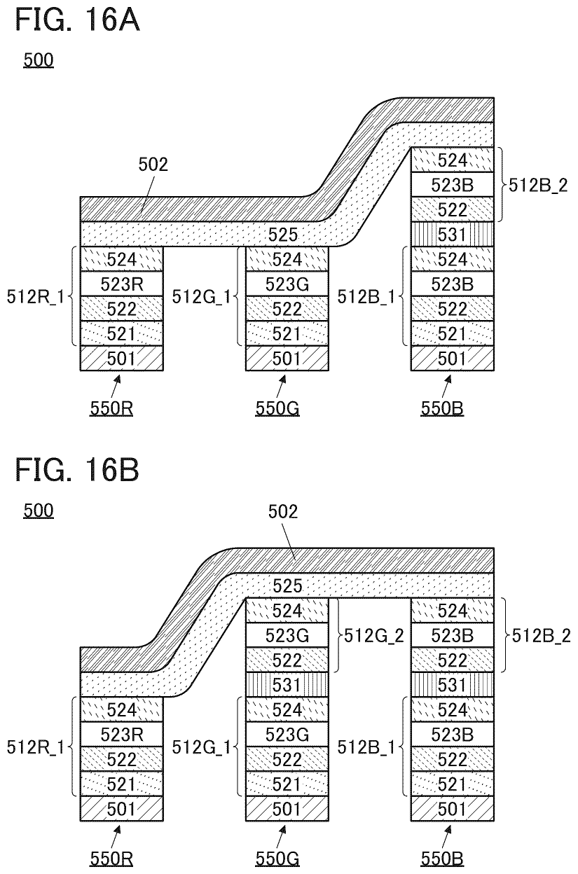

FIG. 16A illustrates a schematic cross-sectional view of a display device 500. The display device 500 includes a light-emitting device 550R that emits red light, a light-emitting device 550G that emits green light, and a light-emitting device 550B that emits blue light. The light-emitting device 550R corresponds to the red-light-emitting device 110R, the light-emitting device 550G corresponds to the green-light-emitting device 110G, and the light-emitting device 550B corresponds to the blue-light-emitting device 110B.

The light-emitting device 550R has a structure in which one light-emitting unit 512R_1 is provided between a pair of electrodes (an electrode 501 and an electrode 502). Similarly, the light-emitting device 550G has a structure in which one light-emitting unit 512G_1 is provided. The light-emitting device 550B has a structure in which a light-emitting unit 512B_1, a charge-generation layer 531, and a light-emitting unit 512B_2 are provided between the pair of electrodes. That is, in the display device 500, the light-emitting device 550R and the light-emitting device 550G have a single structure and the light-emitting device 550B has a tandem structure as in the display device 100A illustrated in FIG. 6A, for example.

The electrode 501 functions as a pixel electrode and is provided in every light-emitting device. The electrode 502 functions as a common electrode and is shared by the plurality of light-emitting devices.

As illustrated in FIG. 16A, the light-emitting unit 512B_1 includes a layer 521, a layer 522, a light-emitting layer 523B, and a layer 524. The light-emitting unit 512B_2 includes the layer 522, the light-emitting layer 523B, and the layer 524. The light-emitting unit 512R_1 includes the layer 521, the layer 522, a light-emitting layer 523R, and the layer 524. The light-emitting unit 512G_1 includes the layer 521, the layer 522, a light-emitting layer 523G, and the layer 524.

The light-emitting device 550B includes a layer 525 between the light-emitting unit 512B_2 and the electrode 502. The light-emitting device 550R includes the layer 525 between the light-emitting unit 512R_1 and the electrode 502. The light-emitting device 550G includes the layer 525 between the light-emitting unit 512G_1 and the electrode 502. In this manner, like the electrode 502, the layer 525 can be shared by the plurality of light-emitting devices. In this case, the layer 525 can be referred to as a common layer. By providing one or more common layers for the plurality of light-emitting devices in this manner, the manufacturing process can be simplified, resulting in a reduction in manufacturing cost.

Note that without limitation to the above, the layer 525 may be provided in each of the light-emitting devices 550R, 550G, and 550B. In that case, the layer 525 can be regarded as part of each of the light-emitting unit 512B_2, the light-emitting unit 512R_1, and the light-emitting unit 512G_1.

In the case where the electrode 501 functions as an anode and the electrode 502 functions as a cathode, the layer 521 includes, for example, a layer including a substance with a high hole-injection property (a hole-injection layer). The layer 522 includes, for example, one or both of a layer including a substance with a high hole-transport property (a hole-transport layer) and a layer including a substance with a high electron-blocking property (an electron-blocking layer). The layer 524 includes, for example, one or both of a layer including a substance with a high electron-transport property (an electron-transport layer) and a layer including a substance with a high hole-blocking property (a hole-blocking layer). The layer 525 includes, for example, a layer including a substance with a high electron-injection property (an electron-injection layer).

In the case where the electrode 501 functions as a cathode and the electrode 502 functions as an anode, for example, the layer 521 includes an electron-injection layer, the layer 522 includes one or both of an electron-transport layer and a hole-blocking layer, the layer 524 includes one or both of a hole-transport layer and an electron-blocking layer, and the layer 525 includes a hole-injection layer.

The structure (e.g., material and thickness) of each of the layer 522, the light-emitting layer 523B, and the layer 524 may be the same or different between the light-emitting unit 512B_1 and the light-emitting unit 512B_2. For example, a light-emitting material emitting blue light may be used for the light-emitting layer 523B of the light-emitting unit 512B_1, and a light-emitting material emitting blue-green light may be used for the light-emitting layer 523B of the light-emitting unit 512B_2.

FIG. 16A illustrates the layer 521 and the layer 522 separately; however, one embodiment of the present invention is not limited thereto. For example, the layer 522 may be omitted when the layer 521 has functions of both a hole-injection layer and a hole-transport layer or the layer 521 has functions of both an electron-injection layer and an electron-transport layer.

In the case of manufacturing a light-emitting device with a tandem structure, two light-emitting units are stacked with the charge-generation layer 531 therebetween. The charge-generation layer 531 includes at least a charge-generation region. The charge-generation layer 531 has a function of injecting electrons into one of the light-emitting unit 512B_1 and the light-emitting unit 512B_2 and injecting holes into the other when voltage is applied between the electrode 501 and the electrode 502.

The light-emitting layer 523R included in the light-emitting device 550R includes a light-emitting substance (also referred to as a light-emitting material) that emits red light, the light-emitting layer 523G included in the light-emitting device 550G includes a light-emitting substance that emits green light, and the light-emitting layer 523B included in the light-emitting device 550B includes a light-emitting substance that emits blue light. Note that the light-emitting device 550R and the light-emitting device 550G have a structure in which the light-emitting layer 523B included in the light-emitting unit 512B_1 of the light-emitting device 550B is replaced with the light-emitting layer 523R and the light-emitting layer 523G, respectively, and the other components are similar to those of the light-emitting device 550B.

Note that the structure (e.g., material and thickness) of each of the layer 521, the layer 522, the layer 524, and the layer 525 may be the same between the light-emitting devices of two or more colors or all colors or may be different between the light-emitting devices of all colors.

A structure in which a plurality of light-emitting units are connected in series through the charge-generation layer 531 as in the light-emitting device 550B is referred to as a tandem structure in this specification. By contrast, a structure in which one light-emitting unit is provided between a pair of electrodes as in the light-emitting device 550R and the light-emitting device 550G is referred to as a single structure. Note that the tandem structure may be referred to as a stack structure. The tandem structure enables a light-emitting device capable of high-luminance light emission. Furthermore, the tandem structure allows the amount of current needed for obtaining the same luminance to be reduced as compared with a single structure, and thus can improve the reliability of the light-emitting device.

In the display device of one embodiment of the present invention, a tandem structure is applied to at least the light-emitting device 550B that emits blue light. Such a structure can improve the reliability of the blue-light-emitting device in which an increase in driving voltage, a decrease in lifetime, or the like is likely to occur. Improving the reliability of the blue-light-emitting device 550B leads to an improvement in the reliability of the display device. Furthermore, when a single structure is applied to the red-light-emitting device 550R, the manufacturing process can be simplified and the yield in the manufacturing process of the display device can be increased.

The light-emitting device 550R, the light-emitting device 550G, and the light-emitting device 550B have an SBS structure in which at least light-emitting layers are separately formed for light-emitting devices. The SBS structure can optimize materials and structures of light-emitting devices and thus can extend the freedom of choice of materials and structures, whereby the luminance and the reliability can be easily improved.

The display device 500 of one embodiment of the present invention employs a light-emitting device with a tandem structure and has an SBS structure. Thus, the display device can have both the advantage of the tandem structure and the advantage of the SBS structure. The light-emitting device 550B in the display device 500 illustrated in FIG. 16A has a structure in which two light-emitting units are formed in series, and this structure may be referred to as a two-unit tandem structure. In the light-emitting device 550B with the two-unit tandem structure illustrated in FIG. 16A, a second light-emitting unit including a blue-light-emitting layer is stacked over a first light-emitting unit including a blue-light-emitting layer.

Furthermore, the light-emitting device 550G may have a tandem structure as illustrated in FIG. 16B. In the light-emitting device 550G, as in the light-emitting device 550B, the light-emitting unit 512G_1 includes the layer 521, the layer 522, the light-emitting layer 523G, and the layer 524 and a light-emitting unit 512G_2 includes the layer 522, the light-emitting layer 523G, and the layer 524. The light-emitting unit 512G_1 and the light-emitting unit 512G_2 are stacked with the charge-generation layer 531 therebetween.

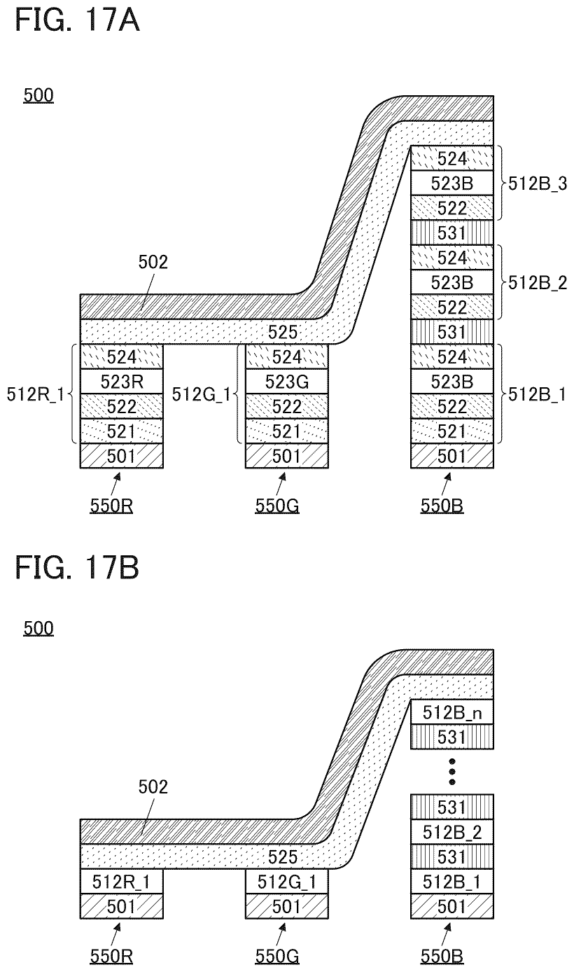

The display device 500 illustrated in FIG. 17A is an example in which three light-emitting units are stacked in the light-emitting device 550B. In the light-emitting device 550B in FIG. 17A, a light-emitting unit 512B_3 is further stacked over the light-emitting unit 512B_2 with the charge-generation layer 531 therebetween. The light-emitting unit 512B_3 has a structure similar to that of the light-emitting unit 512B_2. Note that in the case where the light-emitting device includes a plurality of the charge-generation layers 531, two or more or all of the plurality of charge-generation layers 531 may have the same structure (e.g., material and thickness) or all of the charge-generation layers 531 may have different structures. Although the light-emitting device 550G has a single structure in FIG. 17A, the light-emitting device 550G may have a tandem structure with two or three units instead of the single structure.

FIG. 17B illustrates an example of a case where n light-emitting units (n is an integer greater than or equal to 2) are stacked in the light-emitting device 550B. Although the light-emitting device 550G has a single structure in FIG. 17B, the light-emitting device 550G may have a tandem structure with two or more units without limitation to the single structure.

When the number of stacked light-emitting units is increased in the above manner, luminance obtained from the light-emitting device with the same amount of current can be increased in accordance with the number of stacked layers. Moreover, increasing the number of stacked light-emitting units can reduce the amount of current needed for obtaining the same luminance; thus, power consumption of the light-emitting device can be reduced in accordance with the number of stacked layers.

Next, materials that can be used for the light-emitting device will be described.

A conductive film transmitting visible light is used as the electrode through which light is extracted, which is either the electrode 501 or the electrode 502. A conductive film that reflects visible light is preferably used for the electrode through which light is not extracted. In the case where a display device includes a light-emitting device emitting infrared light, a conductive film transmitting visible light and infrared light is preferably used as the electrode through which light is extracted, and a conductive film reflecting visible light and infrared light is preferably used as the electrode through which light is not extracted.

A conductive film that transmits visible light may be used also for the electrode through which light is not extracted. In that case, the electrode is preferably provided between a reflective layer and the light-emitting unit that is the closest to the reflective layer. In other words, light emitted from the light-emitting device may be reflected by the reflective layer to be extracted from the display device.

As a material that forms the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Examples of the material include In—Sn oxide (indium tin oxide or ITO), In—Si—Sn oxide (ITSO), In—Zn oxide (indium zinc oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag-pd-Cu or APC). Other examples of the material include elements belonging to Group 1 or Group 2 of the periodic table, which are not exemplified above (e.g., lithium, cesium, calcium, and strontium), rare earth metals such as europium or ytterbium, an alloy containing any of these metals in appropriate combination, and graphene.

The light-emitting device preferably employs a microcavity structure. Thus, one of the pair of electrodes included in the light-emitting device is preferably an electrode having properties of transmitting and reflecting visible light (a transflective electrode), and the other is preferably an electrode having a property of reflecting visible light (a reflective electrode). In other words, a transflective electrode is preferably used as the electrode through which light is extracted, which is either the electrode 501 or the electrode 502, and a reflective electrode is preferably used as the electrode through which light is not extracted. When the light-emitting device has a microcavity structure, light obtained from the light-emitting layer can be resonated between the electrodes, whereby light emitted from the light-emitting device can be intensified.

A conductive film that transmits visible light may be provided on the transflective electrode facing the light-emitting layer or on the reflective electrode facing the light-emitting layer. Here, the conductive film that transmits visible light functions as an optical adjustment layer. In this case, the conductive film that transmits visible light can also be regarded as having a function of a pixel electrode or a common electrode.

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting device. The visible light reflectance of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least the light-emitting layer. The light-emitting device may further include, as a layer other than the light-emitting layer, a layer including a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may be included. Each layer included in the light-emitting device can be formed by a method such as an evaporation method (including a vacuum evaporation method), a transfer method, a printing method, an ink-jet method, or a coating method.

The light-emitting layer includes one or more kinds of light-emitting substances. As the light-emitting substance, a substance whose emission color is blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property that can be used for the hole-transport layer and will be described later. As the electron-transport material, it is possible to use a material with a high electron-transport property that can be used for the electron-transport layer and will be described later. As one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of the lowest-energy-side absorption band of the light-emitting substance, energy can be smoothly transferred and light emission can be efficiently obtained. With the above structure, high efficiency, low-voltage driving, and a long lifetime of a light-emitting device can be achieved at the same time.

The hole-injection layer is a layer injecting holes from an anode to the hole-transport layer and a layer including a material with a high hole-injection property. Examples of a material with a high hole-injection property include an aromatic amine compound and a composite material including a hole-transport material and an acceptor material (an electron-accepting material).

As the hole-transport material, it is possible to use a material with a high hole-transport property that can be used for the hole-transport layer and will be described later.

As the acceptor material, an oxide of a metal that belongs to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable because it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material with a high hole-injection property, a material that contains a hole-transport material and the above-described oxide of a metal that belongs to Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer including a hole-transport material. For the hole-transport material, a substance having a hole mobility higher than or equal to 1×10⁻⁶ cm²/Vs is preferable. Note that other substances can also be used as long as they have a property of transporting more holes than electrons. As the hole-transport material, a material with a high hole-transport property, such as a x-electron rich heteroaromatic compound (e.g., a carbazole derivative, a thiophene derivative, or a furan derivative) or an aromatic amine (a compound having an aromatic amine skeleton), is preferable.

The electron-blocking layer is provided in contact with the light-emitting layer. The electron-blocking layer has a hole-transport property and includes a material capable of blocking electrons. Any of the materials having an electron-blocking property among the above hole-transport materials can be used for the electron-blocking layer.

The electron-blocking layer has a hole-transport property and thus can also be referred to as a hole-transport layer. A layer having an electron-blocking property among the hole-transport layers can also be referred to as an electron-blocking layer.

The electron-transport layer is a layer transporting electrons, which are injected from the cathode by the electron-injection layer, to the light-emitting layer. The electron-transport layer is a layer including an electron-transport material. For the electron-transport material, a substance having an electron mobility higher than or equal to 1×10⁻⁶ cm²/Vs is preferable. Note that other substances can also be used as long as they have a property of transporting more electrons than holes. As the electron-transport material, any of the following materials with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer has an electron-transport property and includes a material capable of blocking holes. Any of the materials having a hole-blocking property among the above electron-transport materials can be used for the hole-blocking layer.

The hole-blocking layer has an electron-transport property and thus can also be referred to as an electron-transport layer. A layer having a hole-blocking property among the electron-transport layers can also be referred to as a hole-blocking layer.

The electron-injection layer is a layer injecting electrons from the cathode to the electron-transport layer and a layer including a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the LUMO level of the material with a high electron-injection property and the work function value of the material used for the cathode is preferably small (specifically, smaller than or equal to 0.5 eV).

For the electron-injection layer, an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate can be used, for example. The electron-injection layer may have a stacked-layer structure of two or more layers. As an example of the stacked-layer structure, a structure in which lithium fluoride is used for a first layer and ytterbium is provided for a second layer can be given.

The electron-injection layer may include an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

As described above, the charge-generation layer includes at least a charge-generation region. The charge-generation region preferably includes an acceptor material, and for example, preferably includes a hole-transport material and an acceptor material that can be used for the hole-injection layer.

The charge-generation layer preferably includes a layer including a material with a high electron-injection property. The layer can also be referred to as an electron-injection buffer layer. The electron-injection buffer layer is preferably provided between the charge-generation region and the electron-transport layer. By providing the electron-injection buffer layer, an injection barrier between the charge-generation region and the electron-transport layer can be lowered; thus, electrons generated in the charge-generation region can be easily injected into the electron-transport layer.

The electron-injection buffer layer preferably includes an alkali metal or an alkaline earth metal, and for example, can include an alkali metal compound or an alkaline earth metal compound. Specifically, the electron-injection buffer layer preferably includes an inorganic compound containing an alkali metal and oxygen or an inorganic compound containing an alkaline earth metal and oxygen, further preferably includes an inorganic compound containing lithium and oxygen (e.g., lithium oxide (Li₂O)). In that case, the charge-generation layer can be referred to as a layer including lithium. Alternatively, a material that can be used for the electron-injection layer can be suitably used for the electron-injection buffer layer.

The charge-generation layer preferably includes a layer including a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other on the basis of the cross-sectional shapes, characteristics, or the like in some cases.

Note that the charge-generation layer may include a donor material instead of an acceptor material. For example, the charge-generation layer may include a layer including an electron-transport material and a donor material that can be used for the electron-injection layer.

When the light-emitting units are stacked, provision of a charge-generation layer between two light-emitting units can inhibit an increase in drive voltage.

Note that there is no particular limitation on the light-emitting material of the light-emitting layer in the display devices 500 illustrated in FIG. 16 and FIG. 17. For example, in FIG. 16B, the light-emitting layer 523R included in the light-emitting device 550R can include a phosphorescent material, the two light-emitting layers 523G included in the light-emitting device 550G can each include a fluorescent material, and the two light-emitting layers 523B included in the light-emitting device 550B can each include a fluorescent material.

Alternatively, in FIG. 16B, a structure in which the light-emitting layer 523R included in the light-emitting device 550R includes a phosphorescent material, the two light-emitting layers 523G included in the light-emitting device 550G each include a phosphorescent material, and the two light-emitting layers 523B included in the light-emitting device 550B each include a fluorescent material can be employed, for example.

For the display device of one embodiment of the present invention, a structure may be employed in which fluorescent materials are used for all the light-emitting layers included in the light-emitting devices 550R, 550G, and 550B or a structure may be employed in which phosphorescent materials are used for all the light-emitting layers included in the light-emitting devices 550R, 550G, and 550B.

In FIG. 16A, a structure in which the light-emitting layer 523B included in the light-emitting unit 512B_1 includes a phosphorescent material and the light-emitting layer 523B included in the light-emitting unit 512B_2 includes a fluorescent material, or a structure in which the light-emitting layer 523B included in the light-emitting unit 512B_1 includes a fluorescent material and the light-emitting layer 523B included in the light-emitting unit 512B_2 includes a phosphorescent material, i.e., a structure in which a light-emitting layer in a first unit and a light-emitting layer in a second unit include different light-emitting materials may be employed. Note that here, the light-emitting unit 512B_1 and the light-emitting unit 512B_2 are described, and the same structure can also be applied to the light-emitting unit 512G_1 and the light-emitting unit 512G_2.

This embodiment can be combined with the other embodiments as appropriate.

### Embodiment 3

In this embodiment, a light-receiving device that can be used for the display device of one embodiment of the present invention and a display device that has a light-emitting and light-receiving function will be described.

### [Light-Receiving Device]

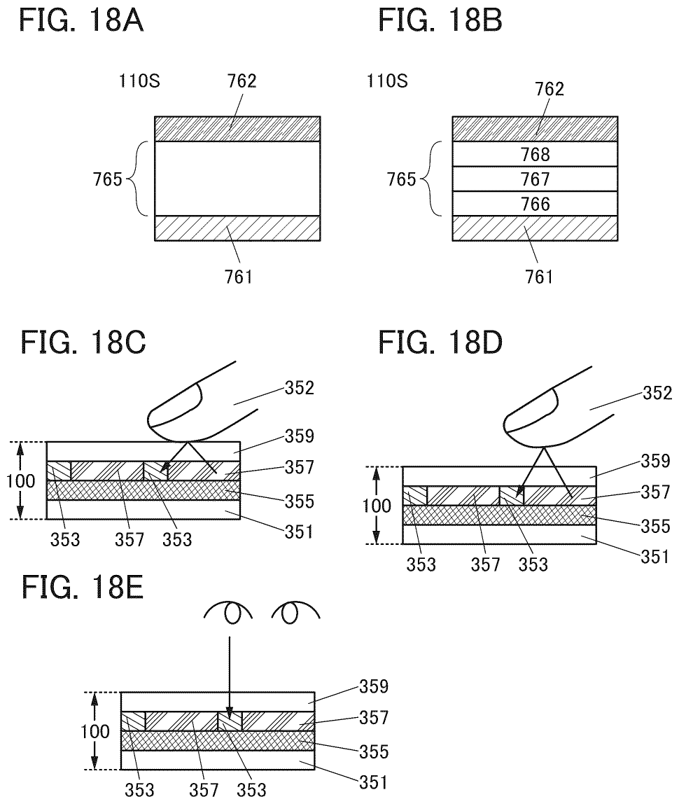

As illustrated in FIG. 18A, a light-receiving device 110S includes a layer 765 between a pair of electrodes (a lower electrode 761 and an upper electrode 762). The layer 765 includes at least one active layer and may further include another layer.

FIG. 18B illustrates a specific example of the layer 765 included in the light-receiving device 110S illustrated in FIG. 18A. The light-receiving device illustrated in FIG. 18B includes a layer 766 over the lower electrode 761, an active layer 767 over the layer 766, a layer 768 over the active layer 767, and the upper electrode 762 over the layer 768. The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layers 766 and 768 are replaced with each other.

Next, materials that can be used for the light-receiving device 110S will be described.

The active layer included in the light-receiving device 110S includes a semiconductor. Examples of the semiconductor include an inorganic semiconductor such as silicon and an organic semiconductor including an organic compound. This embodiment describes an example in which an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ fullerene and C₇₀ fullerene) and fullerene derivatives. Examples of the fullerene derivative include [6,6]-phenyl-C₇₁-butyric acid methyl ester (abbreviation: PC71BM), [6,6]-phenyl-C₆₁-butyric acid methyl ester (abbreviation: PC61BM), and 1′,1″,4′,4″-tetrahydro-di[1,4]methanonaphthaleno[1,2:2′,3′,56,60:2″,3″][5,6]fullerene-C₆₀ (abbreviation: ICBA).

Other examples of an n-type semiconductor material include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material included in the active layer include electron-donating organic semiconductor materials such as copper (II) phthalocyanine (abbreviation: CuPc), tetraphenyldibenzoperiflanthene (abbreviation: DBP), zinc phthalocyanine (abbreviation: ZnPc), tin (II) phthalocyanine (abbreviation: SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c: 4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

The active layer may include a mixture of three or more kinds of materials. For example, a third material may be mixed with an n-type semiconductor material and a p-type semiconductor material in order to extend the wavelength range. The third material may be a low molecular compound or a high molecular compound.

The light-receiving device 110S may further include a hole-transport layer, an electron-transport layer, or a layer including a substance with a bipolar property (a substance with a high electron-transport property and a high hole-transport property), or the like as a layer other than the active layer. Without limitation to the above layers, the light-receiving device 110S may further include a hole-injection layer or a layer including a hole-blocking material, a material with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/polystyrenesulfonic acid (abbreviation: PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

### [Display Device Having Light Detection Function]

The display device of one embodiment of the present invention includes a display portion in which the display devices 110 are arranged in a matrix, and an image can be displayed on the display portion. The light-receiving device 110S may be placed in the display portion. When the light-receiving device 110S is placed, the display portion can have one or both of an image capturing function and a sensing function in addition to an image displaying function. Specifically, the display portion can be used as an image sensor or a touch sensor. That is, light can be detected with the display portion; thus, an image can be captured or an object (e.g., a finger, a hand, or a pen) can be detected.

Furthermore, in the display device of one embodiment of the present invention, the light-emitting device 110 can be used as a light source of the sensor. In that case, when light emitted from the light-emitting device 110 included in the display portion in the display device is reflected (or scattered) by an object, the reflected light (or the scattered light) can be detected by the light-receiving device 110S. Thus, image capturing or touch detection is possible even in a dark place.

In the above-described structure, a light-receiving portion and a light source are not necessarily provided in addition to the display device. For example, an electronic device is not necessarily provided with a biometric authentication device, a capacitive touch panel for scroll operation, or the like in addition to the display device. Thus, with use of the display device of one embodiment of the present invention, the number of components of the electronic device can be reduced and an electronic device can be provided at reduced manufacturing cost.

Specifically, in the display device of one embodiment of the present invention, an organic light-emitting device can be used as the light-emitting device 110 and an organic photodiode can be used as the light-receiving device 110S. The organic light-emitting device and the organic photodiode can be formed over the same substrate.

In the display device that includes the light-emitting device 110 and the light-receiving device 110S in the display portion, each pixel has a light-receiving function, whereby the display device can detect an object while displaying an image. For example, some subpixels included in the display device can be used as a light source and the other subpixels can display an image.

In the case where the light-receiving device 110S is used as an image sensor, the display device can capture an image with the use of the light-receiving device. For example, image capturing for personal authentication with the use of a fingerprint, a palm print, the iris, the shape of a blood vessel (including the shape of a vein and the shape of an artery), a face, or the like can be performed using the image sensor.

With use of the image sensor, an image of the periphery, surface, or inside (e.g., fundus) of the eye of a user of a wearable device including the display device can be captured. Therefore, the wearable device can have a function of detecting one or more selected from blinking, movement of an iris, and movement of an eyelid of the user.

The light-receiving device 110S can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the proximity or contact of an object (e.g., a finger, a hand, or a pen). The touch sensor can detect an object when the display device and the object come in contact with each other. The near touch sensor can detect an object even when the object is not in contact with the display device. For example, the display device is preferably capable of detecting an object when the distance between the display device and the object is greater than or equal to 0.1 mm and less than or equal to 300 mm, preferably greater than or equal to 3 mm and less than or equal to 50 mm. This structure enables the display device to be operated without direct contact of an object; in other words, the display device can be operated in a contactless (touchless) manner. With the above structure, the display device can have a reduced risk of being dirty or damaged, or can be operated without the object directly touching a dirt (e.g., dust or a virus) attached to the display device.

The display device 100 illustrated in FIG. 18C to FIG. 18E includes, between a substrate 351 and a substrate 359, a layer 353 in which a light-receiving device is provided, a functional layer 355, and a layer 357 in which a light-emitting device is provided. FIG. 18C illustrates a structure of a touch sensor, and FIG. 18D illustrates a structure of a near touch sensor.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure including neither a switch nor a transistor may be employed.

After light emitted from the light-emitting device provided in the layer 357 is reflected by a finger 352 in contact with or proximity to the display device 100 as illustrated in FIG. 18C and FIG. 18D, the reflected light is detected by the light-receiving device provided in the layer 353. This enables the contact or proximity of the finger 352 with or to the display device 100 to be detected.

FIG. 18E illustrates an example where information on the periphery, surface, or inside of the human eye (e.g., the number of blinks, movement of an eyeball, and movement of an eyelid) is detected.

This embodiment can be combined with the other embodiments as appropriate.

### Embodiment 4

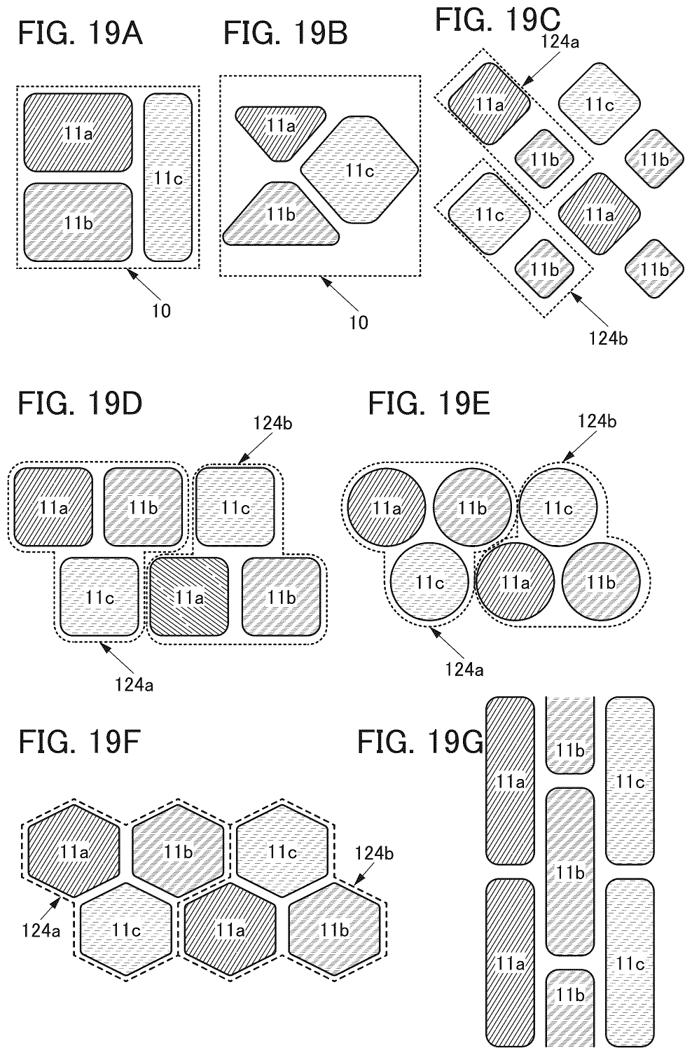

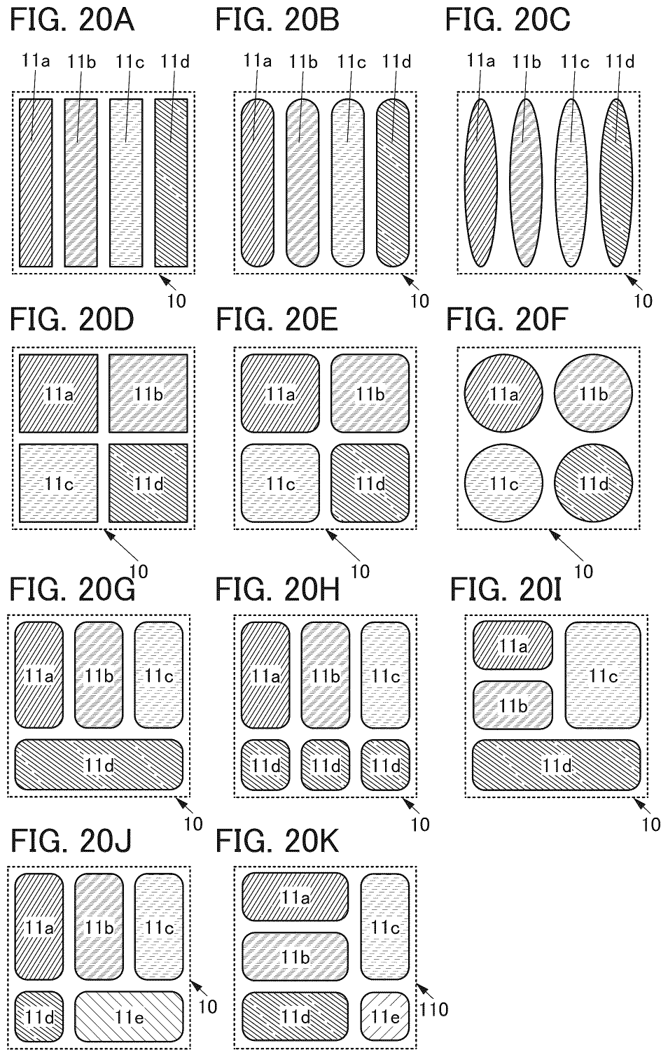

In this embodiment, the layouts of a light-emitting device of one embodiment of the present invention will be described with reference to FIG. 19 and FIG. 20. In FIG. 19 and FIG. 20, a red-light-emitting device can have a single structure and a blue-light-emitting device can have a tandem structure. A green-light-emitting device may have a single structure or a tandem structure.

### [Layout]

Pixel layouts different from the that in the above embodiment will be mainly described in this embodiment. The top surface shapes of subpixels illustrated in FIG. 19 and FIG. 20 correspond to the top surface shape of a light-emitting region (or a light-receiving region). Examples of the top surface shape of the subpixel include polygons such as a triangle, a tetragon (including a rectangle and a square), and a pentagon; polygons with rounded corners; an ellipse; and a circle.

A pixel 10 illustrated in FIG. 19A is composed of three subpixels 11a, 11b, and 11c. The pixel 10 illustrated in FIG. 19A can be referred to as an S-stripe arrangement; the subpixel 11a and the subpixel 11b are arranged and the subpixel 11c is adjacent to these subpixels. In this manner, the shapes and sizes of the subpixels can be determined independently. For example, the size of a subpixel including a light-emitting device with higher reliability can be smaller. The size of a subpixel having a tandem structure can be smaller than that of a subpixel having a single structure.

The pixel 10 illustrated in FIG. 19B includes the subpixel 11a whose top surface has a rough triangle shape with rounded corners, the subpixel 11b whose top surface has a rough triangle shape with rounded corners, and the subpixel 11c whose top surface has a rough tetragonal or rough hexagonal shape with rounded corners. The subpixel 11a has a larger light-emitting area than the subpixel 11b. In this manner, the shapes and sizes of the subpixels can be determined independently. For example, the size of a subpixel including a light-emitting device with higher reliability can be smaller. The size of a subpixel having a tandem structure can be smaller than that of a subpixel having a single structure.

Pixels 124a and 124b illustrated in FIG. 19C employ PenTile arrangement. FIG. 19C illustrates an example in which the pixels 124a each including the subpixel 11a and the subpixel 11b and the pixels 124b each including the subpixel 11b and the subpixel 11c are alternately arranged.

The pixels 124a and 124b illustrated in FIG. 19D to FIG. 19F employ delta arrangement. The pixel 124a includes two subpixels (the subpixels 11a and 11b) in the upper row (first row) and one subpixel (the subpixel 11c) in the lower row (second row). The pixel 124b includes one subpixel (the subpixel 11c) in the upper row (first row) and two subpixels (the subpixels 11a and 11b) in the lower row (second row).

FIG. 19D illustrates an example in which each subpixel has a rough tetragonal top surface shape with rounded corners, FIG. 19E illustrates an example in which each subpixel has a circular top surface shape, and FIG. 19F illustrates an example in which each subpixel has a rough hexagonal top surface shape with rounded corners.

In FIG. 19F, subpixels are arranged inside the respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 11a, the subpixel 11a is surrounded by three subpixels 11b and three subpixels 11c that are alternately arranged. FIG. 19G illustrates an example in which subpixels of different colors are arranged in a zigzag manner. Specifically, the positions of the top sides of two subpixels arranged in the column direction (e.g., the subpixel 11a and the subpixel 11b, or the subpixel 11b and the subpixel 11c) are not aligned in the top view.

In the pixels illustrated in FIG. 19A to FIG. 19G, for example, the subpixel 11a is preferably a subpixel R emitting red light, the subpixel 11b is preferably a subpixel G emitting green light, and the subpixel 11c is preferably a subpixel B emitting blue light. Note that the structure of the subpixels is not limited thereto, and the colors and arrangement order of the subpixels can be determined as appropriate. For example, the subpixel 11b may be the subpixel R emitting red light and the subpixel 11a may be the subpixel G emitting green light.

In a lithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel sometimes has a polygonal shape with rounded corners, an elliptical shape, a circular shape, or the like.

Furthermore, in the method for manufacturing a display device of one embodiment of the present invention, an organic layer is processed with the use of a resist mask. A resist film formed over the organic layer needs to be cured at a temperature lower than the upper temperature limit of the organic layer. Thus, the resist film is insufficiently cured in some cases depending on the upper temperature limit of the material of the organic layer and the curing temperature of a resist material. An insufficiently cured resist film may have a shape different from a desired shape at the time of processing. As a result, the top surface of the organic layer, i.e., the top surface of a light-emitting region may have a polygonal shape with rounded corners, an elliptical shape, a circular shape, or the like. For example, when a resist mask with a square top surface is intended to be formed, a resist mask with a circle top surface may be formed, and the top surface of the organic layer may be circular.

Note that to obtain a desired top surface shape of the organic layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

As illustrated in FIG. 20A to FIG. 20I, the pixel can include four types of subpixels.

The pixels 10 illustrated in FIG. 20A to FIG. 20C employ stripe arrangement.

FIG. 20A illustrates an example in which each subpixel has a rectangular top surface shape, FIG. 20B illustrates an example in which each subpixel has a top surface shape formed by combining two half circles and a rectangle, and FIG. 20C illustrates an example in which each subpixel has an elliptical top surface shape.

The pixels 10 illustrated in FIG. 20D to FIG. 20F employ matrix arrangement.

FIG. 20D illustrates an example in which each subpixel has a square top surface shape, FIG. 20E illustrates an example in which each subpixel has a rough square top surface shape with rounded corners, and FIG. 20F illustrates an example in which each subpixel has a circular top surface shape.

The pixel 10 illustrated in FIG. 20G includes three subpixels (the subpixels 11a, 11b, and 11c) in the upper row (first row) and one subpixel (a subpixel 11d) in the lower row (second row). In other words, the pixel 10 includes the subpixel 11a in the left column (first column), the subpixel 11b in the center column (second column), the subpixel 11c in the right column (third column), and the subpixel 11d across these three columns.

The pixel 10 illustrated in FIG. 20H includes three subpixels (the subpixels 11a, 11b, and 11c) in the upper row (first row) and three subpixels 11d in the lower row (second row). In other words, the pixel 10 includes the subpixel 11a and the subpixel 11d in the left column (first column), the subpixel 11b and another subpixel 11d in the center column (second column), and the subpixel 11c and the other subpixel 11d in the right column (third column). Matching the positions of the subpixels in the upper row and the lower row as illustrated in FIG. 20H enables efficient removal of dust and the like that would be produced in the manufacturing process. Thus, a display device with high display quality can be provided.

The pixel 10 illustrated in FIG. 20I includes the subpixel 11a in the upper row (first row), the subpixel 11b in the center row (second row), the subpixel 11c across the first and second rows, and one subpixel (the subpixel 11d) in the lower row (third row). In other words, the pixel 10 includes the subpixels 11a and 11b in the left column (first column), the subpixel 11c in the right column (second column), and the subpixel 11d across these two columns.

The pixels 10 illustrated in FIG. 20A to FIG. 20I are each composed of the four subpixels 11a, 11b, 11c, and 11d.

The subpixels 11a, 11b, 11c, and 11d can include light-emitting devices with different emission colors. The subpixels 11a, 11b, 11c, and 11d can be subpixels of four colors of R, G, B, and white (W), subpixels of four colors of R, G, B, and Y, or subpixels of R, G, B, and infrared light (IR), for example.

In the pixels 10 illustrated in FIG. 20A to FIG. 20I, for example, the subpixel 11a is preferably a subpixel R emitting red light, the subpixel 11b is preferably a subpixel G emitting green light, the subpixel 11c is preferably a subpixel B emitting blue light, and the subpixel 11d is preferably any of a subpixel W emitting white light, a subpixel Y emitting yellow light, and a subpixel IR emitting near-infrared light. In the case of such a structure, stripe arrangement is employed as the layout of R, G, and B in the pixels 10 illustrated in FIG. 20G and FIG. 20H, leading to higher display quality. In addition, what is called S-stripe arrangement is employed as the layout of R, G, and B in the pixel 10 illustrated in FIG. 20I, leading to higher display quality.

The pixel 10 may include a subpixel including a light-receiving device.

In the pixels 10 illustrated in FIG. 20A to FIG. 20I, any one of the subpixel 11a to the subpixel 11d may be a subpixel including a light-receiving device.

In the pixels 10 illustrated in FIG. 20A to FIG. 20I, for example, the subpixel 11a is preferably a subpixel R emitting red light, the subpixel 11b is preferably a subpixel G emitting green light, the subpixel 11c is preferably a subpixel B emitting blue light, and the subpixel 11d is preferably a subpixel S including the light-receiving device 110S. In the case of such a structure, stripe arrangement is employed as the layout of R, G, and B in the pixels 10 illustrated in FIG. 20G and FIG. 20H, leading to higher display quality. In addition, what is called S-stripe arrangement is employed as the layout of R, G, and B in the pixel 10 illustrated in FIG. 20I, leading to higher display quality.

There is no particular limitation on the wavelength of light detected by the subpixel S including a light-receiving device. The subpixel S can have a structure in which one or both of visible light and infrared light are detected.

As illustrated in FIG. 20J and FIG. 20K, the pixel can include five types of subpixels.

The pixel 10 illustrated in FIG. 20J includes three subpixels (the subpixels 11a, 11b, and 11c) in the upper row (first row) and two subpixels (the subpixel 11d and a subpixel 11e) in the lower row (second row). In other words, the pixel 10 includes the subpixels 11a and 11d in the left column (first column), the subpixel 11b in the center column (second column), the subpixel 11c in the right column (third column), and the subpixel 11e across the second and third columns.

The pixel 10 illustrated in FIG. 20K includes the subpixel 11a in the upper row (first row), the subpixel 11b in the center row (second row), the subpixel 11c across the first and second rows, and two subpixels (the subpixels 11d and 11e) in the lower row (third row). In other words, the pixel 10 includes the subpixels 11a, 11b, and 11d in the left column (first column) and the subpixels 11c and 11e in the right column (second column).

In the pixels 10 illustrated in FIG. 20J and FIG. 20K, for example, the subpixel 11a is preferably a subpixel R emitting red light, the subpixel 11b is preferably a subpixel G emitting green light, and the subpixel 11c is preferably a subpixel B emitting blue light. In the case of such a structure, stripe arrangement is employed as the layout of R, G, and B in the pixel 10 illustrated in FIG. 20J, leading to higher display quality. In addition, what is called S-stripe arrangement is employed as the layout of R, G, and B in the pixel 10 illustrated in FIG. 20K, leading to higher display quality.

In the pixels 10 illustrated in FIG. 20J and FIG. 20K, for example, the subpixel S including a light-receiving device is preferably used as at least one of the subpixel 11d and the subpixel 11e. In the case where light-receiving devices are used in both the subpixel 11d and the subpixel 11e, the light-receiving devices may have different structures. For example, the wavelength ranges of detected light may be different at least partly. Specifically, one of the subpixel 11d and the subpixel 11e may include a light-receiving device mainly detecting visible light and the other may include a light-receiving device mainly detecting infrared light.

In the pixels 10 illustrated in FIG. 20J and FIG. 20K, for example, the subpixel S including a light-receiving device is preferably used as one of the subpixel 11d and the subpixel 11e and a subpixel including a light-emitting device that can be used as a light source is preferably used as the other. For example, one of the subpixel 11d and the subpixel 11e is preferably the subpixel IR emitting infrared light and the other is preferably the subpixel S including a light-receiving device detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels including the light-emitting devices can employ any of a variety of layouts in the display device of one embodiment of the present invention. The display device of one embodiment of the present invention can have a structure in which the pixel includes both a light-emitting device and a light-receiving device. Also in this case, any of a variety of layouts can be employed.

This embodiment can be combined with the other embodiments as appropriate.

### Embodiment 5

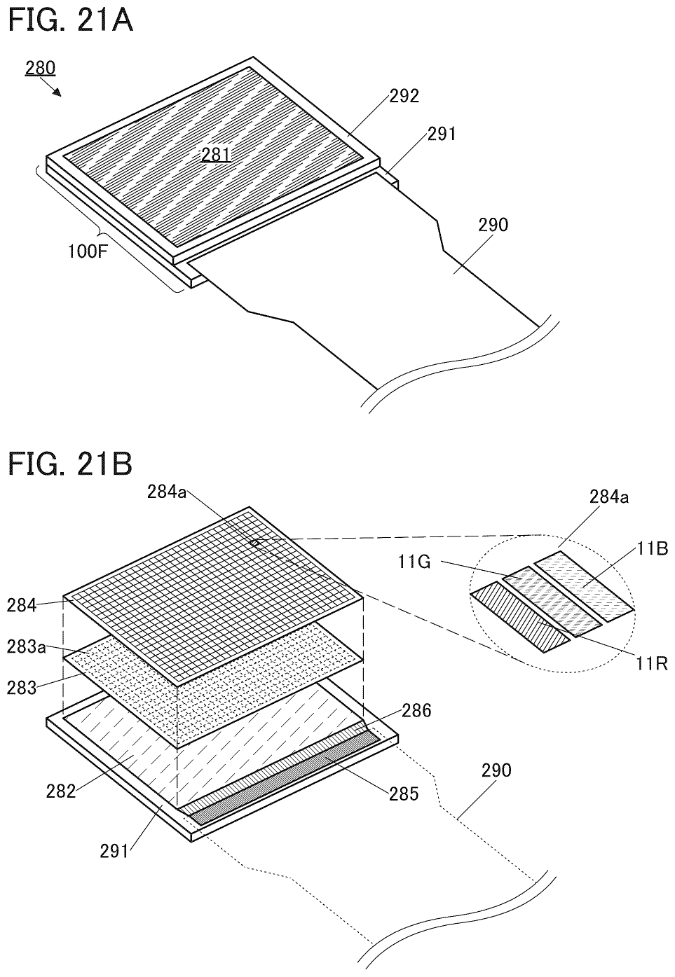

In this embodiment, the display device of one embodiment of the present invention will be described with reference to FIG. 21 to FIG. 29.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display device of this embodiment can be a high-definition display device or a large-sized display device. Accordingly, the display device of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer and the like, digital signage, and a large game machine such as a pachinko machine.

### [Display Module]

FIG. 21A is a perspective view of a display module 280. The display module 280 includes a display device 100F and an FPC 290. The display module 280 includes a substrate 291 and a substrate 292. The display module 280 includes a display region 281. The display region 281 is a region where an image is displayed.

FIG. 21B is a perspective view schematically illustrating a structure on the substrate 291 side. Over the substrate 291, a circuit portion 282, a pixel driver circuit portion 283 over the circuit portion 282, and a pixel portion 284 over the pixel driver circuit portion 283 are stacked. In addition, a terminal portion 285 to be connected to the FPC 290 is provided in a portion over the substrate 291 that does not overlap with the pixel portion 284. The terminal portion 285 is electrically connected to the circuit portion 282 or the like through a wiring portion 286 formed of a plurality of wirings.

The pixel portion 284 includes a plurality of pixels 284a arranged periodically. An enlarged view of one pixel 284a is illustrated on the right side in FIG. 21B. The pixel 284a can employ any of the structures described in the above embodiments and includes the subpixels 11R, 11G, and 11B.

The pixel driver circuit portion 283 includes pixel circuits 283a corresponding to the pixels 284a. One pixel circuit 283a is a circuit that controls driving of a plurality of elements included in one pixel 284a. For example, the pixel circuit 283a can include at least one selection transistor, one current control transistor (driving transistor), and a capacitor for one light-emitting device. In that case, a gate signal is input to a gate of the selection transistor, and a source signal is input to a source of the selection transistor.

The circuit portion 282 includes a circuit for driving the pixel circuits 283a. For example, the circuit portion 282 preferably includes one or both of a gate line driver circuit and a source line driver circuit. The circuit portion 282 may further include at least one of an arithmetic circuit, a memory circuit, a power supply circuit, and the like.

The FPC 290 functions as a wiring for supplying a video signal, a power supply potential, or the like to the circuit portion 282 from the outside. In addition, an IC may be mounted on the FPC 290.

The display module 280 can have a structure in which one or both of the pixel driver circuit portion 283 and the circuit portion 282 are stacked below the pixel portion 284; thus, the effective display area ratio or the aperture ratio of the display region 281 can be high. For example, the aperture ratio of the display region 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display region 281 included in the display module 280 are not seen even when the display region is enlarged by the lens, so that display providing a high sense of immersion can be performed. Without being limited thereto, the display module 280 can also be suitably used for an electronic device including a relatively small display portion. For example, the display module 280 can be suitably used for a display portion of a wearable electronic device such as a wristwatch.

### [Display Device 100F]

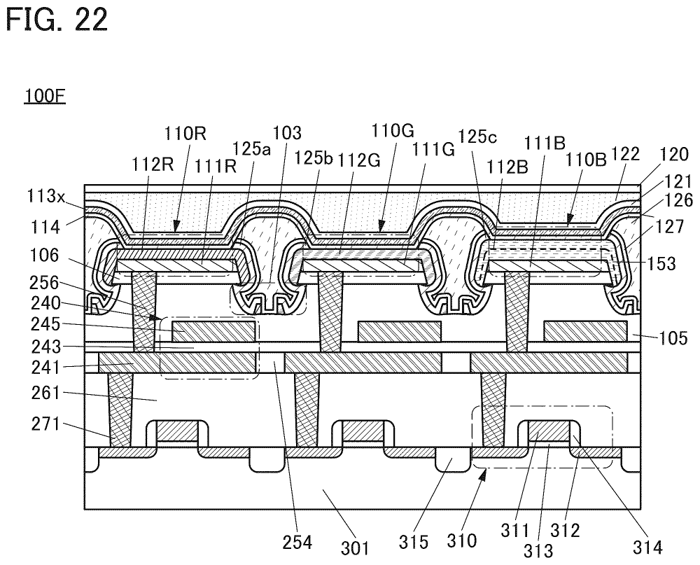

FIG. 22 is a cross-sectional view of the display device 100F. The display device 100F includes a substrate 301, a transistor 310, a capacitor 240, the red-light-emitting device 110R, the green-light-emitting device 110G, and the blue-light-emitting device 110B. As the light-emitting devices used in the display device 100F, the red-, green-, and blue-light-emitting devices described in Embodiment 1 can be used. For example, the red-light-emitting device 110R has a single structure, the blue-light-emitting device 110B has a tandem structure, and the tandem structure includes the charge-generation layer 153. Note that the green-light-emitting device 110G may have a single structure or a tandem structure.

The transistor 310 is a transistor that includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is located between the substrate 301 and the conductive layer 311 and functions as a gate insulating layer. The low-resistance region 312 is a region where the substrate 301 is doped with an impurity, and functions as one of a source and a drain. The insulating layers 314 are provided to cover side surfaces of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned between these conductive layers. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that any conductive layer of the layers included in the transistor is preferably used to surround the outer side of the display region 281 (or the pixel portion 284). The conductive layer can be referred to as a guard ring. By providing the guard ring, elements such as a transistor and a light-emitting device can be inhibited from being broken due to ESD (electrostatic discharge) or charging caused by a step using plasma.

The insulating layer 105 is provided to cover the capacitor 240. The depressed portion 103 can be provided in the insulating layer 105. A conductive layer 256 electrically connected to the conductive layer 241 included in the capacitor 240 is preferably formed in the insulating layer 105.

The insulating layer 105 and the insulating layer 106 preferably include an inorganic material. In the case where the depressed portion 103 can be formed in the insulating layer 105, the insulating layer 106 can be omitted. The insulating layer 106 is provided over the insulating layer 105, and the red-light-emitting device 110R, the green-light-emitting device 110G, and the blue-light-emitting device 110B are provided over the insulating layer 106. The insulating layer 126 is provided in a region between adjacent light-emitting devices. The insulating layer 126 preferably includes an organic material, the insulating layer 126 is provided at a position overlapping with the depressed portion 103, and the insulating layers 125a, 125b, and 125c and the insulating layer 127 over the insulating layers 125a, 125b, and 125c are provided in the depressed portion 103. The insulating layer 125a is located over the organic layer 112R included in the red-light-emitting device 110R, the insulating layer 125b is located over the organic layer 112G included in the green-light-emitting device 110G, and the insulating layer 125c is located over the organic layer 112B included in the blue-light-emitting device 110B. The insulating layer 125a, the insulating layer 125b, and the insulating layer 125c preferably include an inorganic material.

The organic layer 112B has a tandem structure. This can improve the reliability of the light-emitting device 110B and the display device. The organic layer 112R has a single structure. The organic layer 112G may have a single structure or a tandem structure.

The lower electrode 111R, the lower electrode 111G, and the lower electrode 111B are electrically connected to one of the source and the drain of the transistor 310 through the conductive layer 256 and the plug 271 formed in the insulating layer 243, the insulating layer 105, and the like.

The protective layer 121 is provided over the red-light-emitting device 110R, the green-light-emitting device 110G, and the blue-light-emitting device 110B. A substrate 120 is bonded to the protective layer 121 with a resin layer 122.

### [Display Device 100G]

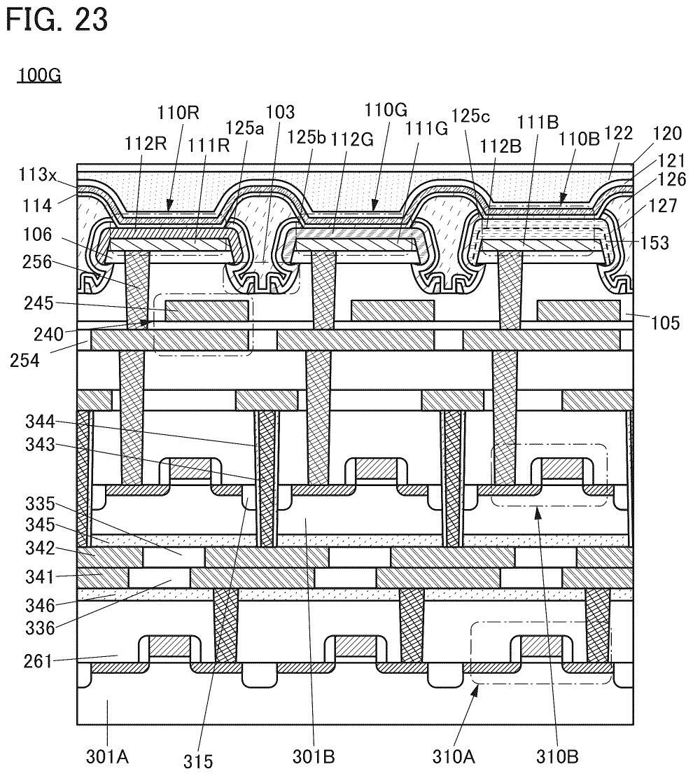

A display device 100G illustrated in FIG. 23 has a structure where a transistor 310A and a transistor 310B in each of which a channel is formed in a semiconductor substrate are stacked. Note that in the description of the display device below, portions similar to those of the above-described display device are not described in some cases.

In the display device 100G, a substrate 301B provided with the transistor 310B, the capacitor 240, and the light-emitting devices is bonded to a substrate 301A provided with the transistor 310A.

Here, an insulating layer 345 is preferably provided on the bottom surface of the substrate 301B. An insulating layer 346 is preferably provided over the insulating layer 261 provided over the substrate 301A. The insulating layers 345 and 346 are insulating layers functioning as protective layers and can inhibit diffusion of impurities into the substrate 301B and the substrate 301A. As each of the insulating layers 345 and 346, an insulating film including the same inorganic material as the protective layer 121 can be used.

The substrate 301B is provided with a plug 343 that penetrates the substrate 301B and the insulating layer 345. An insulating layer 344 is preferably provided to cover a side surface of the plug 343. The insulating layer 344 is an insulating layer functioning as a protective layer and can inhibit diffusion of impurities into the substrate 301B. As the insulating layer 344, an insulating film including the same inorganic material as the protective layer 121 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

Meanwhile, a conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The same conductive material is preferably used for the conductive layer 341 and the conductive layer 342. A metal film including an element selected from Al, Cr, Cu, Ta, Ti, Mo, and W, a metal nitride film including the above element as a component (a titanium nitride film, a molybdenum nitride film, or a tungsten nitride film), or the like can be used, for example. Copper is particularly preferably used for the conductive layer 341 and the conductive layer 342. In that case, it is possible to employ Cu—Cu (copper-to-copper) direct bonding (a technique for achieving electrical continuity by connecting Cu (copper) pads).

### [Display Device 100H]

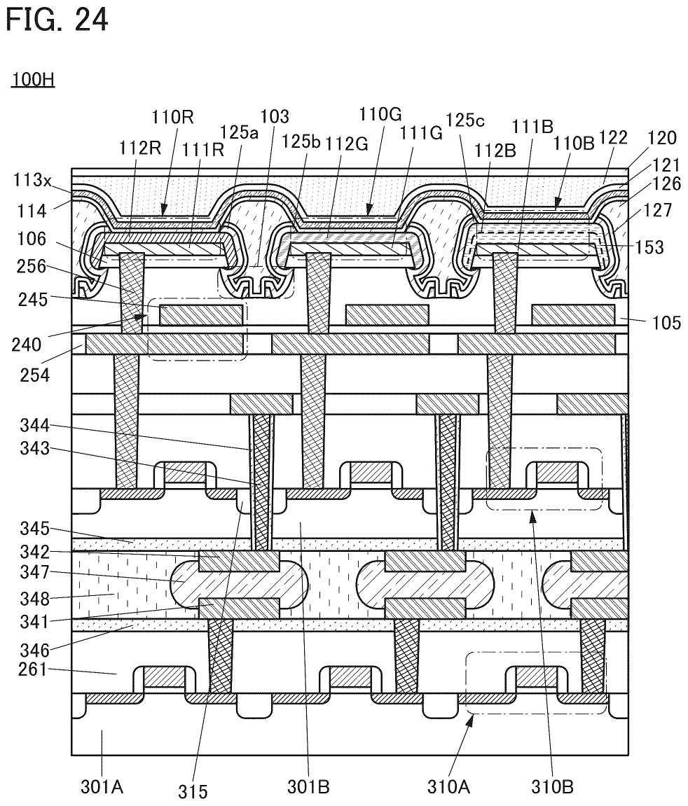

A display device 100H illustrated in FIG. 24 has a structure in which the conductive layer 341 and the conductive layer 342 are bonded to each other through a bump 347.

As illustrated in FIG. 24, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. For another example, solder may be used for the bump 347. An adhesive layer 348 may be provided between the insulating layer 345 and the insulating layer 346. In the case where the bump 347 is provided, a structure without the insulating layer 335 and the insulating layer 336 may be employed.

### [Display Device 100I]

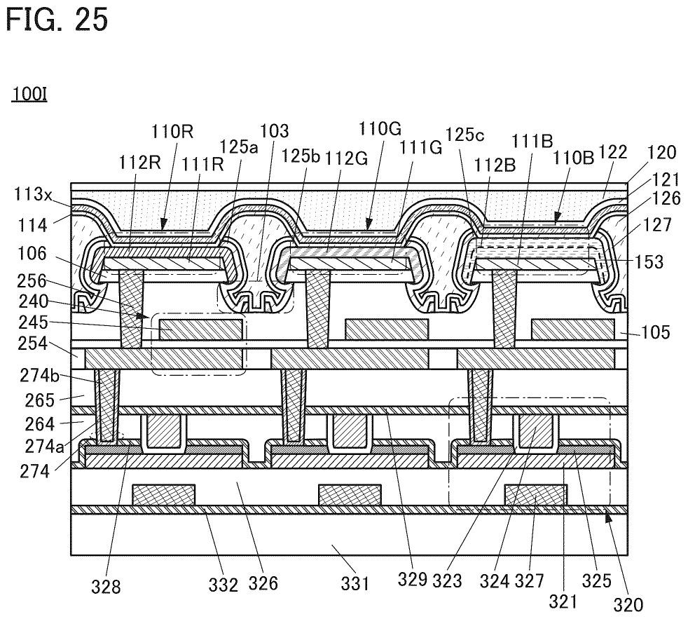

A display device 100I illustrated in FIG. 25 differs from the display device 100F mainly in a structure of a transistor.

A transistor 320 is a transistor (an OS transistor) in which a metal oxide (also referred to as an oxide semiconductor) is used in a semiconductor layer where a channel is formed.

The transistor 320 includes a semiconductor layer 321, an insulating layer 323, a conductive layer 324, a pair of conductive layers 325, an insulating layer 326, and a conductive layer 327.

As the substrate 331, an insulating substrate or a semiconductor substrate can be used.

The insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used for at least part of the insulating layer 326 that is in contact with the semiconductor layer 321. The top surface of the insulating layer 326 is preferably planarized.

The semiconductor layer 321 is provided over the insulating layer 326. The semiconductor layer 321 preferably includes a metal oxide (also referred to as an oxide semiconductor) film having semiconductor characteristics. The pair of conductive layers 325 are provided over and in contact with the semiconductor layer 321, and function as a source electrode and a drain electrode.

An insulating layer 328 is provided to cover the top surfaces and side surfaces of the pair of conductive layers 325, the side surfaces of the semiconductor layer 321, and the like, and an insulating layer 264 is provided over the insulating layer 328. The insulating layer 328 functions as a barrier layer that prevents diffusion of impurities such as water and hydrogen from the insulating layer 264 or the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with side surfaces of the insulating layer 264, the insulating layer 328, and the conductive layer 325 and the top surface of the semiconductor layer 321, and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so as to be level or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 or the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surface of an opening in the insulating layer 265, the insulating layer 329, the insulating layer 264, and the insulating layer 328 and part of the top surface of the conductive layer 325, and a conductive layer 274b in contact with the top surface of the conductive layer 274a. In that case, a conductive material in which hydrogen and oxygen are less likely to diffuse is preferably used for the conductive layer 274a.

### [Display Device 100J]

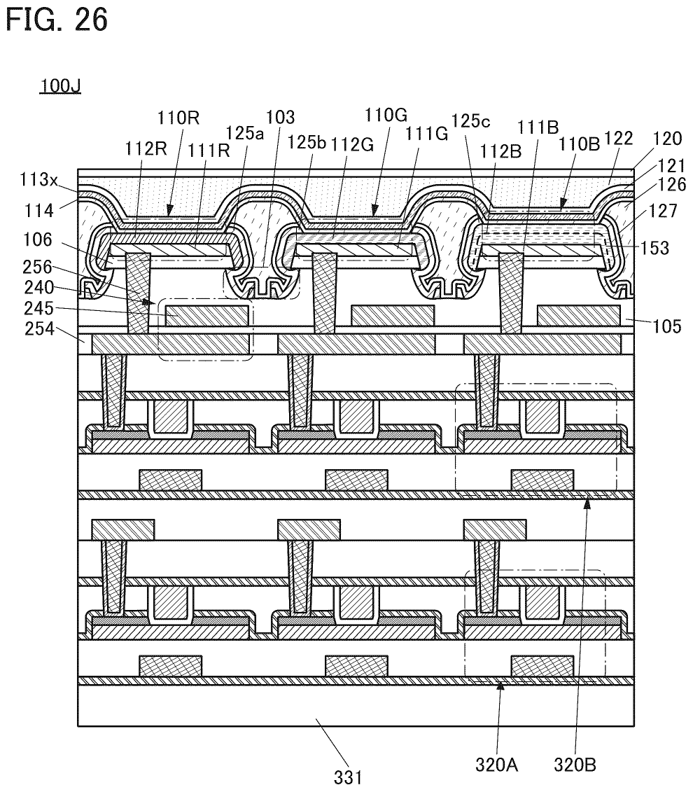

The display device 100J illustrated in FIG. 26 has a structure in which a transistor 320A and a transistor 320B each including an oxide semiconductor in a semiconductor where a channel is formed are stacked.

The display device 100I can be referred to for the transistor 320A, the transistor 320B, and the components around them.

Although the structure in which two transistors including an oxide semiconductor are stacked is described here, the present invention is not limited thereto. For example, a structure may be employed in which three or more transistors are stacked.

### [Display Device 100K]

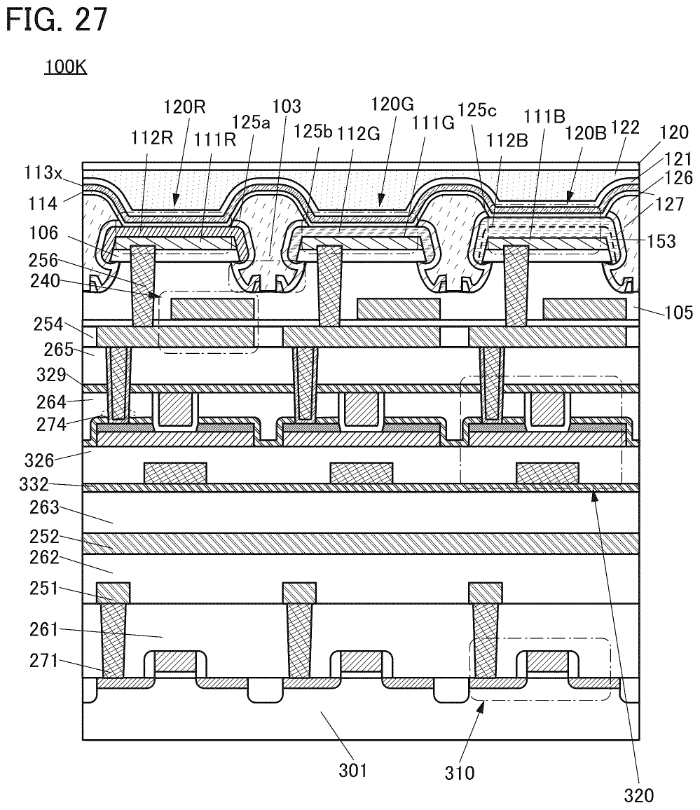

The display device 100K illustrated in FIG. 27 has a structure in which the transistor 310 whose channel is formed in the substrate 301 and the transistor 320 including a metal oxide in a semiconductor layer where a channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in a pixel driver circuit. The transistor 310 can be used as a transistor included in a pixel driver circuit or a transistor included in a driver circuit (a gate line driver circuit or a source line driver circuit) for driving the pixel driver circuit. The transistor 310 and the transistor 320 can also be used as transistors included in a variety of circuits such as an arithmetic circuit and a memory circuit.

With such a structure, not only the pixel circuit but also the driver circuit or the like can be formed directly under the light-emitting device; thus, the display device can be downsized as compared to the case where the driver circuit is provided around a display region.

### [Display Device 100L]

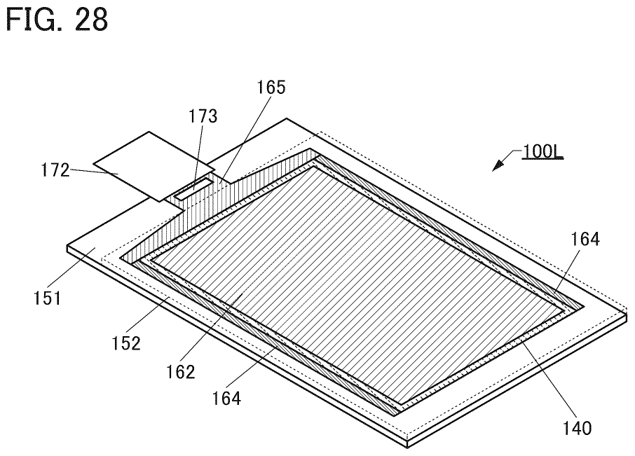

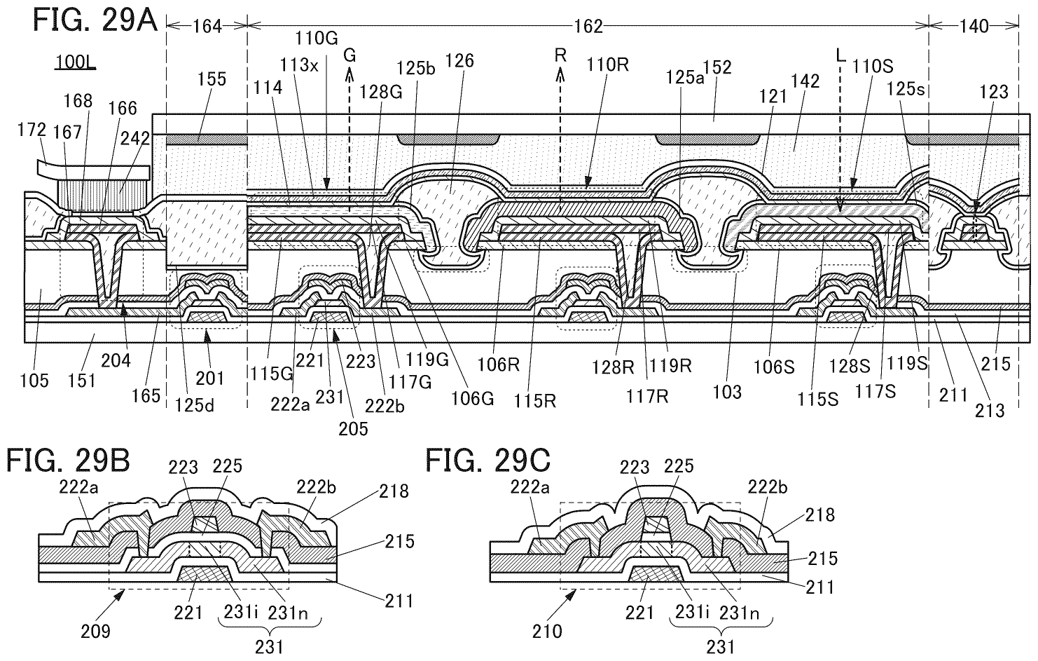

FIG. 28 is a perspective view of a display device 100L and FIG. 29A is a cross-sectional view of the display device 100L. The display device 100L includes a display region 162, a connection portion 140, a circuit 164, a wiring 165, and the like. The display device 100L is mounted with an IC 173 and an FPC 172; thus, the structure can be regarded as a display module including the display device 100L, the IC (integrated circuit), and the FPC. The display device 100L has a structure in which a substrate 152 and a substrate 151 are bonded to each other; in FIG. 28, the substrate 152 is denoted by a dashed line. The display region 162 includes the light-receiving device 110S.

The connection portion 140 is provided outside the display region 162. The connection portion 140 can be provided along one or more sides of the display region 162. The number of the connection portions 140 can be one or more. FIG. 28 illustrates an example in which the connection portion 140 is provided to surround the four sides of the display portion. The common electrode 113x of a light-emitting device is electrically connected to a conductive layer 123 in the connection portion 140, so that a potential can be supplied to the common electrode.

As the circuit 164, a scan line driver circuit can be used, for example, and the circuit 164 includes a transistor 201. The circuit 164 includes the insulating layer 105 including a depressed portion, and an insulating layer 125d, the insulating layer 126, and the protective layer 121 at a position overlapping with the depressed portion. In the circuit 164, a lower electrode is not provided; thus, the insulating layer 106 is not necessarily provided. A structure without the insulating layer 106 is preferably employed, in which case moisture in the insulating layer 105 is easily released. Furthermore, in the case where sufficient flatness above the transistor 201 is ensured, a depressed portion is not necessarily provided in the insulating layer 105 in the circuit 164. It is preferable that the insulating layer 105 include an organic material and the insulating layer 106 include an inorganic material.

The wiring 165 has a function of supplying a signal and power to the display region 162 and the circuit 164. The signal and power are input to the wiring 165 from the outside through the FPC 172 or input to the wiring 165 from the IC 173. As the wiring 165, a conductive layer formed as a source or a drain of the transistor can be used.

FIG. 29A illustrates an example in which the substrate 151 is provided with the FPC 172. The IC may be mounted on the FPC 172 by a COG (Chip On Glass) method, a COF (Chip On Film) method, or the like. The IC can include a scan line driver circuit, a signal line driver circuit, or the like. Note that the display device 100L is not necessarily provided with an IC.

FIG. 29A illustrates an example of cross sections of part of a region including the FPC 172, part of the circuit 164, part of the display region 162, and part of the connection portion 140 of the display device 100L.

In FIG. 29A, the display device 100L includes the transistor 201, a transistor 205, the red-light-emitting device 110R, the green-light-emitting device 110G, the blue-light-emitting device, the light-receiving device 110S, and the like between the substrate 151 and the substrate 152. As described in Embodiment 1, the red-light-emitting device 110R has a single structure and the blue-light-emitting device 110B has a tandem structure; however, the blue-light-emitting device 110B is omitted in FIG. 29A. The green-light-emitting device 110G may have a single structure or a tandem structure. When a tandem structure is applied to the blue-light-emitting device 110B, the reliability of the display device can be improved.

The red-light-emitting device 110R includes, over the insulating layer 106R, a conductive layer 115R, a resin layer 128R filling a depressed portion defined by the conductive layer 115R, a conductive layer 117R over the resin layer 128R, and a conductive layer 119R over the conductive layer 117R. All of the conductive layers 115R, 117R, and 119R can be referred to as lower electrodes. An end portion of the conductive layer 115R is preferably aligned with an end portion of the conductive layer 117R. An end portion of the conductive layer 119R is preferably positioned beyond the end portions of the conductive layer 115R and the conductive layer 117R and is preferably aligned with an end portion of the insulating layer 106R.

The green-light-emitting device 110G includes, over the insulating layer 106G, a conductive layer 115G, a resin layer 128G filling a depressed portion defined by the conductive layer 115G, a conductive layer 117G over the resin layer 128G, and a conductive layer 119G over the conductive layer 117G. All of the conductive layers 115G, 117G, and 119G can be referred to as lower electrodes. An end portion of the conductive layer 115G is preferably aligned with an end portion of the conductive layer 117G. An end portion of the conductive layer 119G is preferably positioned beyond the end portions of the conductive layer 115G and the conductive layer 117G and is preferably aligned with an end portion of the insulating layer 106G.

Although lower electrodes of the blue-light-emitting device are not illustrated, the lower electrodes have structures similar to those of the lower electrodes of the red-light-emitting device 110R and the lower electrodes of the green-light-emitting device 110G.

The light-receiving device 110S includes a conductive layer 115S over an insulating layer 106S, a resin layer 128S filling a depressed portion defined by the conductive layer 115S, a conductive layer 117S over the resin layer 128S, and a conductive layer 119S over the conductive layer 117S. All of the conductive layers 115S, 117S, and 119S can be referred to as lower electrodes. An end portion of the conductive layer 115S is preferably aligned with an end portion of the conductive layer 117S. An end portion of the conductive layer 119S is preferably positioned beyond the end portions of the conductive layer 115S and the conductive layer 117S and is preferably aligned with an end portion of the insulating layer 106S.

The conductive layer 115R is connected to a conductive layer 222b included in the transistor 205 through an opening provided in the insulating layers 106, 105, 215, and 213. That is, the lower electrode of the light-emitting device is connected to the conductive layer 222b included in the transistor 205 through the opening provided in the insulating layers 106, 105, 215, and 213.

The conductive layer 115G is connected to the conductive layer 222b included in the transistor 205 through an opening provided in the insulating layers 106, 105, 215, and 213. That is, the lower electrode of the light-emitting device is connected to the conductive layer 222b included in the transistor 205 through the opening provided in the insulating layers 106, 105, 215, and 213.

The conductive layer 115S is connected to the conductive layer 222b included in the transistor 205 through an opening provided in the insulating layers 106, 105, 215, and 213. That is, the lower electrode of the light-receiving device is connected to the conductive layer 222b included in the transistor 205 through the opening provided in the insulating layers 106, 105, 215, and 213.

The resin layers 128R and 128G have a function of filling the depressed portions defined by the conductive layers 115R and 115G. Thus, the conductive layers 117R and 117G positioned over the resin layers 128R and 128G can have flat regions and the regions can also be used as light-emitting regions, increasing the aperture ratio of the pixels.

The resin layers 128R, 128G, and 128S may each be an insulating layer or a conductive layer. Any of a variety of inorganic insulating materials, organic insulating materials, and conductive materials can be used for the resin layers 128R, 128G, and 128S as appropriate. Specifically, the resin layers 128R, 128G, and 128S are preferably formed using an insulating material and are particularly preferably formed using an organic insulating material.

The top surfaces and side surfaces of the conductive layers 119R, 119G, and 119S are covered with the organic layers 112R and 112G and an active layer. Thus, the entire regions where the conductive layers 119R, 119G, and 119S are provided can be used as light-emitting regions of the red-light-emitting device 110R and the green-light-emitting device 110G and as a light-receiving region, increasing the aperture ratio of the pixels and increasing the light-receiving area. The blue-light-emitting device can have a structure similar to those of the red-light-emitting device 110R and the green-light-emitting device 110G.

Although not illustrated, parts of the organic layers 112R and 112G are positioned in the depressed portion 103 in some cases. Part of the active layer is positioned in the depressed portion 103 in some cases. The structure of the organic layer in the blue-light-emitting device is similar to that in the red-light-emitting device 110R or the green-light-emitting device 110G.

A side surface and part of the top surface of the organic layer 112R are covered with the insulating layer 125a and a side surface and part of the top surface of the organic layer 112G are covered with the insulating layer 125b. Furthermore, a side surface and part of the top surface of the active layer is covered with an insulating layer 125s. The insulating layers 125a, 125b, 125c, 125s, and 125d preferably include an inorganic material.

The insulating layer 126 is positioned so as to overlap with depressed portions defined by the insulating layers 125a and 125b between the red-light-emitting device 110R and the green-light-emitting device 110G. The insulating layer 126 preferably includes an organic material, and the top surface of the insulating layer 126 can be at a higher level than the top surfaces of the organic layers 112R and 112G. The common layer 114 is provided over the organic layer 112R, the organic layer 112G, and the insulating layer 126, and the common electrode 113x is provided over the common layer 114. The common layer 114 and the common electrode 113x are each a continuous film shared by the plurality of light-emitting devices.

The red-light-emitting device 110R, the green-light-emitting device 110G, and the blue-light-emitting device 110B (not illustrated) have a top-emission structure in which light is emitted to the common electrode 113x side. As a light source of the light-receiving device 110S, light from the red-light-emitting device 110R, the green-light-emitting device 110G, or the blue-light-emitting device 110B (not illustrated) can be used. The wavelength from the green-light-emitting device 110G is suitable as the light source. The display device of one embodiment of the present invention may have a bottom-emission structure in which light is emitted to the lower electrode side. In the case of the bottom-emission structure, the light-receiving device may be omitted.

The protective layer 121 is provided over the red-light-emitting device 110R, the green-light-emitting device 110G, and the light-receiving device 110S. The protective layer 121 is also provided over the blue-light-emitting device. The protective layer 121 and the substrate 152 are bonded to each other with an adhesive layer 142. The substrate 152 is provided with a light-blocking layer 155. Furthermore, the substrate 152 may be provided with color filters or color conversion layers such that they overlap with the red-light-emitting device 110R and the green-light-emitting device 110G. A solid sealing structure, a hollow sealing structure, or the like can be employed to seal the light-emitting devices. In FIG. 29A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. In that case, the adhesive layer 142 may be provided not to overlap with the light-emitting device. The space may be filled with a resin different from that of the frame-like adhesive layer 142.

The protective layer 121 is provided at least in the display region 162, and preferably provided to cover the entire display region 162. The protective layer 121 is preferably provided to cover not only the display region 162 but also the connection portion 140 and the circuit 164. It is further preferable that the protective layer 121 be provided to extend to an end portion of the display device 100G. Meanwhile, a connection portion 204 has a portion not provided with the protective layer 121 so that the FPC 172 and a conductive layer 166 are electrically connected to each other.

The connection portion 204 is provided in a region of the substrate 151 not overlapping with the substrate 152. In the connection portion 204, the wiring 165 is electrically connected to the FPC 172 through the conductive layers 166, 167, and 168, and the connection layer 242. The conductive layer 167 is a conductive film obtained by processing the same conductive film as the conductive layers 115R and 115G, the conductive layer 166 is a conductive film obtained by processing the same conductive film as the conductive layers 117R and 117G, and the conductive layer 168 is a conductive film obtained by processing the same conductive film as the conductive layers 119R and 119G. In the case where a depressed portion is defined by the surface of the conductive layer 167, the depressed portion may be filled with a resin layer. Although an insulating layer 125e, the insulating layer 126, and the protective layer 121 are positioned in this order over the conductive layer 168, and an opening is formed in these insulating layers to expose the top surface of the conductive layer 168. An end portion of the insulating layer 126 is preferably covered with the protective layer 121. Thus, the connection portion 204 and the FPC 172 can be electrically connected to each other through the connection layer 242.

For example, the protective layer 121 is formed over the entire surface of the display device 100L and then a region of the protective layer 121 that overlaps with the conductive layer 168 is removed, so that the conductive layer 168 can be exposed.

The top surface of the conductive layer 168 may be covered with a mask so that the protective layer 121 is not provided over the conductive layer 168. As the mask, a metal mask (area metal mask) or a tape or a film having adhesiveness or attachability may be used. The protective layer 121 is formed while the mask is placed and then the mask is removed, so that the conductive layer 168 can be kept exposed even after the protective layer 121 is formed.

With such a method, a region not provided with the protective layer 121 can be formed in the connection portion 204, and the conductive layer 168 and the FPC 172 can be electrically connected to each other through the connection layer 242 in the region.

The connection portion 140 includes the insulating layer 105 including a depressed portion, the insulating layer 106 provided over the insulating layer 105, and the conductive layer 123 provided over the insulating layer 106. The conductive layer 123 has a stacked-layer structure including a conductive film obtained by processing the same conductive film as the conductive layers 115R and 115G, a conductive film obtained by processing the same conductive film as the conductive layers 117R and 117G, and a conductive film obtained by processing the same conductive film as the conductive layers 119R and 119G. The common layer 114 is provided over the conductive layer 123, and the common electrode 113x is provided over the common layer 114. The conductive layer 123 and the common electrode 113x are electrically connected to each other through the common layer 114. Note that the common layer 114 is not necessarily formed in the connection portion 140. In that case, the conductive layer 123 and the common electrode 113x are in direct contact with each other to be electrically connected to each other.

The display device 100L has a top-emission structure. Light emitted from the light-emitting device is emitted toward the substrate 152 side. For the substrate 152, a material having a high visible-light-transmitting property is preferably used. The pixel electrode includes a material that reflects visible light, and a counter electrode (the common electrode 113x) includes a material that transmits visible light.

The transistor 201 and the transistor 205 are formed over the substrate 151. These transistors can be manufactured using the same material in the same step.

An insulating layer 211, the insulating layer 213, and the insulating layer 215 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 105 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers that cover the transistors. This allows the insulating layer to function as a barrier layer. Such a structure can effectively inhibit diffusion of impurities into the transistors from the outside and increase the reliability of a display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 105 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 105 may have a stacked-layer structure of an organic insulating layer and an inorganic insulating layer. The outermost layer of the insulating layer 105 preferably has a function of an etching protective layer. In that case, a depressed portion can be inhibited from being formed in the insulating layer 105 at the time of processing the conductive layer 117R, the conductive layer 117G, the conductive layer 117B, or the like. Alternatively, a depressed portion may be formed in the insulating layer 105 at the time of processing the conductive layer 117R, the conductive layer 117G, the conductive layer 117B, or the like. In FIG. 29A, the depressed portion 103 of the insulating layer 105 is formed through a step different from the step of processing the conductive layer 117R, the conductive layer 117G, the conductive layer 117B, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate or bottom-gate transistor structure may be employed. Alternatively, gates may be provided above and below the semiconductor layer where a channel is formed.

The structure in which the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

The semiconductor layer of the transistor preferably includes a metal oxide (also referred to as an oxide semiconductor). That is, a transistor including a metal oxide in its channel formation region (hereinafter, referred to as an OS transistor) is preferably used for the display device of this embodiment.

Examples of the metal oxide that can be used for the semiconductor layer include indium oxide, gallium oxide, and zinc oxide. The metal oxide preferably contains two or three selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

When the metal oxide used for the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or an atomic ratio in the neighborhood thereof, In:M:Zn=1:1:1.2 or an atomic ratio in the neighborhood thereof, In:M:Zn=1:3:2 or an atomic ratio in the neighborhood thereof, In:M:Zn=1:3:4 or an atomic ratio in the neighborhood thereof, In:M:Zn=2:1:3 or an atomic ratio in the neighborhood thereof, In:M:Zn=3:1:2 or an atomic ratio in the neighborhood thereof, In:M:Zn=4:2:3 or an atomic ratio in the neighborhood thereof, In:M:Zn=4:2:4.1 or an atomic ratio in the neighborhood thereof, In:M:Zn=5:1:3 or an atomic ratio in the neighborhood thereof, In:M:Zn=5:1:6 or an atomic ratio in the neighborhood thereof, In:M:Zn=5:1:7 or an atomic ratio in the neighborhood thereof, In:M:Zn=5:1:8 or an atomic ratio in the neighborhood thereof, In:M:Zn=6:1:6 or an atomic ratio in the neighborhood thereof, and In:M:Zn=5:2:5 or an atomic ratio in the neighborhood thereof. Note that an atomic ratio in the neighborhood includes the range of ±30% of an intended atomic ratio.

For example, when the atomic ratio is described as In:Ga:Zn=4:2:3 or an atomic ratio in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or an atomic ratio in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or an atomic ratio in the neighborhood thereof, the case is included where Ga is greater than 0.1 and less than or equal to 2 and Zn is greater than 0.1 and less than or equal to 2 with In being 1.

The semiconductor layer may include two or more metal oxide layers having different compositions. For example, a stacked-layer structure of a first metal oxide layer having In:M:Zn=1:3:4 or an atomic ratio in the neighborhood thereof and a second metal oxide layer having In:M:Zn=1:1:1 or an atomic ratio in the neighborhood thereof and being formed over the first metal oxide layer can be favorably employed. In particular, gallium or aluminum is preferably used as the element M.

Alternatively, a stacked-layer structure of one selected from indium oxide, indium gallium oxide, and IGZO and one selected from IAZO, IAGZO, and ITZO (registered trademark) may be employed, for example.

As the oxide semiconductor having crystallinity, a CAAC (c-axis aligned crystalline)-OS, an nc (nanocrystalline)-OS, and the like can be given.

Alternatively, a transistor using silicon in its channel formation region (a Si transistor) may be used. Examples of silicon include single crystal silicon, polycrystalline silicon, and amorphous silicon. In particular, a transistor including low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows simplification of an external circuit mounted on the display device and a reduction in component cost and mounting cost.

An OS transistor has much higher field-effect mobility than a transistor using amorphous silicon. In addition, the OS transistor has extremely low leakage current between a source and a drain in an off state (hereinafter, also referred to as off-state current), and charge accumulated in a capacitor that is connected in series to the transistor can be retained for a long period. Furthermore, the power consumption of the display device can be reduced with the OS transistor.

To increase the emission luminance of the light-emitting device included in a pixel circuit, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be fed through the OS transistor than through a Si transistor. Thus, by using an OS transistor as the driving transistor, a stable current can be fed through the light-emitting device even when the current-voltage characteristics of the EL device vary, for example. In other words, when the OS transistor operates in the saturation region, the source-drain current hardly changes with an increase in the source-drain voltage; hence, the emission luminance of the light-emitting device can be stable.

As described above, by using an OS transistor as the driving transistor included in the pixel circuit, it is possible to achieve “inhibition of black-level degradation”, “increase in emission luminance”, “increase in the number of gray levels”, “inhibition of variation in light-emitting devices”, and the like.

The transistor included in the circuit 164 and the transistor included in the display region 162 may have the same structure or different structures. A plurality of transistors included in the circuit 164 may have the same structure or two or more kinds of structures. Similarly, a plurality of transistors included in the display region 162 may have the same structure or two or more kinds of structures.

All of the transistors included in the display region 162 may be OS transistors or all of the transistors included in the display region 162 may be Si transistors; alternatively, some of the transistors included in the display region 162 may be OS transistors and the others may be Si transistors.

For example, when both an LTPS transistor and an OS transistor are used in the display region 162, the display device can have low power consumption and high drive capability. Note that a structure where an LTPS transistor and an OS transistor are combined is referred to as LTPO in some cases. Note that as a more suitable example, a structure where the OS transistor is used as a transistor or the like functioning as a switch for controlling continuity and discontinuity between wirings, and the LTPS transistor is used as a transistor or the like for controlling current, can be given.

For example, one of the transistors included in the display region 162 functions as a transistor for controlling a current flowing through the light-emitting device and can also be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

Another transistor included in the display region 162 functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having an MML (metal maskless) structure. This structure can significantly reduce the leakage current that might flow through a transistor, and the leakage current that might flow between adjacent light-emitting devices (also referred to as a lateral leakage current, a side leakage current, or the like). With the structure, a viewer can notice any one or more of the image crispness, the image sharpness, a high chroma, and a high contrast ratio in an image displayed on the display device. Note that when the leakage current that might flow through the transistor and the lateral leakage current between the light-emitting devices are extremely low, light leakage that might occur in black display (what is called black-level degradation) or the like can be reduced as much as possible.

In particular, in the case where a light-emitting device having the MML structure employs the above-described SBS structure, a layer provided between light-emitting devices (for example, an organic layer shared by the light-emitting devices, also referred to as a common layer) is disconnected; accordingly, lateral leakage can be eliminated or reduced as much as possible.

FIG. 29B and FIG. 29C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 29B illustrates an example of the transistor 209 in which the insulating layer 225 covers a top surface and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 29C, the insulating layer 225 overlaps with the channel formation region 231i of the semiconductor layer 231 and does not overlap with the low-resistance regions 231n. The structure illustrated in FIG. 29C can be manufactured by processing the insulating layer 225 using the conductive layer 223 as a mask, for example. In FIG. 29C, the insulating layer 215 is provided to cover the insulating layer 225 and the conductive layer 223, and the conductive layer 222a and the conductive layer 222b are connected to the respective low-resistance regions 231n through the openings in the insulating layer 215.

A light-blocking layer 155 is preferably provided on the surface of the substrate 152 on the substrate 151 side. The light-blocking layer 155 can be provided between adjacent light-emitting devices, in the connection portion 140, and in the circuit 164, for example. A variety of optical members can be placed on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

This embodiment can be combined with the other embodiments as appropriate.

### Embodiment 6

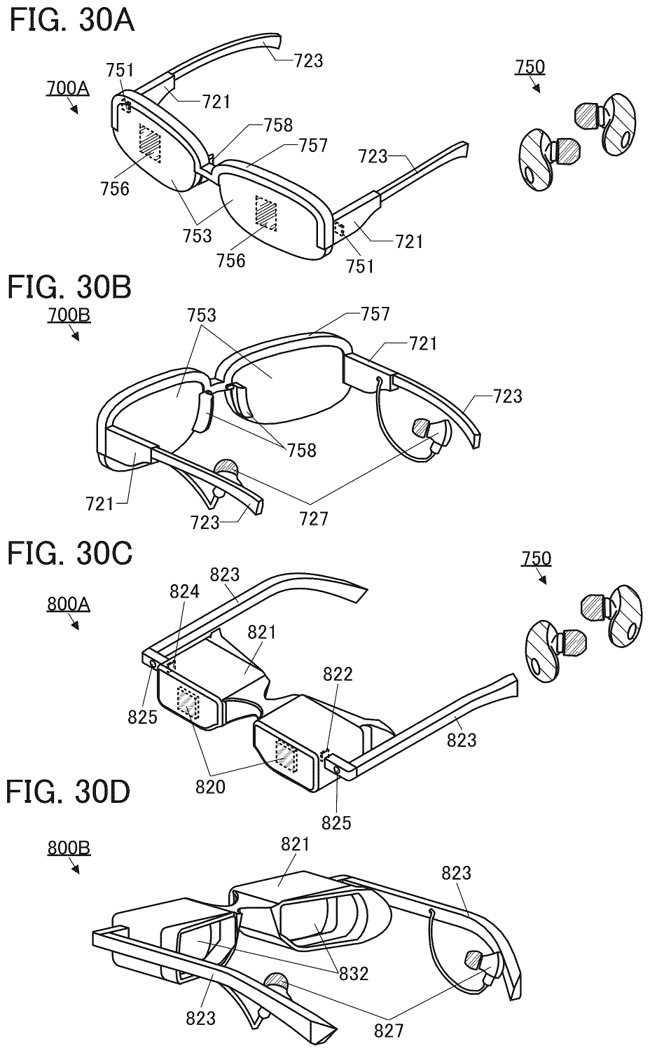

In this embodiment, electronic devices of one embodiment of the present invention will be described with reference to FIG. 30 to FIG. 32.

Electronic devices of this embodiment each include the display device of one embodiment of the present invention in a display portion. The display device of one embodiment of the present invention can be easily increased in resolution and definition. Thus, the display device of one embodiment of the present invention can be used for display portions of a variety of electronic devices.

Examples of electronic devices include electronic devices with a relatively large screen, such as a television device, a desktop or laptop personal computer, a monitor of a computer or the like, digital signage, and a large game machine such as a pachinko machine; a digital camera; a digital video camera; a digital photo frame; a mobile phone; a portable game machine; a portable information terminal; and an audio reproducing device.

In particular, the display device of one embodiment of the present invention can have high resolution, and thus can be suitably used for an electronic device having a comparatively small display portion. Examples of such an electronic device include watch-type and bracelet-type information terminals (wearable devices) and wearable devices that can be worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably greater than or equal to 100 ppi, further preferably greater than or equal to 300 ppi, still further preferably greater than or equal to 500 ppi, yet further preferably greater than or equal to 1000 ppi, yet still further preferably greater than or equal to 2000 ppi, yet still further preferably greater than or equal to 3000 ppi, yet still further preferably greater than or equal to 5000 ppi, yet still further preferably greater than or equal to 7000 ppi. With the use of such a display device with one or both of high definition and high resolution, an electronic device for portable use or home use can have higher realistic sensation, sense of depth, and the like. There is no particular limitation on the screen ratio (aspect ratio) of the display device of one embodiment of the present invention. For example, the display device is compatible with a variety of screen ratios such as 1:1 (square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a head-mounted wearable device are described with reference to FIG. 30A to FIG. 30D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 30A and an electronic device 700B illustrated in FIG. 30B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panel 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In each of the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 30C and an electronic device 800B illustrated in FIG. 30D each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic device can perform display with extremely high resolution. This enables a user to feel high sense of immersion.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 30C or the like illustrates an example where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portions 825 are provided is shown here, a range sensor capable of measuring a distance between the user and an object (hereinafter also referred to as a sensing portion) just needs to be provided. That is, the image capturing portion 825 is one embodiment of the sensing portion. For the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, any one or more of the display portion 820, the housing 821, and the wearing portion 823 can employ a structure including the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 30A has a function of transmitting information to the earphones 750 with the wireless communication function. For another example, the electronic device 800A illustrated in FIG. 30C has a function of transmitting information to the earphones 750 with the wireless communication function.

The electronic device may include an earphone portion. The electronic device 700B in FIG. 30B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 30D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. The earphone portions 827 and the wearing portions 823 may include magnets. This is preferred because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

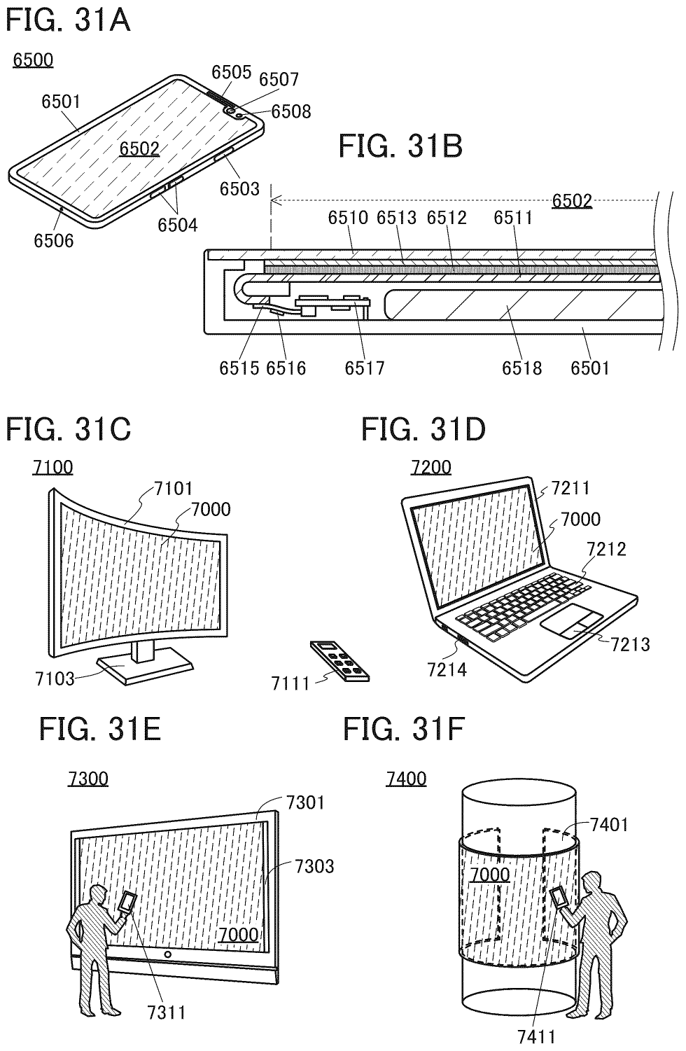

An electronic device 6500 illustrated in FIG. 31A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used for the display portion 6502.

FIG. 31B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be employed for the display panel 6511. Thus, an extremely lightweight electronic device can be achieved. Since the display panel 6511 is extremely thin, the battery 6518 with high capacity can be mounted while an increase in thickness of the electronic device is suppressed. Moreover, part of the display panel 6511 is folded back such that a connection portion with the FPC 6515 is provided on the back side of the pixel portion, whereby an electronic device with a narrow bezel can be obtained.

FIG. 31C illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used for the display portion 7000.

Operation of the television device 7100 illustrated in FIG. 31C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 31D illustrates an example of a notebook personal computer. A laptop personal computer 7200 includes a housing 7211, a keyboard 7212, a pointing device 7213, an external connection port 7214, and the like. In the housing 7211, the display portion 7000 is incorporated. The display device of one embodiment of the present invention can be used for the display portion 7000.

FIG. 31E and FIG. 31F illustrate examples of digital signage.

Digital signage 7300 illustrated in FIG. 31E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 31F is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIG. 31E and FIG. 31F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 31E and FIG. 31F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

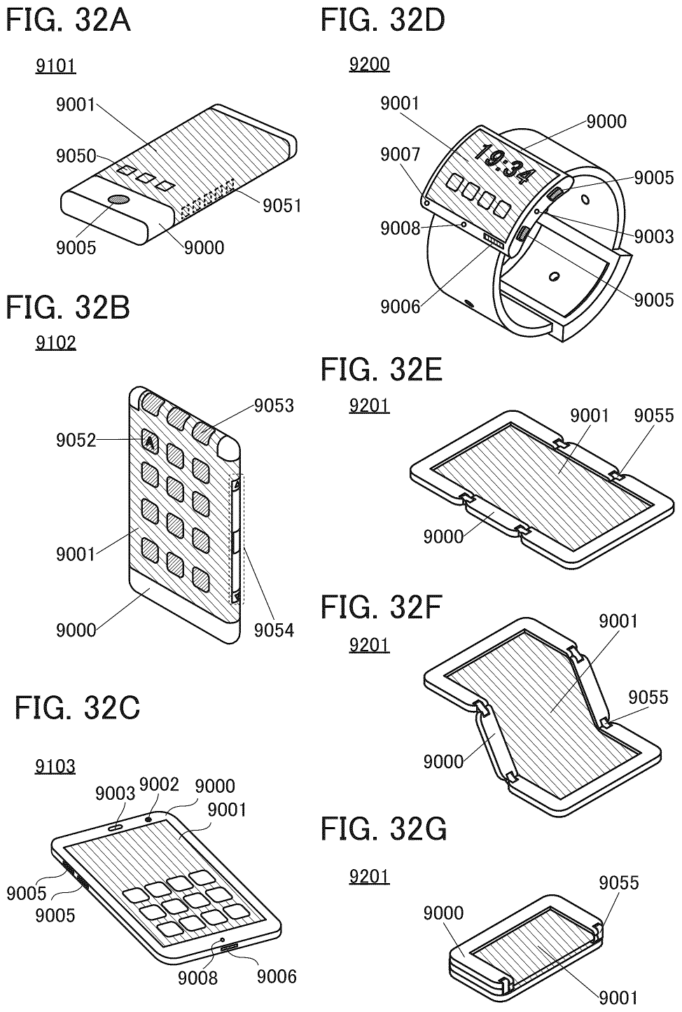

Electronic devices illustrated in FIG. 32A to FIG. 32G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display device of one embodiment of the present invention can be used for the display portions 9001 in FIG. 32A to FIG. 32G.

The electronic devices illustrated in FIG. 32A to FIG. 32G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. In addition, the electronic devices may each include a camera or the like and have a function of capturing a still image or a moving image and storing the captured image in a recording medium (an external recording medium or a recording medium incorporated in the camera), a function of displaying the captured image on the display portion, or the like.

The details of the electronic devices illustrated in FIG. 32A to FIG. 32G are described below.

FIG. 32A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display characters and image information on its plurality of surfaces. FIG. 32A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 32B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 32C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 32D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 32E to FIG. 32G are perspective views illustrating a foldable portable information terminal 9201. FIG. 32E is a perspective view of an opened state of the portable information terminal 9201, FIG. 32G is a perspective view of a folded state thereof, and FIG. 32F is a perspective view of a state in the middle of change from one of FIG. 32E and FIG. 32G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

103: depressed portion, 105: insulating layer, 106: insulating layer, 107: protruding portion, 110: light-emitting device, 111: lower electrode, 112: organic layer, 113: upper electrode, 125: insulating layer

1. A display device comprising:
a first insulating layer;
a second insulating layer;
a first light-emitting device over the first insulating layer;
a second light-emitting device over the second insulating layer; and
a third insulating layer comprising a region covering a part of a side surface of the first light-emitting device, and a region covering a part of a side surface of the second light-emitting device,
wherein the first light-emitting device has a tandem structure, and
wherein the second light-emitting device has a single structure.

2. (canceled)

3. A display device comprising:
a first insulating layer comprising a depressed portion;
a second insulating layer over the first insulating layer and comprising a first protruding portion overlapping with the depressed portion;
a third insulating layer over the first insulating layer and comprising a second protruding portion overlapping with the depressed portion;
a first light-emitting device over the first insulating layer;
a second light-emitting device over the second insulating layer; and
a fourth insulating layer comprising a region covering a part of a side surface of the first light-emitting device, and a region covering a part of a side surface of the second light-emitting device.

4. (canceled)

5. A display device comprising:
a first insulating layer;
a second insulating layer;
a first light-emitting device over the first insulating layer;
a second light-emitting device over the second insulating layer; and
a third insulating layer comprising a region covering a part of a side surface of the first light-emitting device, and a region covering a part of a side surface of the second light-emitting device,
wherein the first light-emitting device comprises a first light-emitting unit, a charge-generation layer over the first light-emitting unit, and a second light-emitting unit over the charge-generation layer, and
wherein the second light-emitting device comprises a third light-emitting unit.

6. (canceled)

7. (canceled)

8. (canceled)

9. (canceled)

10. (canceled)

11. (canceled)

12. (canceled)

13. The display device according to claim 1,
wherein the third insulating layer further comprises a region covering a part of a bottom surface of the first insulating layer, and a region covering a part of a bottom surface of the second insulating layer.

14. The display device according to claim 1,
wherein the third insulating layer further comprises a region in contact with a part of a bottom surface of the first insulating layer, and a region in contact with a part of a bottom surface of the second insulating layer.

15. The display device according to claim 3,
wherein the fourth insulating layer further comprises a region covering a bottom surface of the first protruding portion, and a region covering a bottom surface of the second protruding portion.

16. The display device according to claim 3,
wherein the fourth insulating layer further comprises a region in contact with a bottom surface of the first protruding portion, and a region in contact with a bottom surface of the second protruding portion.

17. The display device according to claim 3,
wherein the first light-emitting device has a tandem structure, and
wherein the second light-emitting device has a single structure.

18. The display device according to claim 5,
wherein the third insulating layer further comprises a region covering a part of a bottom surface of the first insulating layer, and a region covering a part of a bottom surface of the second insulating layer.

19. The display device according to claim 5,
wherein the third insulating layer further comprises a region in contact with a part of a bottom surface of the first insulating layer, and a region in contact with a part of a bottom surface of the second insulating layer.

20. The display device according to claim 13,
wherein the first insulating layer, the second insulating layer, and the third insulating layer each comprise an inorganic material.

21. The display device according to claim 14,
wherein the first insulating layer, the second insulating layer, and the third insulating layer each comprise an inorganic material.

22. The display device according to claim 15,
wherein the first light-emitting device further comprises a first light-emitting unit, a charge-generation layer over the first light-emitting unit, and a second light-emitting unit over the charge-generation layer, and
wherein the second light-emitting device comprises a third light-emitting unit.

23. The display device according to claim 15,
wherein the first insulating layer comprises an organic material, and
wherein the second insulating layer, the third insulating layer, and the fourth insulating layer each comprise an inorganic material.

24. The display device according to claim 15,
wherein the first insulating layer, the second insulating layer, the third insulating layer, and the fourth insulating layer each comprise an inorganic material.

25. The display device according to claim 16,
wherein the first light-emitting device further comprises a first light-emitting unit, a charge-generation layer over the first light-emitting unit, and a second light-emitting unit over the charge-generation layer, and
wherein the second light-emitting device comprises a third light-emitting unit.

26. The display device according to claim 16,
wherein the first insulating layer comprises an organic material, and
wherein the second insulating layer, the third insulating layer, and the fourth insulating layer each comprise an inorganic material.

27. The display device according to claim 17,
wherein the first insulating layer comprises an organic material, and
wherein the second insulating layer, the third insulating layer, and the fourth insulating layer each comprise an inorganic material.

28. The display device according to claim 18,
wherein the charge-generation layer comprises lithium.

29. The display device according to claim 19,
wherein the charge-generation layer comprises lithium.
